(19) United States
(12) Patent Application Publication
(10) Pub. No.: US 2008/0297265 A1
(43) Pub. Date: Dec. 4, 2008

(54) 4Less-TSOC of XLC, QBXOCK, QBTCXO, QBVCXO, SMLDVR and ANLVCO or 4Free-TSOC of XLC, QBXOCK, QBTCXO, QBVCXO, SMLDVR and ANLKVCO

(76) Inventors: Min Ming Tarng, San Jose, CA (US); Mei Jech Lin, San Jose, CA (US); Eric Yu-Shiao Tarng, San Jose, CA (US); Alfred Yu-Chi Tarng, San Jose, CA (US); Angela Yu-Shiu Tarng, San Jose, CA (US); Jwu-Ing Nieh, San Jose, CA (US); Huang-Chang Tarng, San Jose, CA (US); Shun-Yu Nieh, San Jose, CA (US); Minh V. Nguyen, San Jose, CA (US)

Correspondence Address: Min Ming Tarng, Ph.D., 1367 Glenmoor Way, San Jose, CA, 95129, US

(21) Appl. No.: 12/082,601

(22) Filed: Apr. 12, 2008

Related U.S. Application Data
(63) Continuation-in-part of application No. 11/500,125, filed on Aug. 5, 2006.
Application No. 11/500,125 is a continuation-in-part of application No. 11/593,271, filed on Nov. 6, 2006.

(51) Int. Cl. H03B 5/30

(52) U.S. Cl. 331/116 R

(57) ABSTRACT

Even the 4Less-Xtaless, Capless, Indless, Dioless TSOC Design of SOC or 4Free-Xtafree, Capfree, Indfree, Diofree TSOC Design of SOC is developed for the TSOC True System-On-Chip, the 4Less/4Free technologies can still be applied to the conventional XCLK, PMU, etc chip design to have the drastically fantastical improvements over the conventional crystal clock and power management unit chips. The application of 4Less/4Free-TSOC technology to the conventional crystal oscillator to be the QBXOCK Q-Boost Crystal Oscillator Clock, QBTCXO Q-Boost Temperature Cancelling Crystal Oscillator Clock and QBVCXO Q-Boost Voltage Control Crystal Oscillator Clock. Temperature cancelling technique is different from temperature compensation technique. Temperature cancelling technique gets rid of the temperature effect completely. However, the temperature compensation technique still has the residue temperature effect which cannot be compensated with the trimming bits. The application of 4Less/4Free-TSOC technology to the conventional PMU is the SMLDVR Switch Mode & Low Drop Voltage Regulator to have one power supply having two operation modes of switch mode and low drop voltage regulator to have the ultra-extended battery life for portable devices. The application of 4Less/4Free-TSOC technology to the conventional PLL is to have the ANLVCO Adaptive Non-Linear VCO to have the ultra-performance of clock jitter being much less than 1 ps. For the high frequency Network system such as Ethernet, WiMAX, Fiber optics, etc, the ANLVCO is the core technology.

This is a Continuation in Part application claims priority of U.S. patent application Ser. No. 11/500,125, filed Aug. 5, 2006, U.S. patent application Ser. No. 11/593,271, filed Nov. 6, 2006 and U.S. and patent application Ser. No. ______ filed on Mar. 25, 2008 which are herein incorporated by reference in their entirety.

### BACKGROUND

1. Field of Invention

The 4Less-Xtaless, Capless, Indless, Dioless SOC Design or 4Free-Xtafree, Capfree, Indfree, and Diofree SOC Design is to get rid of all the on-board external components of the SOC design. It takes a lot efforts and innovations to develop the new circuit technologies. Even the 4Less-Xtaless is developed for SOC, the new 4Less technologies of chip design can have the immediate application on the old product lines to enhance the old product performance.

The XLC XtaLess Clock or XQBXOCK is the Q-Boost Crystal Oscillator Clock based on the on-chip LC resonator of X-LC resonator technology. The gain-boost-Q and temperature cancelling technologies have the immediate application to improve the conventional crystal oscillator clock performance quite a lot. This gain-boost-Q and temperature cancelling can be applied all the product line of crystal oscillator. It is well known that the high quality crystal costs a lot money. With the gain-boost-Q technology, even with the cheap low quality crystal, it still can beat the performance of the high quality crystal. It has a lot business chance to apply the 4Less technology to the old product line. It will take out all the market share with the gain-boost-Q crystal clock. QBTCXO is Q-Boost Temperature Cancelling Crystal Oscillator which is the application of Q-Boost technology to the product line of Temperature Cancelling Crystal Oscillator. The other TCXO is temperature compensation and the nonlinear temperature effect. Our design technique is temperature cancelling that all the temperature effect is eliminated. QBVCXO is Q-Boost voltage control Crystal Oscillator which is the application of Q-Boost technology to the product line of voltage control Crystal Oscillator. Furthermore, the TRNG can generate the high quality spread spectrum clock. The on-chip TRNG True Random Number Generator is easily integrated with the BQXOCK to have the option to be the regular clock or spread spectrum clock. The TRNG is implemented with the randomized chaotic circuit.

SMLDVR is the merge of the capless LDVR and indless SM to the PMU of battery to have the ultra extended battery life and the superior power efficiency and minimum switching power noise. The SM and LDVR can share the same power driver and make the smooth switching between the SM mode and LDVR mode, and vice versa. It saves the chip area and eliminates the over-voltage protection problem and the in-rush current problem. Furthermore, now the SMLDVR chip designed with the 4Less technology that the SMLDVR chip doesn't use the cap and inductor at all. So the SMLDVR can take over all the market share of PMU.

To have the high frequency clock, it adopts the frequency synthesizer to lock with the low frequency clock reference. Now the on-chip LCO can have the high frequency clock directly. However, for the CDR type problem, the frequency synthesizer is still needed. Furthermore, the CDR problem is the twist-pair Ethernet being 10 GB right now. The PLL needs the ultra-high performance to have the clock jitter being less than 1 ps. To have the very fine tune at the operating frequency, the Kvco is minimum and the frequency tuning speed needs to be very fast. However, the frequency tracing range stills needs to be wide. So, the Kvco curve has to be not only nonlinear but also dynamic adaptive to the variance of the operating frequency. To have the ultra PLL-performance, the new architecture of PLL has to be invented to have the ANLVCO, Adaptive Nonlinear Kvco coefficient Voltage Control Oscillator.

2. Description of Prior Art

There are two kinds of design styles: (1) the board design oriented; and (2) the chip design oriented. For the board oriented design is to use the off-shelf components to implement the design. The more components are, the more board layout area and the more cost the board is. So, the board design oriented design is to use the minimum components to implement the minimum function. On the contrary, the chip design is to use more transistors to achieve the best performance. The transistors cost is negligible. The chip design is designed for high performance. The designer can reinvent new wheel to implement the best performance for the same function. Today's problem is the circuit designer does not have the capability to reinvent new wheel. So the prior designer just port the board design to be the chip design without reinvent new wheel. For these circuits which the former designers cannot port, they just leave the board design as it is. They don't know how to create new algorithm, new architecture and new circuit configuration to implement the same function. So, the crystal clock, LVDR, SM and TRNG are the circuit which they cannot be ported to the SOC and leave them as the original board design is. The most serious problem is the today circuit designer doesn't have enough training and education. They don't know, even there is no such training class to instruct them how to create new algorithm, new architecture, new system, new circuit configuration, etc. This is the high-level circuit designer training we don't have in the university graduate courses. Today, the circuit designer only knows pole, zero, device characteristics, etc. However, these factors are not important in the creation of the new circuit configuration at all. The designer needs philosophical thinking, however, the philosophical professor doesn't know the circuit at all.

Today's crystal clock is still in the board design style. The board design crystal clock is very simple and it has only one inverter, one inductor and two capacitors. For the requirement of the high performance clock, it just adopts the high cost and high quality crystal. The designer doesn't know how to use the GBQ Gain-Boost-Q circuit technique to enhance the crystal clock performance and it can have the high performance clock with the low quality crystal. The designer doesn't know that he can use the low quality crystal to design the high quality clock chip. The design just wastes money to adopt the high quality crystal to make the high performance clock chip. For the TCXO, the other people only use the temperature compensation methodology. They don't know the temperature cancelling techniques. So, the TCXO still has the nonlinear temperature effects on the XO performance.

Today PMU Power Management Unit needs to use a lot capacitors and inductors. The LDVR Low Drop Voltage Regulator has a lot of power loss and the SM Switch Mode Power Supply has a lot of switch noises. Even worse, the LDVR needs to use the large layout area for driver; the SM also needs to use the large layout area for driver. The formal designer never thinks that the capacitors and inductors are not necessary with the creative circuit designs. Even they don't think that the driver of LDVR and the driver of SM can share with each other that only one driver is needed. The former design doesn't know the SM and LDVR mode can switch each other that the power efficiency, switching noise, over voltage protection and the rush-in current problems can be all solved once.

Today PRNG Pseudo Random Number Generator is the only on-chip RNG Random Number. Today TRNG is the on-board circuit implemented with the Avalanche Diode reverse-biased with 15 volts power supply. Both the Avalanche Diode and the 15 volts cannot be integrated on the low voltage 1.2V CMOS chip. The TRNG needs to be reinvented with new circuit configuration. However, the circuit does not know the design of the chaos circuit at all, not to mention the randomized chaotic circuit.

### OBJECTS AND ADVANTAGES

The 4-less/4-Free TSOC technology applying to the conventional circuits such as XOCLK crystal oscillator clock generator, PMU power management unit circuit and FSPLL frequency synthesizer phase lock loop circuit, it makes the tremendous improvements in the performance and saving a lot of cost. The XOCLK crystal oscillator clock generator can use the low cost low quality crystal to get the same performance of the high cost high quality crystal. With the universal approach, one SMLDVR switch mode low drop voltage regulator can have the general purpose power supply to save power, low switching noise and extended battery life. There is no over-voltage, rush-in current and ESD problems as the conventional PMU chip does. With the on-chip TRNG, the EMI problem of the XOCLK and PMU are both eliminated. The XOCLK has the true uniform distributed spread spectrum clock and the SMLDVR doesn't have the EMI problem.

### DRAWING FIGURES

FIG. 1 (A) is the top-level block diagram of the 4Less/4Free TSOC design for SOC Security of Community; (B) is the signal flow block diagram of SOC, Security of Community; (C) is the illustrative diagram of the SOC, Security of Community.

FIG. 2 shows the self-compensated design principles; (A)(B) shows the self compensated for the L, R, and C; (A) is the section view of the basic components of the capacitor, inductor and resistor; (B) is the section view of the basic components of the capacitor, inductor and resistor having the temperature variance and humidity variance combinatory effect; (C) is the two dimensional temperature and humidity combinatory variances effect curves; (D) is the SC (Self-Compensated) design of the resistor; (E) The SC design of the inductor having the closed toroid shape and resistor layout style resistive capacitor; (F) is the sectional view of the SC design of the inductor having the toroid closed shape and resistor type capacitor taken along the line F-F in FIG. 2E; (G) is the schematics of the fundamental SC-LC resonator; (H) is the SC-LC resonator with the self-compensated SC-R type resistors R_{L} and R_{C}; (I) is the self-compensated SC-LC resonator having the resistor trimming bits for adjustment of the minor deviation after the self-compensation and the capacitor with modulation or trimming capabilities.

FIGS. 3 (A) and (B) are the comparisons between the free-running LC resonator and the gain-boost-Q LC resonator; (A) is the input, LC transfer function and output of the LC free-running/free-wandering resonator; (B) is the input, LC transfer function and output of the gain-boost-Q LC resonator; (C) to (J) shows the anti-sea-tide-breezing LC resonator design; (C) shows the sea-tide-breezing power supply chaos causes the chaotic behavior of the power supply; (D) is the flow block diagram, phase diagram and frequency spectrum of the noise generated chaotic behavior in the parametric chaotic circuit of LC oscillator; (E) is the ideal oscillatory behavior of the anti-sea-tide-breezing LC resonator after the chaos in FIG. 3C being removed; (F) is the flow block diagram of the fundamental mechanism for the anti-sea-tide-breezing LC resonator; (G) is the frequency spectrum of the anti-sea-tide-breezing LC resonator design corresponding to FIG. 3F; (H) is the amplitude control and common-mode control for the LC resonator design; (I) is the anti-sea-tide-breezing LC resonator design; (J) is the circuit of the anti-sea-tide-breezing LC resonator design; (K) is the injecting path of the inductor switching noise sneaking into the oscillator such as crystal oscillator; (L) is the direct conversion RF front architecture with the conventional LC resonator; (M) is the direct modulation architecture with the anti-sea-tide-breezing LC resonator; (O) is the PFLL having both the phase lock loop and the frequency lock loop; (P) is the 3-CHPH charging pump and control voltage holding circuit for the frequency lock loop; (Q) is the timing waveform and state diagram of the frequency lock loop.

FIG. 4 is RC/IC resonator; (A) is the idealized RC/IC resonator operation; (B) is the real nonlinear behavior waveform of the RC/IC resonator; (C) is the timing waveform of the RC/IC resonator operation in the real noisy chip; (D) is the idealized interleave charging and discharging RC/IC architecture; (E) is the interleave RC/IC resonator operation in the real noisy chip; (F) is the conventional RC/IC resonator timing chart, the trigger point is fixed and the Tperiod is varying; (G) is our innovative RC/IC resonator timing chart; the trigger point varies and the Tperiod is fixed; (H) is the conventional toggling switch mechanism which has the hang-up problem is the high-speed operation; (I) is timing diagram of the conventional toggling switch mechanism; (J) is the modified conventional toggling switch mechanism to avoid the hang-up problem in high speed operation; (K) is timing diagram of the modified conventional toggling switch mechanism; (L) is the algorithm and architecture of the synchronize toggling switch; (M) is the circuit configuration of the synchronize toggling switch; (N) is timing diagram of the synchronize toggling switch; (O) is the circuit of the synchronize toggling switch. (P) is the wide dynamic swing current source circuit for the RC/IC resonator; (Q) is the single loop type basic architecture of the Loop compensated RC/IC resonator; (R) is the basic interleaved loops type basic Loop compensated RC/IC resonator; (S) is the complete circuit of the interleaved loops type Loop compensated RC/IC resonator.

FIG. 5 (A) is the architecture of the capless LDVR; (B) is the ramping curve of the capless LDVR; (C) is the circuit of the capless LDVR; (D) is the slew rate control circuit; (E) is the modified driver circuit of the capless LDVR having the large PSRR and anti-ESD-latch capability; (F) is the conventional LDVR which has the intrinsic stability problem; (G) is the conventional LDVR being modified with the Capless LDVR circuit design technology; (H) is the circuit of the capless PID control circuit; (I) the load adaptive hybrid capless LDVR being made of the digital LDVR and analog capless LDVR; (J) is the load regulation on the digital control LDVR; (K) is the difference generator with the peak and valley detector.

FIG. 6 is the Indless SM; (A) is the conventional PMU architecture for the board/system level power supply; (B) is the architecture for the battery PMU (Power Management Unit); (C) is the PMU-X design and analysis on the power swing of SM for different switch noise and switch power efficiency; (D) is the power plan for the dual mode of the capless SM with digital SM and the analog hybrid SM□ (E) is the waveforms of PWM, PFM and PHM; (F) is the core mechanism of PWM (Pulse Width Modulation); (G) is the core mechanism to implement the PFM (Pulse Frequency Modulation): (H) is the core mechanism to implement the PHM (Pulse Hybrid Modulation) and the driver for Indless SM; (I) is the difference amplifier and the varying frequency resonator in current control oscillator mode; (J) is the difference amplifier and the varying frequency resonator in voltage control oscillator mode; (K) is the illustrative waveform example of the PHM; (L) is the switch delay for the minimum modulation pulse width of PHM; (M) is the hybrid SMPHM of the digital PHM and analog PHM; (N) is the difference generator; (O) is the PMU architecture of the conventional board; (P) is the PMU architecture of the battery PMU; (Q) is the power up sequence of battery PMU; (R) is the supply voltage level generator of the high voltage; (S)(T)(U) shows the unified PMU with configurable circuit for the high voltage PHM, capless LDVR and low voltage PHM; (S) is the modified high voltage PHM to be the capless LDVR; (T) is the capless LDVR serving as the high voltage PHM; (U) is the modified version of the high voltage PHM or capless LDVR to be the low voltage PHM; (V) is the SMLDVR Switch Mode & Low Drop Voltage regulator to extend the battery life about 6 times; (W) the timing waveform to wake-up the CML of fiber optics input buffer; (X) is the difference amplifier to wake-up the CML of fiber optics input buffer.

FIG. 7 is the TRNG (True Random Number Generator); (A) is the conventional PRNG (Pseudo Random Number Generator) with the left shift digital register; (B) is the basic TRNG (True Random Number Generator) with the ring-shift analog inverter; (C) is the HTRNG (Hierarchical True Random Number Generator) having the recursive structure of the basic TRNG; (D) is the illustrative picture of the concept of the randomized chaos; (E) is the result of the phase plotting trace of the randomized chaos; (F) is the phase diagram of the X1 and X2 in FIG. 7B having no chaos condition; (G) is the phase diagram of X1 and X2 in FIG. 7B having the chaos condition; (H) is the frequency band of signal; (I) is the frequency spectrum of white noise; (J) is the sampling S/H effect; (K) is the white noises spectrum of the random number; (L) is the architecture for the addition of the random number noise to the circuit noise through the AC coupling in FIG. 7B and FIG. 7C; (M) is the circuit configuration for the addition of the random number noise to the circuit noise through the AC coupling in FIG. 7B and FIG. 7C; (N) is the left shift type analog register in ring oscillator; (O) is the voltage mode analog register; (P) is the current mode analog register; (Q) is the example of the basic circuit configuration of the True Random Noise Generator made of the left shift analog register; (R) is the clock chip having both random number and the spread spectrum clock.

FIG. 8 is the first true comparator in all the world; (A) is the jumping behavior in the true comparator; (B) is the limit cycles phenomena on the phase plot for the jumping phenomena; (C) the universal architecture for the true comparator; (D) is the specialized OPAMP for the true comparator which has the jumping behavior.

FIG. 9 is the electronic debouncing switch; (A) is the conventional mechanical toggle pseudo-debouncing switch; (B) is the mechanical double-throw pseudo-debouncing switch; (C) is the circuit of the electronic capless true debouncing switch; (D) is the switch behavior of the capless electronic true-debouncing switch.

FIG. 10 (A) is the pseudo-truth-table of the USB smart switch; (B) is the pseudo-state-diagram of the USB smart switch; (C) the architecture and circuit configuration of the USB smart switch; (D) the schematic of the circuit of the USB smart switch.

FIG. 11 is the bandgap reference Vbg, Ibg and Vbg_ok; (A) the bandgap reference circuit; (B) the schematic of the circuit of Vbg_ok; (C) is the working principle of the sub threshold bandgap voltage Vbg_iptat; (D) is the working principle of the Vbg_OK.

FIG. 12 (A) is the high dynamic range APS; (B) the characteristic curve of the high dynamic range APS; (C) is the leakage of low voltage MOS; (D) is the still/video/surveillance triple mode camera in the surveillance mode to have the wide dynamic range; (E) is the pipeline of the bit line read and parallel integration ADC conversion; (F) is the sampling of bit line for reset signal and holding for ADC conversion for integrated signal; (G) is the sampling of bit line for the integrated signal and holding for ADC conversion for reset signal; (H) is the digital correlated double sampling; (I) is the pipeline for the counting and read out pipelined parallel operation; (J) is the architecture for the still/video/surveillance triple mode camera.

FIG. 13 is the emergency pumping system for the SOC security of community; (A) the wireless toggle activating and clogging detectable smart pumping system; (B) is correlated double sampling in the open environment for the detection for clogs.

FIG. 14 is the digital temperature sensor for the temperature compensation in PVTANH design; (A) is the analog signal process of the architecture of the digital temperature sensor for the temperature compensation; (B) is the waveform of the timing diagram of the digital temperature sensor; (C) is the multi-phase clock generator of the digital temperature sensor; (D) is the SPC (Serial to Parallel Conversion) circuit for the algorithmic ADC or pipeline ADC. FIG. 15 is the unified approach for the Gain-Boost-Q (GBQ) or Q-Boost (Q) platform applying to the single-stage crystal oscillator, dual-stage LC oscillator and multi-stage ring oscillator; (A) is the gain-boost-Q platform of the amplitude-control and common-mode control type; (B) is the gain-boost-Q platform of the peak-control and valley-control type; (C) is the gain-boost-Q platform for the single stage oscillator of the amplitude-control and common-mode control type; (D) is the gain-boost-Q platform for the single stage oscillator of the peak-control and valley-control type; (E) is the gain-boost-Q platform for the single stage crystal oscillator of the amplitude-control and common-mode control type; (F), is the gain-boost-Q platform for the single stage crystal oscillator of the peak-control and valley-control type; (G) is the gain-boost-Q platform for the dual stage LC oscillator of the amplitude-control and common-mode control type; (H) is the gain-boost-Q platform for the dual stage LC oscillator of the peak-control and valley-control type; (G) is the gain-boost-Q platform for the dual stage LC oscillator of the amplitude-control and common-mode control type; (H) is the gain-boost-Q platform for the dual stage LC oscillator of the peak-control and valley-control type; (I) is the gain-boost-Q platform for the differential LC oscillator of the amplitude-control and common-mode control type; (J) is the gain-boost-Q platform for the differential LC oscillator of the peak-control and valley-control type; (K) is the gain-boost-Q platform for the conjugate LC oscillator of the amplitude-control and common-mode control type and the peak-control and valley-control type; (L) is the gain-boost-Q platform for the ring oscillator of the peak-control of the current mode; (M) is the gain-boost-Q platform for the ring oscillator of amplitude-control and common-mode control type and the peak-control of the voltage mode.

FIG. 16 (A) is the cross section of the varactor in the MOSFET accumulation mode; (B) is the voltage relations between control voltage of low pass filter (LPF) and the level shift substrate voltage of the varactor in the LCO; the Kvco is a nonlinear function; (C) is the block diagram of the clock data recovery (CDR) type frequency synthesizer to implement the VCO having the nonlinear Kvco; the phase adjustment and frequency adjustment are separately with only one PFD; (D) is the block diagram of the digital type nonlinear Kvco; (E) is the block diagram of the analog type nonlinear Kvco; (F) is the phase adjustment for the VCO of the frequency synthesizer in the gain-boost-Q platform of the amplitude-control and common-mode control type platform; (G) is the phase adjustment for the VCO of the frequency synthesizer in the gain-boost-Q platform of the peak-control and valley-control type platform.

### DESCRIPTION AND OPERATION

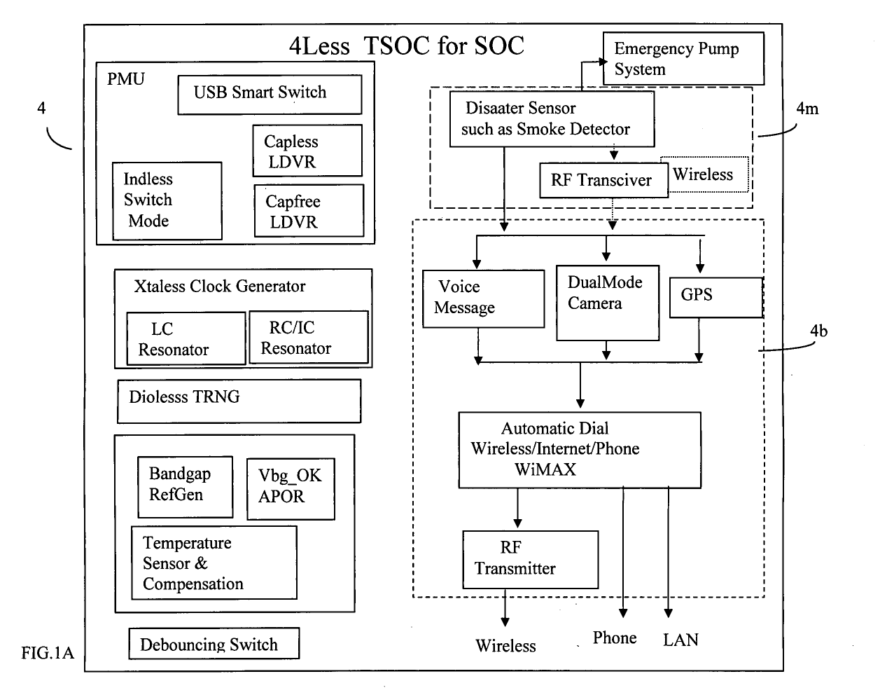

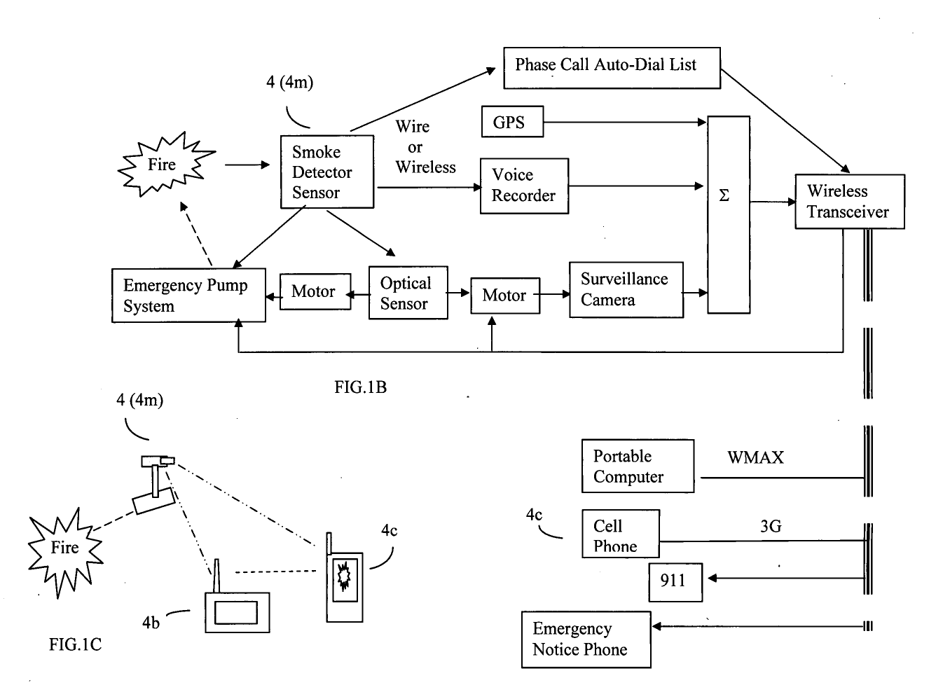

As shown in FIG. 1, the SOC (Security Of Community) is implemented with the 4Less TSOC (True System On Chip) technology. The TSOC has all the on board components been eliminated and the on-board circuits been replaced with the different implementations of the on-chip innovative new circuits. In contrast to the PSOC (Pseudo System On Chip) still having a lot of on-board components, the TSOC is referred to be True-SOC. The TSOC has the completely different circuit implementations for the same functions of the PSOC. To prevail the SOC, the system cost must be cheap. However, the cost of the on-board components is much higher than the chip itself. So, the only solution is the TSOC to have all the on-board component been eliminated. Without the TSOC technology, the SOC (Security Of Community) is just a dream.

For the SOC, all the supporting circuits are as shown in FIG. 1A. The Xtaless Clock is the on-chip clock generator having no external crystal to generate the accurate reference clock having the quality of the crystal clock. The PMU (Power Management Unit) has the Capless LDVR (Low Drop Voltage Regulator), the Capfree LDVR and Indless SM (Switch Mode Power Supply). The Capless LDVR and Capfree LDVR are the LDVRs having no external on-board capacitor. The Indless SM is the switch mode power supply having no external on-board inductor. The Dioless TRNG is the True Random Number Generator having no external Avalanche diode. The Vbg_OK and APOR generator is the APOR (Analog Power On Reset) signal being generated by the Vbg_OK signal.

The disaster sensor can be any monitoring disaster sensor. Here we use the fire disaster monitoring sensor, smoke sensor, as one illustrative example. As shown in FIG. 1B, the smoke sensor detects the smoke of the fire. The mobile smoke detector uses the wire or wireless to command the communicative base to activate the voice message, dual mode camera and GPS and the automatic dial, etc to report where the disaster and what the disaster to the emergency center, the house owner, 911, etc which has been programmed in the autodial list. The house owner, etc also can issue the command to the SOC to drive the motors to point the triple-mode surveillance camera and the emergency-pumping extinguisher to the firing disastrous place. FIG. 1C is the illustrative view of the SOC system. The smoke sensor can be either a mobile station 4m or an entire independent workstation 4. The cellular phone 4c shows the disaster scene. The house owner can use the keyboard to issues the command to the surveillance camera to take the views at the entire scene and the emergency pump to eject the extinguisher on the fire.

Now, we make the analysis of the individual components in the SOC. The oscillator has the LC and RC/IC oscillators. Today's accurate reference clock circuit is the crystal clock circuit. It is high Q mechanical oscillator to operate between the 25 MHz to 75 MHz. It cannot run in GHz that it needs PLL to boost up the frequency that it induces the phase noises to reduce the performance. However, the crystal cannot be integrated on the CMOS chip. So, the design trend is to design the clock circuit without the crystal to be Xtaless. The Xtaless clock is the clock circuit has no crystal that it can be integrated on CMOS.

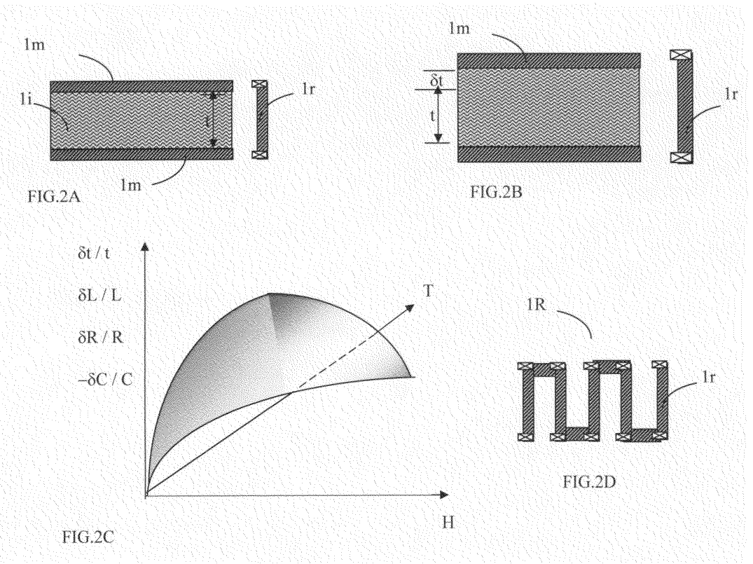

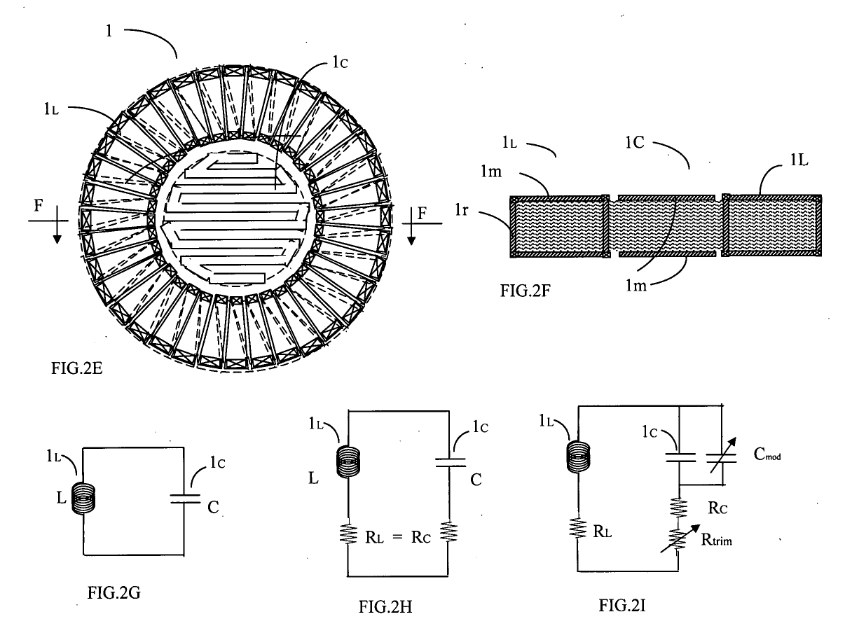

Both the temperature and humidity will change the electronic characters of the chip. As shown in FIG. 2A, before the variation of the temperature and/or the humidity, the thickness of the isolation is t. As shown in FIG. 2B, the temperature increases and/or the humidity increases, the thickness of the insulation increases to be t+δt. As we apply the fundamental principle of the thickness variation of the temperature and humidity to the R, L and C, as shown in FIG. 2C, δt/t causes the variance of increase the inductance of δL/L and the increase of the resistance of δR/R and decrease the capacitance to be −δC/C. It is noted that the δC/C decreases and both the δL/L and δR/R increase. It is the fundamental of the self-compensation of the RC resonator and LC resonator. Furthermore, it is very complex 2-D temperature-humidity that it is impossible for the temperature trimming bits and the humidity trimming bits to make the temperature-Humidity (TH) compensation. It must use the self-compensation techniques for the RC and LC.

For the RC resonator, the RC constant after the increase of the temperature and/or humidity is

(R+δR)(C+δC)=RC(1+δR/R)(1+δC/C)=RC[1+(δR/R+δC/C)+(δR/R)(δC/C)]

δR/R˜δt/t; δC/C˜−δt/t

(R+δR)(C+δC)−RC[1+(δt/t−δt/t)]˜RC=constant

As shown in FIG. 2D is the self-compensated resistor design.

For the LC resonator, the LC constant after the increase of the temperature and/or humidity,

(L+δL)(C+C)=LC(1+δL/L)(1+δC/C)=LC[1+(δL+δC/C)+(δL/L)(δC/C)]

δL/L˜δt/t; δC/C˜−δt/t

(L+δL)(C+δC)˜LC[1+(δt/t−δt/t)]˜LC=constant

As shown in FIG. 2E and FIG. 2F, it is the self-compensated LC resonator design. As shown in FIG. 2F, it is the cross-section of the LC resonator. The inductor 1_{L} has the cross section area to be proportional to the variance of δt/t. The inductance of the inductor 1_{L} is proportional to the cross section area that the inductance of the inductor 1_{L} is proportional to (t+&t/t). On the contrary, the capacitance 1_{C} is reverse proportional to the variance of the δt/t. For the small variance of δt, the variance of the inductance δL and the variance of the capacitance δC are mutually compensated to have the self-compensation.

For the LC resonator, it uses the self-compensated LC resonator to have the self-compensation. As shown in FIG. 2E, the inductor 1_{L} having the self-compensated capability is in the shape of toroid. The toroid is in the ring type closed shape. Actually it can be any closed shape as long as it is the vertical section coil. However, it must be the closed form such that all the magnetic streamline is confined in the coil of the toroid and the external circuits will not have any impact or the impact is minimized on the inductance of the inductor.

It is very important that the magnetic line to be confined in the toroid coil. If the magnetic streamlines go out the coil, there is no way to terminate it. The magnetic of the inductor will interfere with the surrounding circuits and induce a lot of noise to the LC resonator. For the LC resonator, such kind noise incurred by the open domain magnetic streamline is not acceptable. It will generate the excess phase noise and clock jitters. So the on-chip toroid coil is invented for the self-compensated LC resonator. The closed magnetic streamline to have less noise induced by the surrounding circuit. For the open-space flat inductor, the surrounding circuit modifies the inductance. For the toroid shape inductor, the inductor has the inductance that is independent of the surrounding circuit. However, the inductor of toroid still varies according to the variance of the temperature and humidity.

FIG. 2G is the ideal LC resonator. However, the inductor has the long string in the coil. So, the coil has the parasitic resistance R_{L}. We develop the temperature cancelling technique. Referring to FIG. 2H,

ω(T)=ωₒ[(CR_{L}(T)**2−L)/(CR_{C}(T)**2−L)]**½
as R_{L}(T)=R_{C}(T), ω(T)=ωₒ
   To have the fo to be independent of the temperature, R_{L}=R_{C}. To have R_{C} for the capacitor in FIG. 2H, as shown in FIG. 2E, the capacitor 1_{C} is in the shape of the strips. As shown in FIG. 2F, the strips 1m of the capacitor 1_{C} are overlapping with each other to constitute the capacitor. To have the fine tune of the resistor to have R_{L}=R_{C}, as shown in FIG. 2I, the trimming resistor Rtrim is added in series with the capacitor resister R_{C}.

To make the on-chip LC resonator type clock, we need to make the breakthrough in the LC resonator design. There is one wrong concept that the clock chip needs to have high-Q resonator made of the high-Q components. The formal golden rule is the Q of the component must be 4 times larger than the Q of the resonator. For the crystal, the Q is 1,000,000. For the on-chip spiral winding inductor, the Q is only 10. For the previous wrong concept, it is impossible to use Q=10 inductor to make the high Q clock reference. However, the previous concept on the LC resonator is completely wrong. It is based on the implicit assumption on-board design style free-running oscillator. It is not the on-chip gain-boost-Q circuit design.

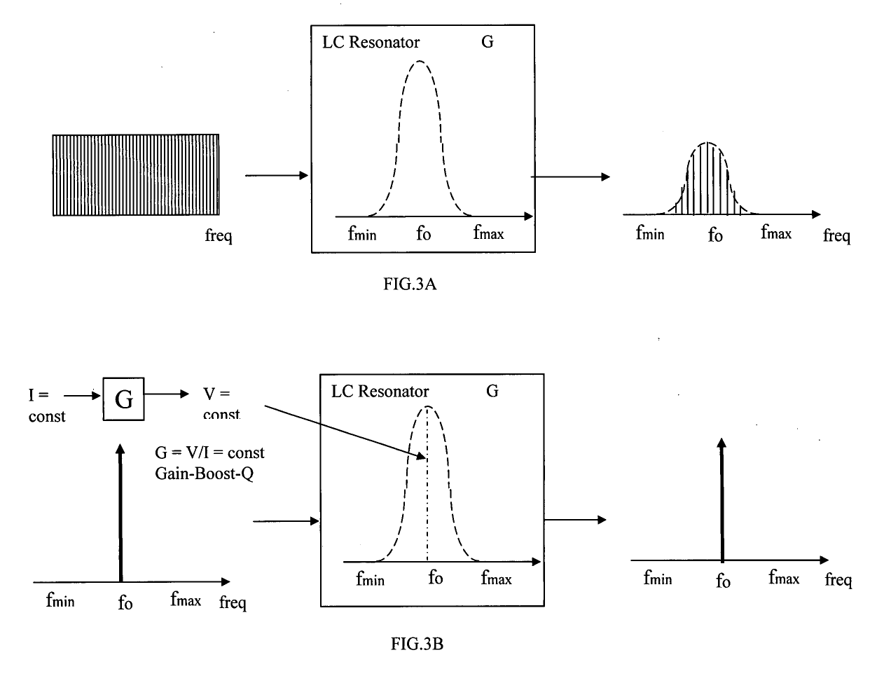

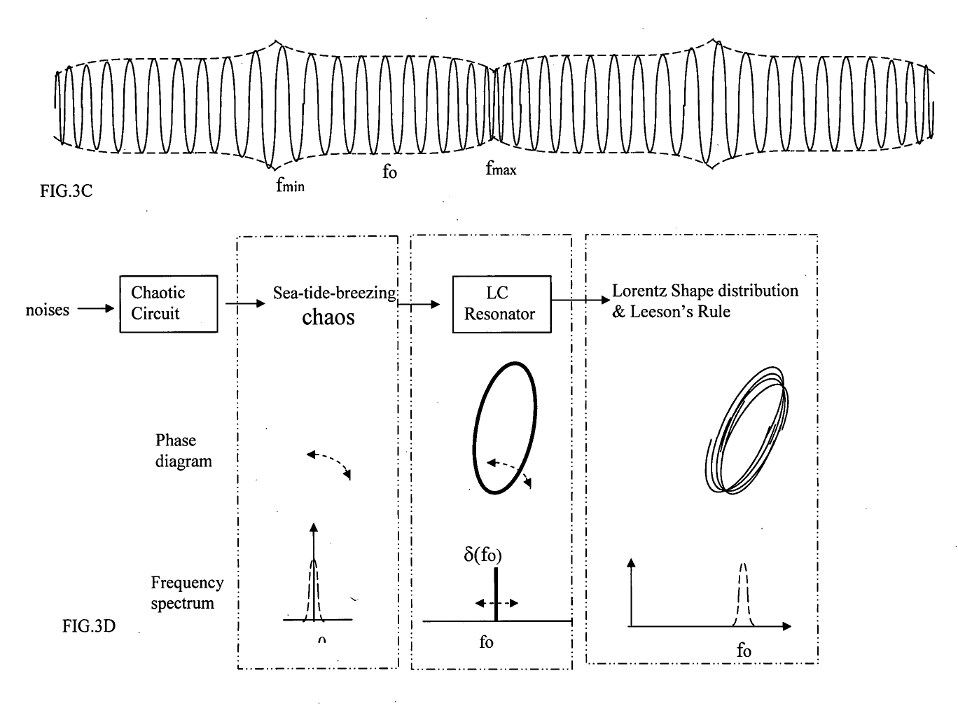

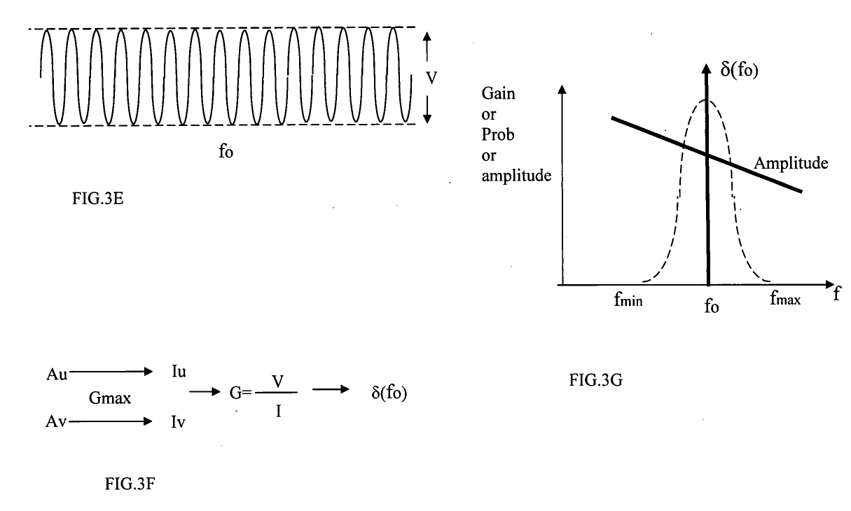

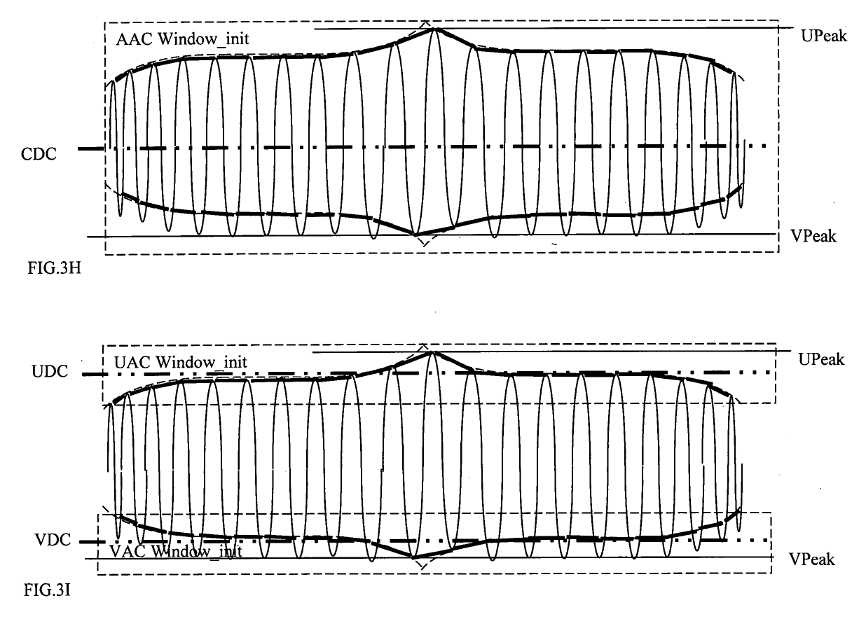

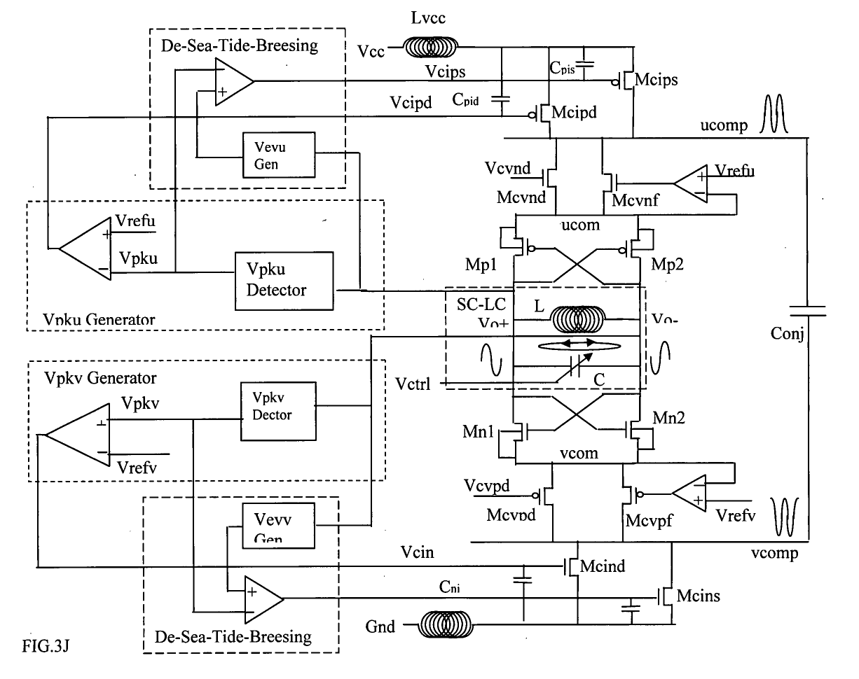

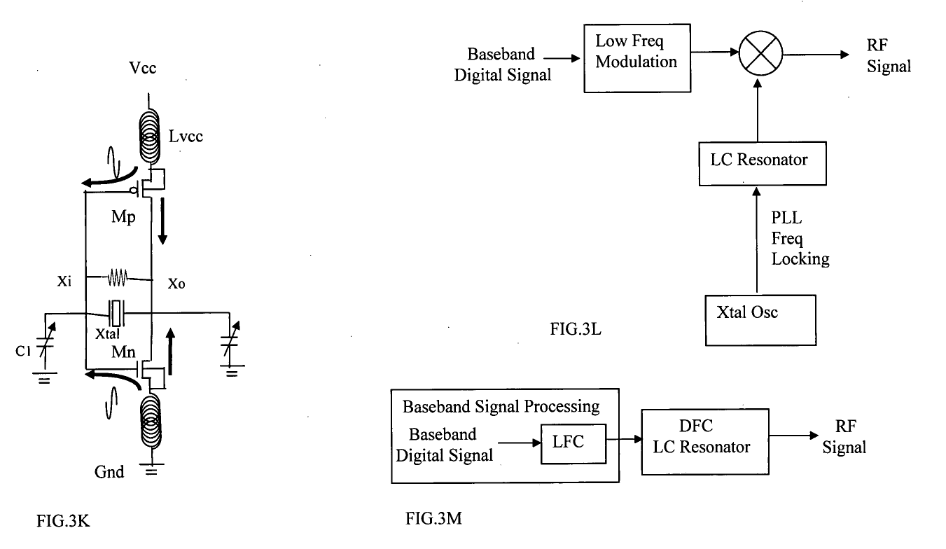

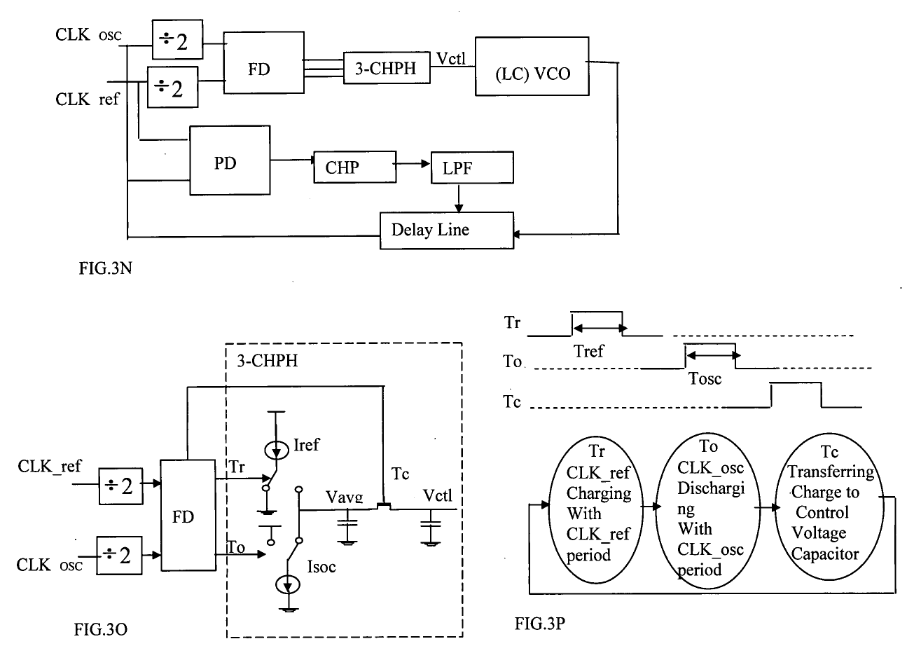

However, as shown in FIG. 3A, the wrong concept has one implicit assumption that the LC resonator is free-running LC resonator. As the free running is the old-fashioned on-board design style does, the LC resonator is one block diagram of bandpass filter. The LC resonator circuit has white noise as input and the LC resonator is a bandpass filter.

At the system-on-board time, the controlling circuit costs a lot money. So it is reasonable to have the resonator free running. However, in the system-on-chip SOC design style, the controlling circuit cost means nothing. So, as shown in FIG. 3B, we use the gain-boost-Q and anti-sea-tide-breezing circuit to boost the Q of the on-chip LC resonator.

The fundamental breakthrough of the gain-boost-Q is to have the different interpretation of the basic gain function of the LC resonator. We re-investigate the basic gain function G for the RLC resonator is

G=V/I=1/[1/R+j(ωC−1/ωL)]

It is noted that this equation doesn't put the constraint for the low-Q LC resonator cannot generate the high-Q oscillatory signal. As shown in FIG. 3B, on the contract, this equation does say, even at low-Q, the LC resonator still can generate the high Q signal as long as we can fix the gain G to be a constant. As G=Gmax, it has only one frequency oscillate which is oscillate at ω=ωo. Now, the key issue for the LC resonator to generate the high Q oscillatory is to keep the gain G to be constant all the time.

Fixing G=Gmax=>keep oscillation at ω=ωo

The traditional free-running LC resonator actually is free-wandering LC resonator. The oscillations wandering in the LC resonator have the possibility to be any gain. Now, in the reverse process, we fix the gain of the oscillation to have the pure frequency oscillation to become the high-Q LC resonator to have all the oscillation oscillates at the frequency ω=ωo. So, we refer the new LC resonator to be the gain-boost-Q LC resonator. So the gain-boost-Q LC resonator is no more a free-wandering bandpass filter circuit. All the previous Q concepts and conclusions fail to apply to the gain-boost-Q LC resonator circuit.

We have one explanation why we can use low-Q LC resonator to generate the high-Q oscillation with the gain-boost-Q technique. The high-Q crystal oscillator is a doghouse. The dog in the doghouse cannot run randomly that you can locate the dog easily. The dog is in the high-Q oscillation mode. The low-Q LC oscillator is a big house. The dog in the big house can run randomly and free wandering that you cannot find out the dog easily. The dog is in the low-Q oscillation mode. However, as we use one belt to tight the dog to the door. The dog even cannot move. So, even the dog in the big house, we still can locate the dog exactly. The dog is in the gain-boost-Q superior high-Q oscillation mode now. The problem is what is the belt is. The belt is Gmax=V/I. We need to control G(t)=Gmax const all the time. Then, the LC oscillation oscillates at f(t)=fo, always and exactly. This is the gain-boost-Q superior high-Q you can get even with the low-Q LC resonator.

Furthermore, as shown in FIG. 3C and FIG. 3D, as we inspect the spectrum of the free-running/free-wandering output oscillation, it shows there is the universal Lorentz curve. We make analysis of the spectrum with the histogram view. There is famous golden rule between the amplitude and frequency for the analog signal. As shown in FIG. 3G, as the amplitude of the oscillation is large, the oscillation frequency is small. As the amplitude of the oscillation is small, the oscillation frequency is large. As shown in FIG. 3C, we reconstruct the free-running/free-wandering oscillation in time domain from the Lorentz curve in FIG. 3G. As shown in FIG. 3D, the bandwidth is very narrow that the modulation frequency of the sea-tide-breezing waveform is very slow long period modulation. The envelop of the peaks of the oscillation shows a sea-tide-breezing waveform. The sea-tide-breezing mechanism is a natural generic phenomenon of the chaos. The chaotic mechanism of the free-wandering LC resonator is shown in FIG. 3D. The noises of the LC resonator input the parametric chaotic circuit in the LC resonator and generate the sea-tide-breezing waveform which is overlapping on the DC voltage power supply.

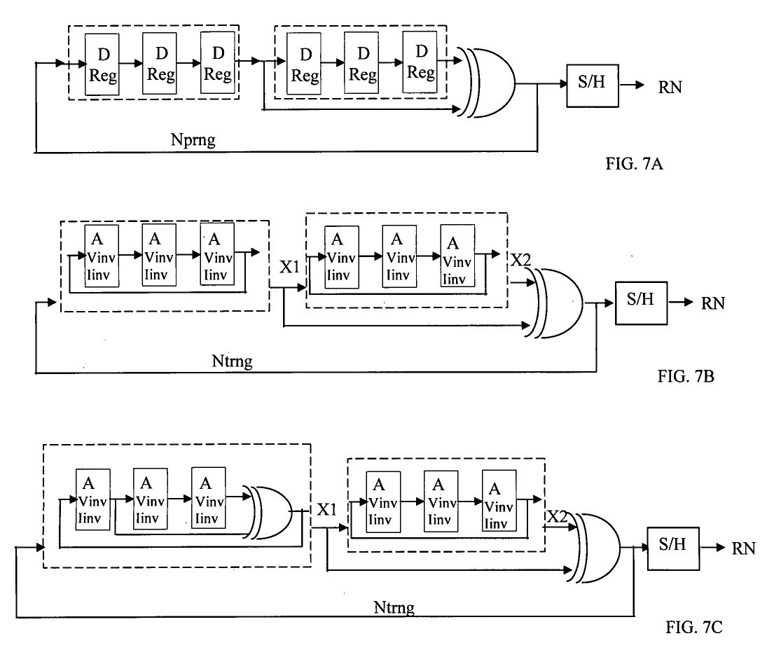

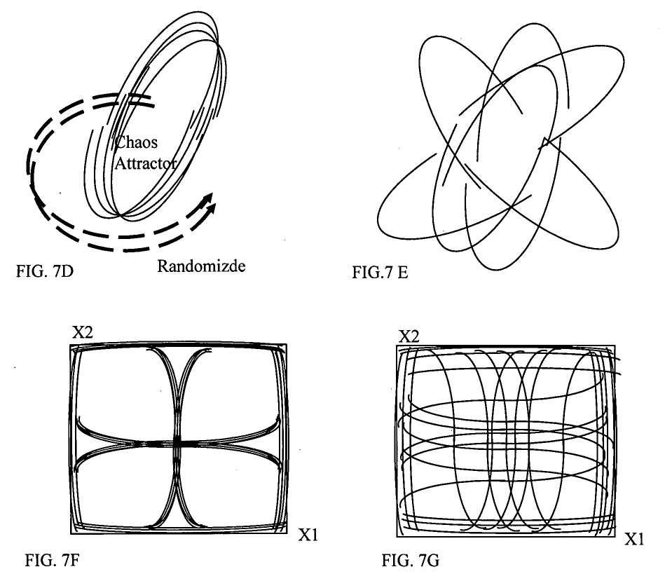

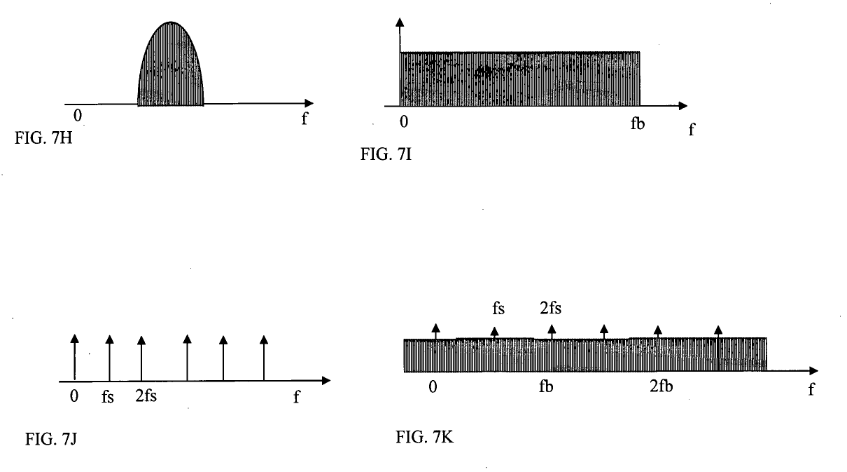

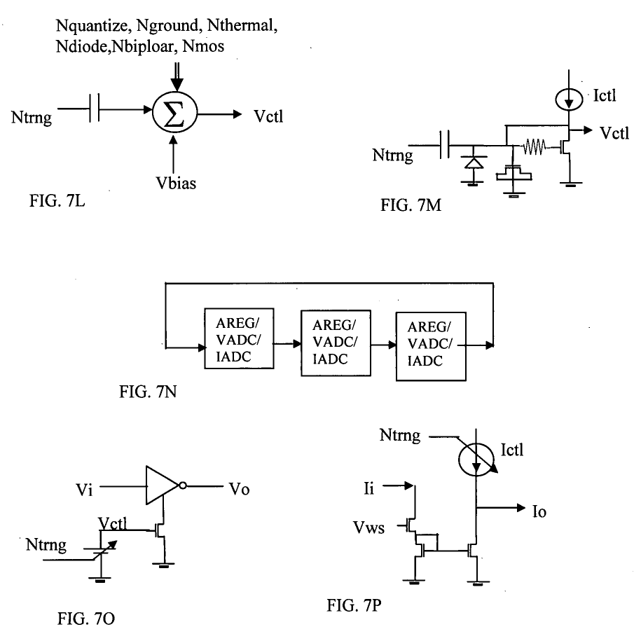

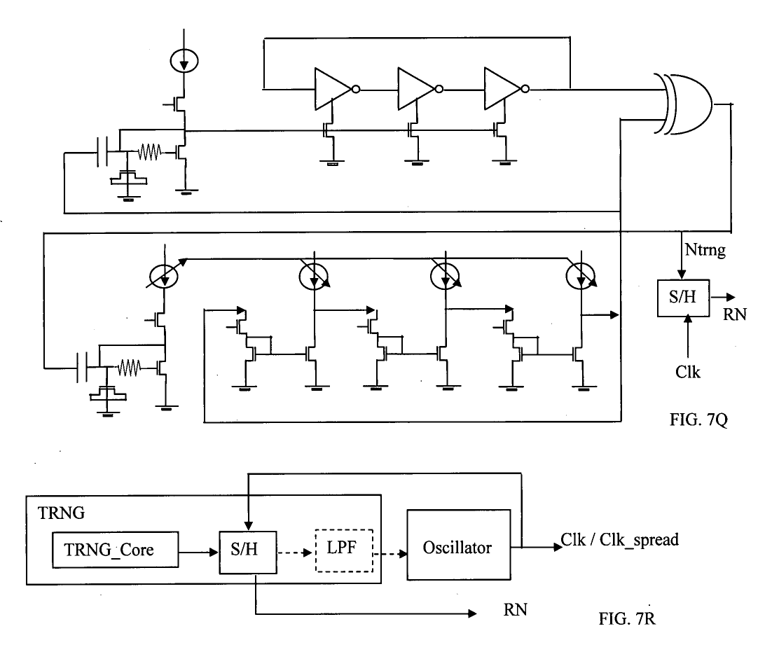

Until now, nobody in the world understands the chaos in the oscillator. They fail to recognize the oscillator problem. They don't know the chaotic mechanism in the oscillator. To study the gain-boost-Q LC oscillator, we need to have the multi-disciplinary of the chaos, RNG and oscillator. From the chaotic research on the RNG (Random Number Generator) as shown in FIG. 7D and FIG. 7E, the noise will not causes the problem unless there is a chaotic mechanism or chaotic circuit. The noise is fuel; the chaotic circuit is engine. If it has only the fuel without engine, the working power cannot be generated. If it has only the noise without the chaotic circuit, the random number cannot be generated. Before, it uses the ring oscillator pulsing the noise, the RNG (Random Number Generator) circuit just quenched and stopped to work. It has noises, but it does have the chaotic circuit engine. However, with the chaotic circuit as shown in FIG. 7B and FIG. 7C, the chaotic circuit engine starts to cranking, the fuel noise adds up to randomized the chaos to generate the random number. Another practical case is the crystal oscillator circuit. The conventional crystal oscillator circuit can be consider to be the single stage ring oscillator. With the addition of the resistor to set the operating point at the biasing point, the crystal oscillation is actually is a random number generator circuit. However, the crystal circuit works. The thermal noise of the resistor doesn't create the random number. Instead of the crystal oscillator generates a high-Q oscillator curve. The reason is the feedback of the crystal circuit can suppress the thermal noise to generate the high-Q oscillation. The same principle can be applied to the LC resonator. We can use the feedback circuit to suppress the noise to generate the high-Q oscillation. For the LC resonator, the noise suppression circuit is the AC type feedback loop anti-sea-breathing circuit; the high Q boosting circuit is the DC type feedback loop gain-boosting-Q circuit.

As shown in FIG. 3C and FIG. 3D, the sea-tide-breezing power supply inputs into the LC resonator, generate the free-running/free-wandering oscillation having the Lorentz shape spectrum. For the high-Q LC resonator, the bandwidth of the Lorentz shape spectrum, it means the sea-tide-breezing waveform is in very low frequency. For the low-Q LC resonator, the sea-tide-breezing waveform has higher bandwidth and higher frequency. But in either high-Q LC resonator or the low-Q LC resonator, the sea-tide-breezing waveform frequency is very low and it is very easy to clean out with today high-speed high gain OPAMP. As shown in FIG. 3C and FIG. 3E, as the sea-tide-breezing waveform is cleaned out, the waveform in FIG. 3C becomes the waveform in FIG. 3E to be the high purity waveform oscillating at the frequency fo.

As shown in FIG. 3H and FIG. 3I, there are two anti-sea-tide-breezing ways to clean out the sea-tide-breezing waveform. As shown in FIG. 3H, it is the common-mode-voltage control working together with the amplitude-control to get rid of the sea-tide-breezing in the LC resonator. CDC is the common mode DC voltage. AAC represent the amplitude AC window. It was the our prior application and had reduce the jitter of free-running/free-wandering LC oscillator from 400 ppm to be 90 ppm at 1 GHz oscillation frequency. To make the further improvement, the new anti-sea-tide-breezing circuit configuration/architecture is invented.

As shown in FIG. 3F and FIG. 3I, the upper power sea-tide-breezing waveform and the valley ground sea-tide-breezing waveform are cleaned out separately. UDC is the upper DC voltage; VDC is the valley DC voltage. UAC is the upper AC amplitude window; VAC is the valley AC amplitude window.

Comparing FIG. 3I with FIG. 3H, the amplitude AC window is much narrow range that it is much easier to clean out the sea-tide-breezing waveform. The difference of the UDC and VDC is the amplitude. The middle point of the UDC and VDC is the CDC. So, the feedback control of FIG. 3I is equivalent to the amplitude control and commode-mode control. However, it has much better control scheme. It can differentiate between the upper sea-tide-breezing waveform disturbance and the valley sea-tide-breezing waveform disturbance and clean out them much efficiently. So, the clock jitter will be further reduced down to be less 10 ppm.

FIG. 3F shows the signal flow block diagram of the anti-sea-tide-breezing circuit configuration and architecture. From the upper peak of the amplitude Au, the supply current Iu is injected into the LC resonator. From the valley peak of the amplitude Av, the supply current Iv is discharged form the LC resonator. Actually, Iu=Iv=I. The cooperation of Iu and Iv will control the amplitude Au, Av and keep the CDC=(UDC+VDC)/2. FIG. 3I shows the anti-sea-tide-breezing circuit. Furthermore, the UAC and VAC will shrink down as the sea-tide-breezing waveform is cleaned out. As shown in FIG. 3I and FIG. 3J, the circuit is to detect the Upeak and Vpeak. Finally, the Upeak=UDC and Vpeak=VDC. However, the AAC window still keeps the same.

As shown in FIG. 3J, the SC-LC is the self-LC-compensated, gain-boost-Q, anti-sea-breathing LC resonator for the principle illustrated in FIG. 3I. The upper Vpku peak detector generates the peak value Vpku. The Vpku is compared with the upper amplitude setting reference value Vrefu. If Vpku<Vrefu, the MOS device Mcipd will inject the current into the LC resonator. It is to control the UDC voltage level in FIG. 3I to be the DC level adjustment.

The Vevu is to generate the envelop of the peaks of the oscillation which is the UAC curve in FIG. 3I. The UAC is compared with Vpku to adjust MOS Mcips to inject the AC current into the LC resonator to compensate to clean out the UAC upper sea-tide-breezing waveform to be a straight line.

Similarly, The valley Vpkv valley detector generates the valley value Vpkv. The Vpkv is compared with the valley amplitude setting reference value Vrefy. If Vpkv>Vrefy, the MOS device Mcind will discharge more current from the LC resonator. It is to control the VDC voltage level in FIG. 3I to be the DC level adjustment.

The Vevv is to generate the envelop of the valleys of the oscillation which is the VAC curve in FIG. 3I. The VAC is compared with Vpkv to adjust MOS Mcins to discharge the AC current from the LC resonator to compensate to clean out the VAC valley sea-tide-breezing waveform to be a straight line.

To have the control of G=V/I to have the gain-boost-Q for any LC resonator, we are not only to control the current I but also to control the voltage V. The above-discussed circuits are for the current, we need more circuit to control the variance of voltage V. During the switching of the MP1 and MP2, the peak value of the oscillation is to follow the ucom node voltage. During the switching of the Mn1 and Mn2, the peak value of the oscillation is to follow the vcom node voltage. To minimize the variation V in G=V/I, it is equivalent to minimize the variance of the voltages at nodes ucom and vcom.

The feedback loop for Mcvnf and Mcvpf are single stage feedback look. It is not only fast but also unconditionally stable. To speed up the response of the feedback loop control, we further separate the DC current from the AC current. The large MOS Mcvnd is biased with the DC voltage Vcvnd; the large MOS Mcvpd is biased with DC voltage Vcvpd. The AC variation of the ucom node voltage is suppressed with the feedback of the MOS Mcvnf. The AC variation of the vcom node voltage is suppressed with the feedback of the MOS Mcvpf. As both Mp1 and Mn1 are on or both Mp2 and Mn2 are on, there is crowbar short current. The node ucom voltage decreases instantly and the node vcom voltage will increase instantly. The source follower of Mcvnd and the feedback loop of Mcvnf will push the variance to the node ucomp. The source follower of Mcvpd and the feedback loop of Mcvpf will push the variance to the node vcomp. The voltage of ucomp and vcomp are conjugate with each other. There is a big capacitor Conj to adapt the instant conjugate voltage variance efficiently.

So, the ucom and vcom are kept to be almost constant voltage that the amplitude of the oscillation of Vo+ and Vo− are kept to be constant, too. The current is almost to be constant and the amplitude is almost const that the Gain G is almost to be constant. So, the gain-boost-Q has very pure oscillation. With the Mcipd, Mcips, Mcind and Mcins, the current I in G=V/1 equation is under well control to keep to be constant. With the Mcvnd, Mcvnf, Mcvpd and Mcvpf, the voltage V in G=V/1 equation is under well control to keep to be constant. So, the gain G of the LC resonator is to keep to be the constant. Furthermore, the reason to keep the ucom and vcom to be constant is due to the switching noise of the parametric inductance of the bonding wire and pin. As shown in FIG. 3K, even for the crystal oscillator, there is serious switching noise injecting into the crystal oscillator. That is the reason why we can use the gain-boost-Q technology to boost up the performance: (1) get rid of the switching noise of the inductor; (2) keep the constant V and I, boost up the Q of the crystal oscillator.

It is noted that from the oscillation amplitude to control the inject current, the LC resonator automatically put the G=Gmax to operate at the oscillation frequency fo automatically. The control circuits control the gain G to be constant to make the oscillation at the same condition all the time to have the same oscillation all the time. The oscillation is pure. It is equivalent to have the high-Q. So we refer this circuit to be the gain-boost-Q LC resonator.

This gain-boost-Q LC resonator is not only use for the Xtaless Clockgen circuit but also has very important application in the RF transceiver circuit design. It can make the revolution in the RF transceiver design. As shown in FIG. 3L, it is today's most efficient direct conversion transceiver architecture. The digital baseband signal goes through the low frequency modulation to generate the baseband analog signal. For the signal side, the low frequency modulation includes a lot of circuits such as the preprocessor of the up sampling and down sampling of the baseband signal, then follows the digital low pass filter serving the pulsing shaping, then DAC. For the carrier side, the LC resonator use PLL to lock with the Xtal Oscillator as the frequency reference. Then the baseband analog signal is mixed with the carrier with the multiplier of mixer to generate the RF signal. Why the traditional transceiver has to use such complex architecture and circuit configuration to generate the RF signal? It comes back the essential problem of the oscillation problem: the oscillation frequency cannot generate accurately. It has to lock with the Xtal Clock as the frequency reference. Furthermore, the Xtal Clock is actually a mechanical oscillator. For the mechanical oscillator, it only oscillates at the low frequency. It cannot be directly use in the RF transceiver.

Now, for the Xtaless clock generator, it means that we have the capability to control the oscillation frequency accurately for the LC resonator as Xtal Clock does. However, the LC resonator is an electronic resonator. It has the high frequency to use in the RF transceiver directly. With such kind accurate control resonator frequency operating at high frequency, the new generation RF transceiver architecture is generated. It is the direct-modulation architecture.

As shown in FIG. 3M and FIG. 2I, the baseband digital signal applies to the tunable capacitor Cmod directly to vary the oscillation frequency of the LC resonator to generate the. It is DFC—Digital to Frequency Conversion. Comparing the new architecture with the traditional architecture, it saves a lot of power and chip area. Furthermore, if the Baseband Digital Signal in FIG. 3M is the random number output RN as shown in FIG. 7B and FIG. 7C, the output clock is the clock having the spread spectrum effect to get rid of the electric magnetic wave emission problem.

For the LC resonator to lock with the other reference clock, as shown in FIG. 3N, the frequency synthesizer has phase detector (PD) and frequency detector (FD) to work separately. Frequency detector FD is to detect the frequency deviation with the period of the clock. Phase detector PD is to detect the deviation of the phase and adjust the delay line of the oscillation clock to match with the phase of the input reference clock. CHP is charge pump for the phase detector loop and LPF is the low pass filter for the phase detector loop. 3-CHPH is the 3-way charging pump and the holding capacitor to hold the control voltage for the VCO.

Referring to FIG. 3N, FIG. 30 and FIG. 3P, 2 divide the clock, the “on” time Tref, Tsoc become the periods of the CLK_ref and CLK_osc. Tr signal switches on the Iref for the time Tref. To signal switches on the discharging current for Tosc. Then Tc signal switching on to transfer the charge to the control voltage Vctrl. It is noted that the ratio of Iref/Iosc is the frequency ratio of the CLK_osc and CLK_ref. As Iref=Iosc, at equilibrium, Tref=Tosc. It means that the CLK_ref and CLK_osc have the same frequency, fref=fosc. FIG. 3P shows the state diagram of the frequency detector. The switch on time of Tr, To and Tc signals have no overlapping time. The charging state, discharging state and charge sharing state have to follow in sequence.

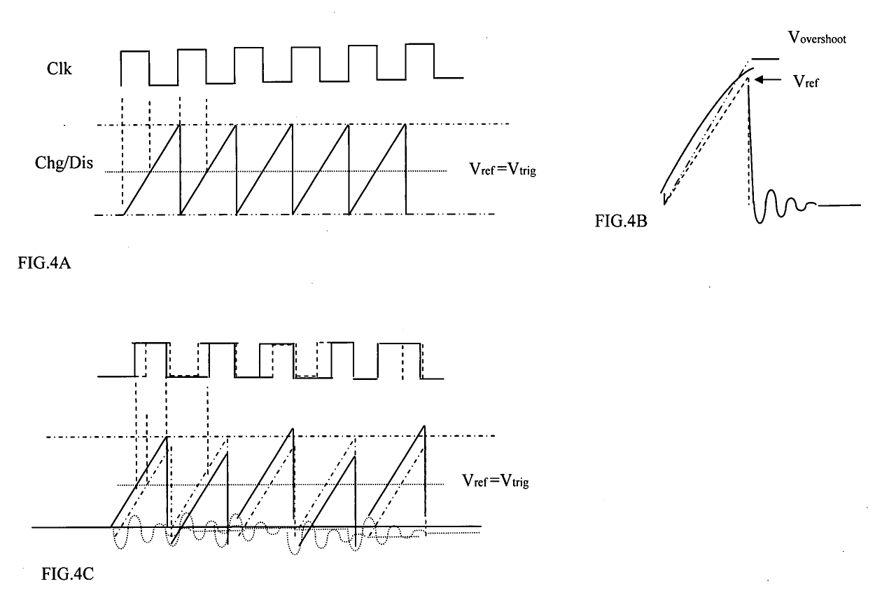

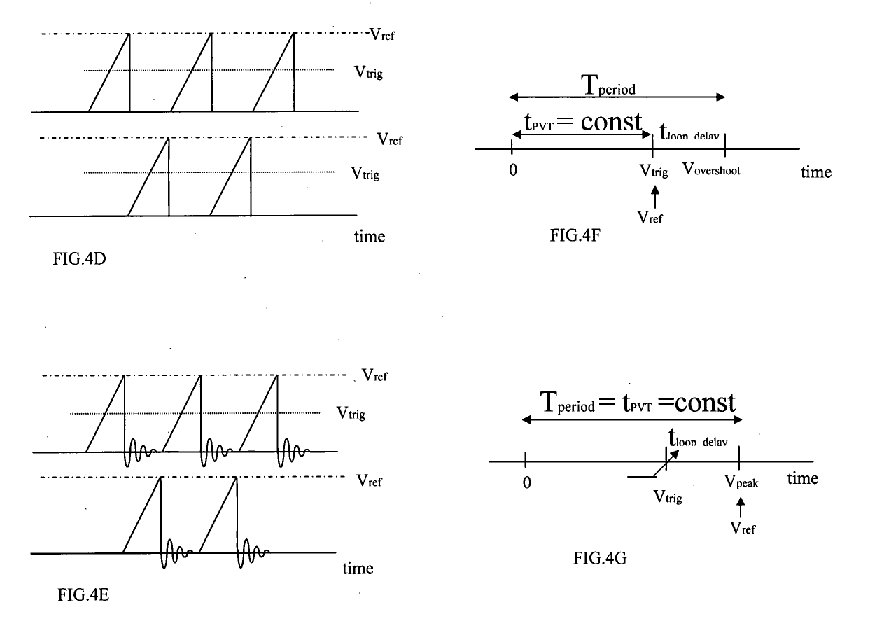

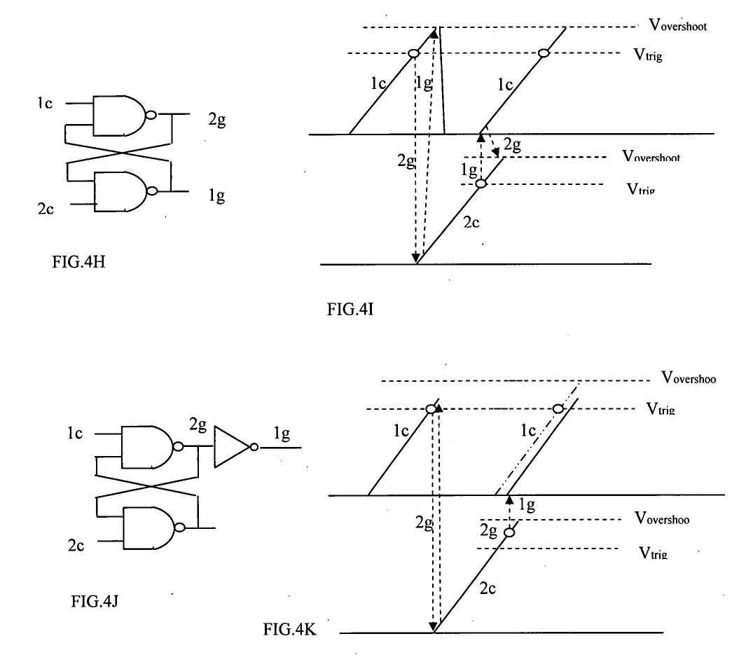

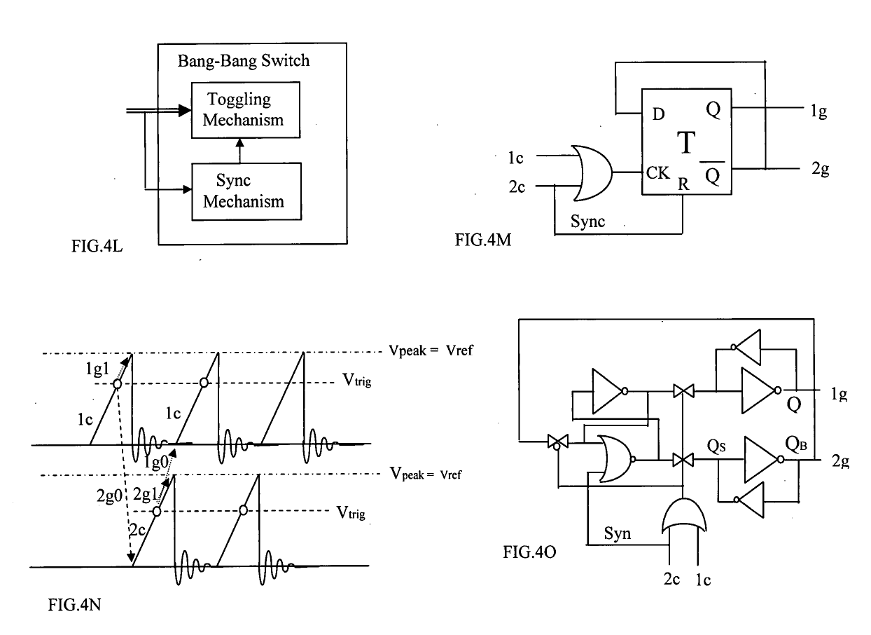

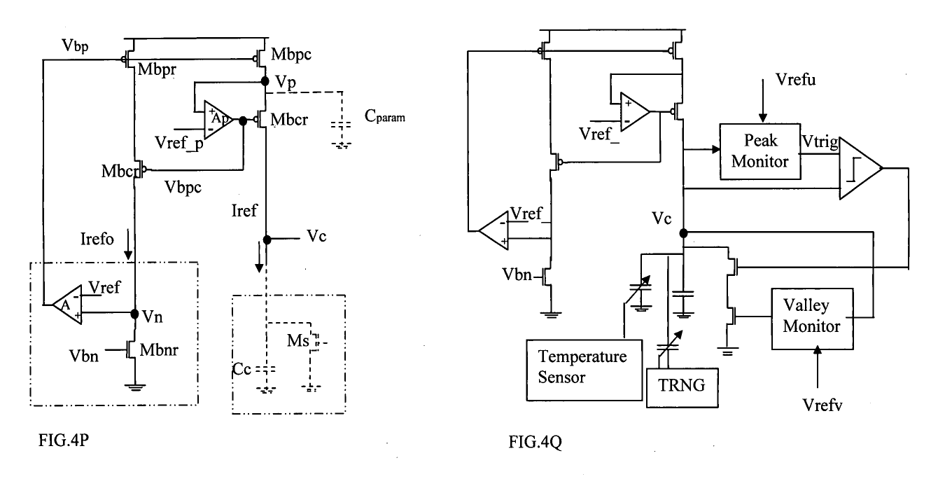

FIG. 4 shows the Xtaless RC/IC resonator. As shown in FIG. 4A, the concept is very simple. It uses the constant current to charge a capacitor, the capacitor voltage increases linearly. As the capacitor is equal to and larger than the reference voltage Vref, the comparator is flip to the other state. The reference voltage Vref is the trigger voltage Vtrig. As shown in FIG. 4A, the conventional RC/IC oscillator is to charge and discharge periodically to generate a triangle voltage wave. A reference voltage slices the triangle voltage wave to generate the periodic clock.

However, as shown in FIG. 4B, the real circuit has the nonlinear effects. Before, the RC/IC oscillator is used as low performance oscillator in KHz range. Now due to a lot of company having no RF design experience to design LC resonator, so they want to push the RC/IC to the 200 MHz range. For the specification of the RC/IC oscillator, the clock jitter is less than the 4% or clock period, i.e., 200 ps. It is a high performance requirement for the RC/IC resonator having the nonlinear curve as shown in FIG. 4B. It is a tremendous challenge for the circuit design of RC/IC resonator. So, we make the review of the limit on the performance of IC/RC oscillator and make the fundamental breakthroughs for the RC/IC algorithm, architecture and circuit configuration.

As shown in FIG. 4B, in the realistic chip, the charge and discharge curve of RC/IC oscillator is never ideal as FIG. 4A. They cause the degrade of the RC/IC oscillator. First, the charging curve of the charge of the RC/IC oscillator is not a ideal straight line as specified in the original RC resonator specification. It is a nonlinear curve. At low voltage, the charging rate is higher. At high voltage, there is the saturation phenomenon that the charging rate is slower. For the discharging curve, the discharging rate is higher at high voltage and the discharging rate is slower at low voltage. As shown in FIG. 4P, the nonlinear curve is due to the charge sharing between the node Vp and Vc.

Even worse, as shown in FIG. 4B, there is oscillation due to the ground bounce being caused the parametric inductance of the bonding wire and pin. The oscillation needs settling time to settle down to a finite value. As shown in FIG. 4C, in the real chip, the charging curve and discharging curve has the all the above three factors, nonlinear charging, voltage bouncing and settling time, to destroy the performance of the RC/IC resonator. The oscillation curve for the RC/IC resonator is an up and down wandering curves. Accordingly, the corresponding clock has the serious jitter problems. That is the reason why the RC/IC oscillator was restricted to be the low performance and low clock frequency application before.

However, under the requirement of the on-chip Xtaless oscillator, we make the innovation of the technology breakthrough for the RC/C oscillator. As shown in FIG. 4D, to solve the voltage bouncing and settling time problem, there are two banks of oscillator. The two banks are charged and discharged alternatively. As shown in FIG. 4E, the voltage bouncing effect in the discharging process has enough time to damp out that all the charging processes can start with exactly the same initial voltage level. The jitter of the clock is mainly due to there is no enough settling time in the oscillator loop. Comparing with the jitter caused by the settling problem, the thermal noise is just a minor issue.

As shown in FIG. 4F, it is the algorithm of the conventional RC/IC oscillator. The conventional RC/C oscillator has the slicing voltage Vtrig to be the reference voltage to control the clock period. After the triggering at the Vref voltage, there is a free running time of loop delay T_loopdelay for the switching off process of the RC/IC oscillator. So the actual time period of the RC/IC oscillator is

T_{—period}=C(Vref/I)+T_{—loopdelay}=Ck(Vbg/Ibg)+T_{—loopdelay}=tₚᵥₜ+T_{loopdelay}

The tₚᵥₜ is C(Vref/I) to be controlled by the Vref. Both Vref and I are derived from the bandgap reference circuit. Vref, I, Vbg and Ibg are constant over process, voltage and temperature variations, So the tₚᵥₜ is compensated to be the constant over process, voltage and temperature. However, the T_{—loopdelay} still varies over process, voltage and temperature. So, there is the fundamental mistakes in the conventional RC/IC oscillator. For low frequency and low performance RC/IC oscillator, the loop delay T_{—loopdelay} is only a small portion of clock period to be neglected. However, for the high frequency oscillation, the T_{—loopdelay} is a big portion of the T_{—period}. It cannot be neglected any more. So, we make innovation of the new algorithm for the RC/IC oscillator.

As shown in FIG. 4G, we set the Vₚₑₐₖ to be the V_{ref}. The T_{—loopdelay} is included in the tpvt. To compensate for the variance of the loop delay T_{—loopdelay}, the triggering voltage Vtrig is adjusted to keep the Vₚₑₐₖ to be the constant of reference voltage V_{ref}.

T_{—period=C}(V_{trig}/I_{ref})+T_{—loopdelay}=C(Vref/Iref)=tₚᵥₜ

For the innovation of this new algorithm and architecture, we need the peak detector to detect the peak voltage Vₚₑₐₖ first, then comparing the Vₚₑₐₖ with the reference voltage V_{ref} to adjust the V_{trig} to keep the clock period T_{—period} to be constant.

To avoid the settling problem, the new architecture uses the two-bank architecture. For the two-bank architecture, there is the toggle mechanism problem. As shown in the FIG. 4H, the SR latch is adopted for the low speed RC/IC resonator in kilo Hertz range. It has the symmetry property in architecture and half duty cycle. As shown in FIG. 4I, the SR latch input (1c signal) is to turn off the switch (2g signal) of the other bank to charge first then turn on its own switch (1g signal) to discharge the voltage of its own bank, and vice versa. This SR latch mechanism is only valid for the slow frequency RC/IC oscillator. It cannot be used for the high frequency operation. For the high frequency RC/IC oscillator, the switch signal sequence is no more valid. This switching process is relying on the delay which is sensitive to the process variation. Even worse, the circuit has the hang up in the undetermined state in high-speed clock operation. The switching signal may overlap and make the oscillator to hang up and stop to oscillate. So, as shown in FIG. 4J, in the conventional high frequency RC/IC oscillator, it uses an inverter to substitute for the SR latch mechanism to walk around the SR hang-up problem in the undetermined state. However, this add-on inverter to SR latch solution loses the symmetry of mechanism and loses the half duty cycle clock property as shown in FIG. 4K.

To make the technology breakthrough, we come back to the fundamental property and essential characteristics of the bank-bank switch. As shown in FIG. 4L, the bank-bank switching mechanism is divided to be the toggling mechanism and the synchronizing mechanism. The SR latch has the two mechanism messed together and induces new uncertainties to hang up the RC/IC oscillator. In the new architecture of FIG. 4L, the toggling mechanism and synchronizing mechanism are separated from each other. There is no uncertainty that the RC/IC oscillator will not be hang up. Furthermore, the synchronization needs only to synchronize with one bank signal of these two bank-bank switching signals. On the contrary, the SR latch needs two signals in the synchronization process.

As shown in FIG. 4M, it is the RTL level circuit implementation of the synchronization toggling mechanism in FIG. 4L. In this innovative synchronization toggling mechanism, it is noted that the switching on of one bank and the switching off of the other bank are switching simultaneously. The conventional SR latch is switching off the other bank to charge up first, then switch on its own bank to discharge its own voltage. It has to hold its own voltage to make sure the other bank being switched off to start the charge up process. As shown in FIG. 4N, the waveform of the synchronization toggling mechanism shows this simultaneous parallel process. FIG. 4O shows the gate level circuit implementation of the synchronization toggling mechanism. In the new innovative synchronization toggling mechanism, the switching on and switching off processes are switched at the same time. It is even much different form the traditional FIFO structure. In the traditional FIFO, the output signal Q_{B} is the inverting signal of Q. However, in the innovative synchronization toggling mechanism, the output signal Q_{B} is the inverting signal of Q_{S}. The synchronization toggling mechanism is the hybrid of the partial SR latch and the toggling mechanism. However, the partial SR latch is for single signal synchronization. The toggling mechanism is to have the switch to toggle in two banks. There are two stages. All the switching signal process is handled in the level-sensitive first stage. The first stage has the plenty time of Tperiod to settle down the states. It is more like to take time to fill the bullet in the gun. However, the second stage is edge-sensitive process. As soon as the trigger signal is triggered, the toggling switch process is fired immediately. It is more like to fire the gun with the trigger. That is the reason why the synchronization toggling mechanism is suitable for the high frequency clock operation. The loop delay of the SR latch in the conventional RC/IC clock is completely eliminated in the innovative new architecture of the synchronization toggling mechanism. Once the switching processes happen, there is no way to cancel of this switching processes. The conventional SR latch is a sequential process. The synchronization toggling mechanism is simultaneous parallel process. So, there is no need to hold of one switching process for the other process to make sure the switch of the other bank has already started the switching process.

As shown in FIG. 4P and FIG. 4B, to keep the constant clock period, in the RC/IC oscillator, both the (C Vref) and Iref have to be kept to be constant. However, as the Vc varies, (1) the charging current Iref might vary as the voltage Vc varies and (2) due to the charge sharing, the effective capacitor Cc actually is not a constant, either.

In other words, both the variance of Cc and Iref are varying over the variance of Vc. To have the constant clock period over PVT (process, voltage and temperature), we have to keep the Iref and the effective Cc to be constant over voltage variance of Vc first.

As shown in FIG. 4P, the parametric capacitor Cₚₐᵣₐₘ at Vp node will contribute the variance of the capacitor Cc. Due to the charge sharing between the nodes Vp and Vc, it causes the nonlinear charging curve of Cc at Vc node as shown in FIG. 4B. As Vc is at the low voltage, the charge of Vₚₐᵣₐₘ at Vp is transferred to the Cc due to charge sharing. The slope of Vc rising curve is steeper. As Vc is at the high voltage, the charging current I_{ref} charges both the Cc and Cₚₐᵣₐₘ. The slope of Vc rising curve is slower. So, we need to eliminate the capacitor effect of the Cₚₐᵣₐₘ. As the derivation as follows, we need to keep Vp to be constant, that the charge of Cₚₐᵣₐₘ will not share with Cc and the charging current Iref will not charge the Cₚₐᵣₐₘ.

T=CVpeak/Iref

C=(CₚₐᵣₐₘΔVp+CcΔVc)/ΔVc=Cₚₐᵣₐₘ(ΔVp/ΔVc)+Cc

If ΔVp=0 then C=Cc.

To have ΔVp=0, i.e., Vp=const, we must design circuit to keep Vp to be constant. As shown in FIG. 4P, there are two dual purpose to keep the voltage Vp to be constant. The first is eliminate the charging share between the nodes Vp and Vc. The second is to keep Iref to be constant over the voltage variance of Vc.

The variance of Vc from the lowest voltage to the peak voltage Vpeak is highly dynamic process. In this dynamic variance process to keep the two factors of charging current Iref to be constant and the Vc varies linearly, we need to have two controlling mechanisms. As shown in FIG. 4P, the dynamic variance of Vc will be fed back to the current source to dynamically adjust the biasing voltage Vbp. From the constant biasing voltage Vbn to generate the constant I_{ref} for the dynamic load variance of Vc. FIG. 4P shows the dynamic current biasing circuit. The biasing voltage Vbn and the Vrefo is to generate the constant biasing current Iref. To generate the constant biasing current Iref, there are two dynamic biasing voltages Vbp and Vbpc. The dynamic biasing voltages Vbp and Vbpc is to keep the Iref=Irefo=constant.

Combining FIG. 4G with FIG. 4P, the basic architecture of the circuit configuration of the RC/IC oscillator is as shown in FIG. 4Q. The Peak Monitor monitors the peak of the node voltage Vc. According to the peak value of Vc and the setting value Vrefu, the peak monitor generates a triggering voltage Vtrig. As the node voltage Vc is larger than the triggering voltage Vtrig, the feedback loop starts to run and discharge the node Vc. The Valley Monitor will monitor the valley voltage of the node Vc to keep the valley voltage of Vc to be the constant Vrefy.

To have the temperature compensation for the variation of capacitor, it can use the self-compensated RC as shown in FIG. 2B and FIG. 2D. There are the trimming bits being set up by the temperature sensor for the minor deviation after the RC self-compensation. For the self-compensation in RC/IC oscillator, the self-compensated R will be compensated in the bandgap reference. The self-compensated C is in the RC/IC oscillator. To have the spread spectrum effect on the clock, the True Random Number Generator is added to make the minor modification of the oscillation frequency of the RC/IC clock.

Combining FIG. 4E, FIG. 4G, FIG. 4M and FIG. 4Q, the basic RC/IC clockgen is shown in FIG. 4R. For RC/IC oscillator, there is kick-to-start initialize circuit. The kick-to-start initialize circuit will set the node voltage of V_{c1} at Vrefu1, the voltage of node V_{c2} to be zero, the V_{trig1} and V_{trig2} are set to be V_{trig}. The new architecture will start as the conventional RC/IC resonator does. Then it will be released to operate in the new RC/IC resonator having the adaptive triggering voltage V_{trig1} and V_{trig2} to compensate for the PVT variation of the feedback loop. In FIG. 4R, the valley voltage is set to be ground to simplify the circuit configuration for being easy to understand. In FIG. 4S, it is the final complete circuit of the RC/IC resonator. The valley voltage can be set to some voltage above the ground to filter out the substrate noise, etc. The valley monitor circuit, etc is the conjugate symmetry to the peak monitor circuit.

The conventional LDVR has the OPAMP in the feedback-closed loop is 3-stages. The output capacitor is included as the stability analysis in the 3-stages OPAMP. It is impossible to make the 3-stages OPAMP feedback loop to be stable in any case to satisfy the versatile requirements, such as in-rush current, over-voltage protection, minimum slew rate, etc. The conventional LDVR just fails to meet the specifications.

Furthermore, there are the rush-in current and over-voltage protection problems in the transient process and power up process in the traditional LDVR. They will cause the latch-up problem of the chip. For the large capacitive load C, I=C(dV/dt), there is large rush-in current if we have no control over V. Consequently, according to V=L(dl/dt) of the inductance L of the bonding wire and pin, the problem of the over voltage protection V and the rush-in current I are highly correlated with each other. Unfortunately, the big capacitor is at the pin, and the over voltage is at the pad. The big capacitor cannot help to solve the overvoltage problem. Even worse, the over voltage at the pad will induce the latch up problem of the chip. For the battery powered chip, as long as the chip is in latch up, there is not enough power to pull the chip out of the latch up condition. The battery power will be drained very fast.

The capless low drop voltage regulator (LDVR) doesn't need the capacitor to stabilize the voltage regulator at any load conditions of the capacitor load, current load and satisfying the ramping up requirements. It can meet the loading requirements from zero current and/or zero capacitance to the maximum rated current and/or maximum capacitance.

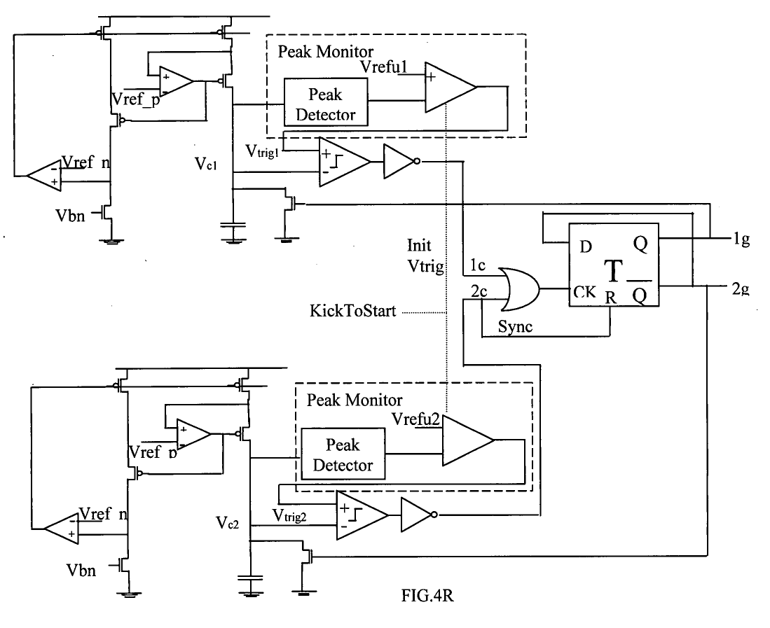

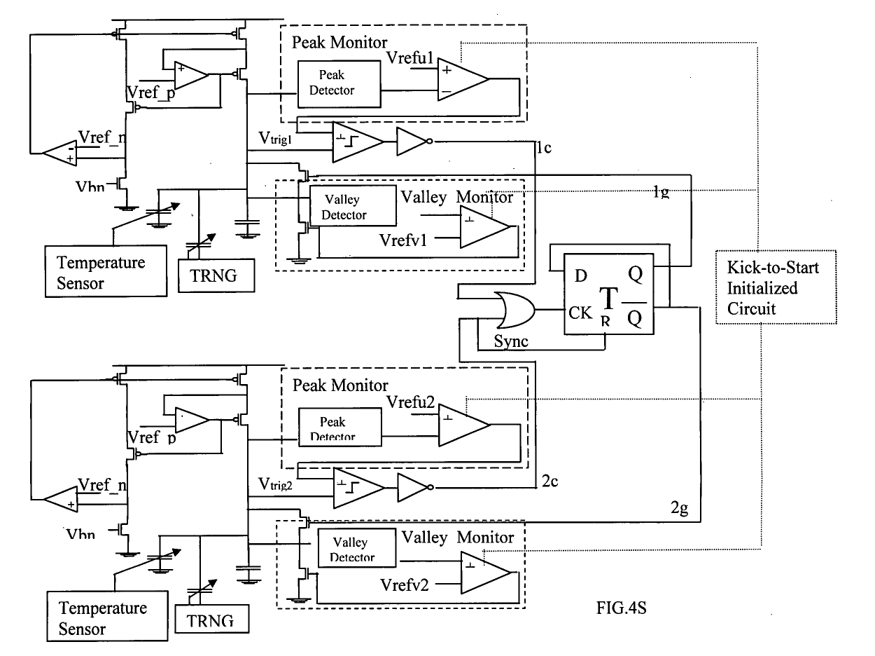

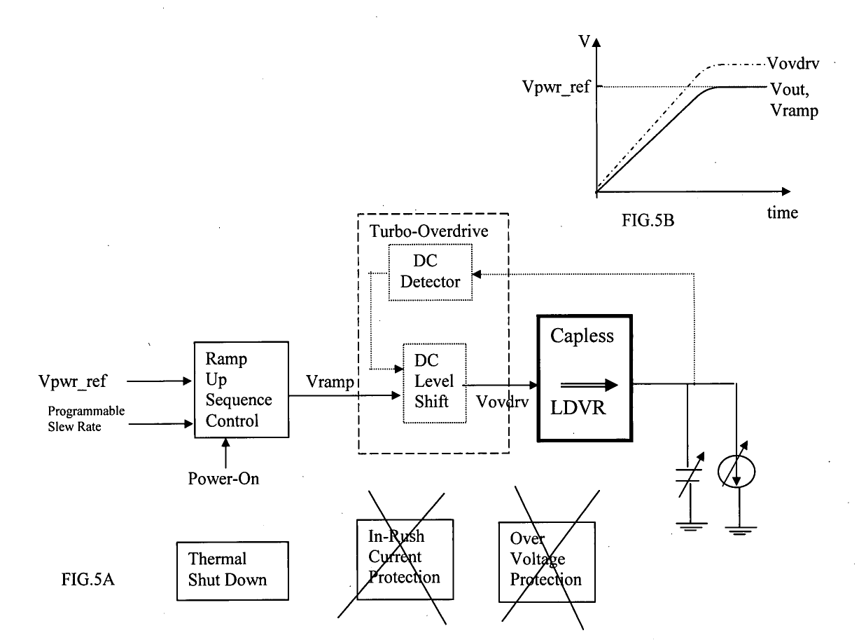

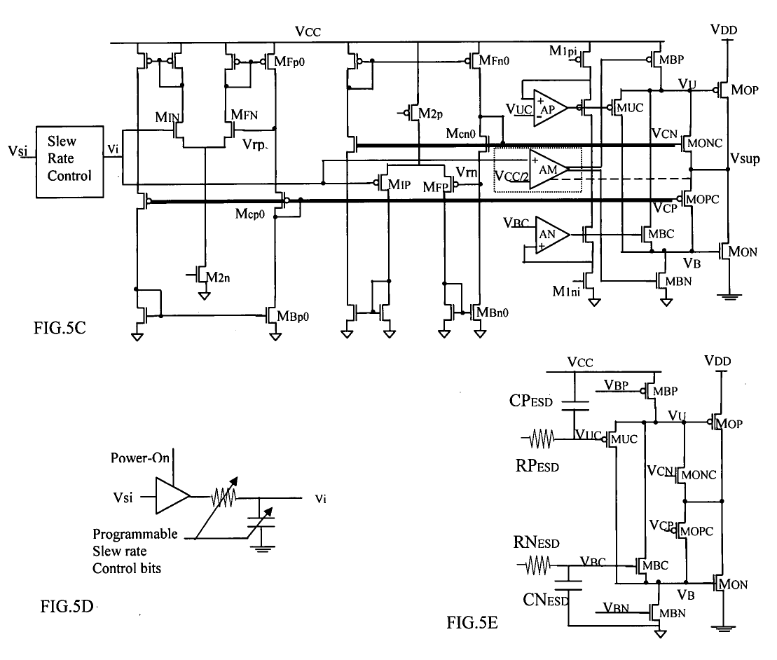

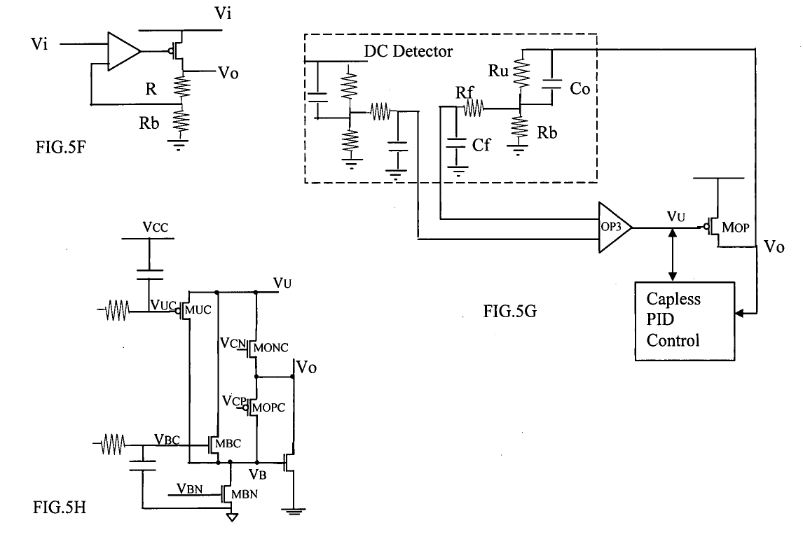

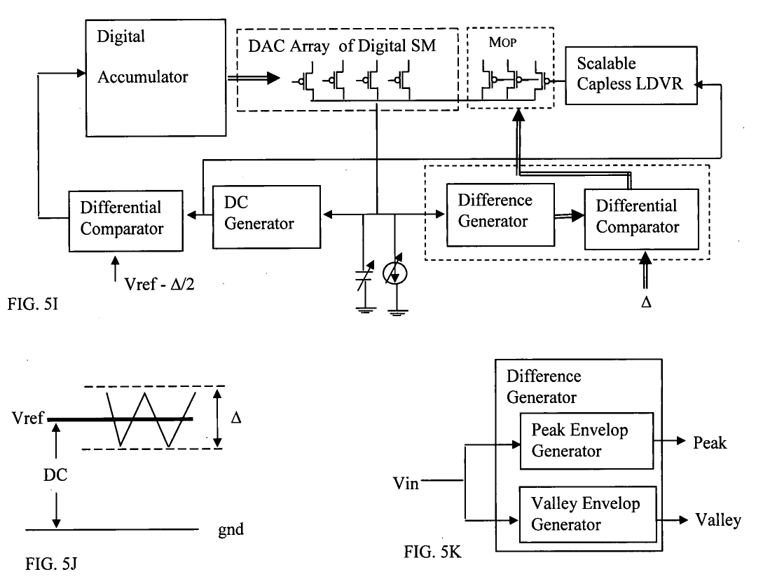

As show in FIG. 5A, we adopt the hierarchical architecture for the capless LDVR. There is no feedback loop. In the core of the capless LDVR, all the control is feed forward. As shown in FIG. 5C, all the feedback loop is local and only single stage. The single stage is unconditionally stable that the capless LDVR is unconditional stable. There are several local feedback loops in cascade. Each loop has ultra-high speed to stabilize the output load regulation and the line regulation of the individual loops.

As shown in FIG. 5A and FIG. 5B, for the long chain of the cascading loops, we need to check the deviation between the input of the first local loop (Vpwr_ref) and the output of the last local loop (Vout). For the power supply, the input of the first loop is constant or the reference voltage or the very slow ramp-up voltage. So, the feedback loop of the power supply is DC style voltage. All the fast response is left for the local feedback loop to take care. For the long chain feedback from the output of the last stage loop to the input of the first stage local loop, it is only the DC type average of the output level. The fast response of the output load regulation and line regulation are left to the local loop. With such kind approach, we divide the control loop to be two level hierarchical control. The high level is the global DC level control loop and the low level is the local loops. This is referred to be hierarchical LDVR.

As shown in FIG. 5B, for the light load, the output voltage of the last stage is equal to the input voltage of the first stage. However, for the heavy load, the output voltage of the last stage has a small deviation to the input voltage of the first stage. To compensate the small deviation, we can raise up the input voltage level of the first stage. So, there is a DC level shift to modify the voltage level of the input voltage to have the load adaptive adjusting capability.

For the capless LDVR as shown in FIG. 3B, there is the build-in over-voltage-protection capability. Furthermore, the output of the capless LDVR has the direct image of the input voltage capability. So we can control the input voltage ramp up slew rate to control the output voltage ramp up slew rate without any stability problem. For the other conventional LDVRs, they don't have such capability due to the stability of the LDVRs. With the feedback loop control of the conventional LDVRs, all the LDVRs should have the capability to control the output slew rate with the control of the input slew rate. However, due to the stability, the conventional LDVRs cannot have the slew rate control capability. As long as the conventional LDVRs don't work at the designed working condition of the reference voltage, the conventional LDVR becomes unstable. Even worse, such kind constraint of the working condition at the fixed operating point causes the rush-in current due to I=C(dVo/dt) with Vo=Vi=Vref at t=0. At the power up, the Vo jumps from 0 to Vref instantly. So, all the rush-in current and over voltage protection problems are due to the poor circuit design stability problem of the conventional LDVRs.

Since the capless LVDR in FIG. 5B has the unconditional stability capability for all the voltage level and the output voltage can trace the input voltage, as shown in FIG. 5A, there is a ramp up sequence control. As the LDVR is powered on, the LDVR will follow the preset ramp up slew rate to bring up the Vo to the target power supply voltage. As shown in FIG. 5D, the ramp up voltage can be as simple as one RC low pass filter. Changing the programmable slew rate control bits to change the value R or C, we can change the slew rate of the output power supply voltage.

Why the capless LVDR is such kind superior to the conventional LDVRs? It is the push-pull clamping output voltage power supply. The output voltage V0 is divided to be 3 voltage ranges: (1) upper range: from Vdd to (Vdd−Vth,n); (2) middle range: from (Vdd−Vth,n) to (Vgnd+Vthp); (3) low range: from (Vgnd+Vthp) to Vgnd. The voltage Vrp, Vm and Vsup have the same source follower relation that in the middle range, Vsup=Vrp=Vm=Vi. However, even the clamping voltages VCP and VCN have the full voltage, the source follower voltage Vsup still has the voltage range from (Vdd−Vth,n) to (Vgnd+Vthp) to be the middle range operation. However, the LDVR is low drop to be less than 200 mV to operate in the upper range. We need to expand the working range from the high efficiency middle range to the upper range. Furthermore, to have the ramping up capability to solve the in-rushing current and over-voltage protection problem we need to work in the low range, too.

To work in the upper range, the capless LDVR has the other circuit to have the full-range operating capabilities. The upper range circuit components are MBP, MUC MBN, MONC and MON. The voltage VU is biased at the voltage VU=VUC>Vdd−Vth,p that MOP is shut off.

As shown in FIG. 5C, to work in the upper range, Vi>VCC/2. The amplifier means AM compare the Vi with VCC/2 to decide the operation range is in the upper range and generating the biasing voltage such that the current flows through MBN is larger than the current flowing through MBP. So the Vu voltage is pulled down to turn on the output device MOP. As the output voltage Vsup>Vi, MOPC is turned on and a lot of current injects into the node VB that the voltage is raised up to turn off the device MBC a little bit and the voltage VU is raised up to turn off the out put device MOP a little bit. With this feedback mechanism, the Vsup=Vi.

Being Similar, to work in the lower range, the capless LDVR has the other circuit to have the full-range operating capabilities. The lower range circuit components are MBP, MBC MBN, MOPC and MOP. The voltage VB is biased at the voltage VB=VBC<Vth,n that MON is shut off.

To work in the lower range, Vi<VCC/2. The amplifier means AM compare the Vi with VCC/2 to decide the operation range is in the lower range and generating the biasing voltage such that the current flows through MBP is larger than the current flowing through MBN. So the VB voltage is charged up to turn on the output device MON. As the output voltage Vsup<Vi, MONC is turned on and a lot of current flowing out of the node VU that the voltage decreases to turn off the device MUC a little bit and the voltage VB is drop down to turn off the out put device MON a little bit. With this feedback mechanism, the Vsup=Vi.

The power supply circuit is very large device. As they are tested in the HBM (Human Body Mode), the ground voltage drops negative voltage, if the VB node voltage still high, a lot current will drain to the substrate and causes the chip to latch up. To protect the chip in the ESD test, we need the modify the capless LDVR as shown in FIG. 5E. The RN_{ESD} and CN_{ESD} are added. As the ground is pulled downward instantly, the node voltage V_{BC} also decreases to follow the ground that the V_{B} follows the ground and there is no current injecting into the substrate. The latch up problem in the ESD test is cleaned out with the capacitor CN_{ESD}. Similarly, the RP_{ESD} and CP_{ESD} are added to clean out the ESD test causing latch up problem at the Vdd pin.

The techniques developed for the capless LDVR can be applied on the conventional LDVRs to modify the conventional LDVRs to be the capfree LDVR. A shown in FIG. 5F, it is the circuit configuration of the conventional LDVR. As shown in FIG. 5A and FIG. 5G, the input side has the DC Detector and the output MOP is compensate with the capless PID control. The DC detector is the low pass filter having one zero and one pole. The zero is made of Co and Rb and the pole is made of Rf and Cf. The zero is to short the strong AC component to the ground. The filter is to clean out the high frequency component of the Vsup. As shown in FIG. 5H, the capless LDVR driver section serves as the Capless PID Control.

Furthermore, to reduce the switching noise and driving power, the hybrid LDVR made of the digital LDVR and analog LDVR is developed as shown in FIG. 5I. As shown in FIG. 5J, the digital LDVR is for the DC level of power supply; the analog LDVR is for the AC variance of the power supply. With this kind approach, the LDVR driving circuit is only for the least significant bits small power supply. The main significant bits power supply is supplied by the digital power. The digital power doesn't need to switch that a lot of switching control power is saved. The analog LDVR is just supply the AC type current and make the power voltage variance is smaller than the specified.

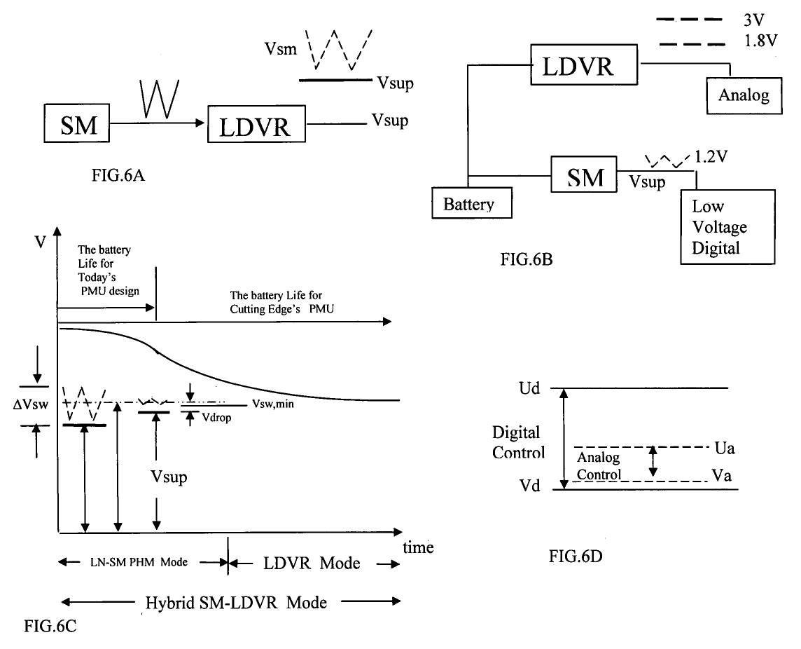

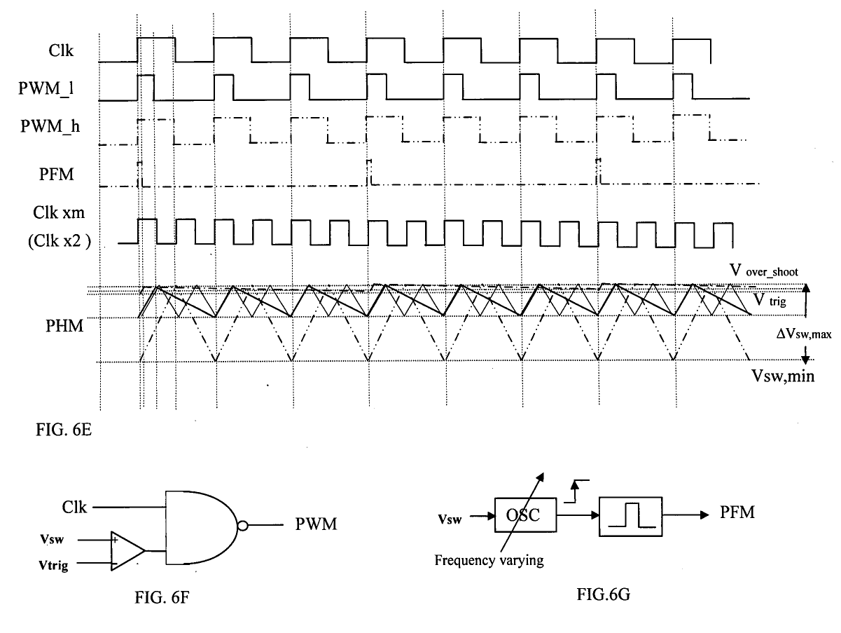

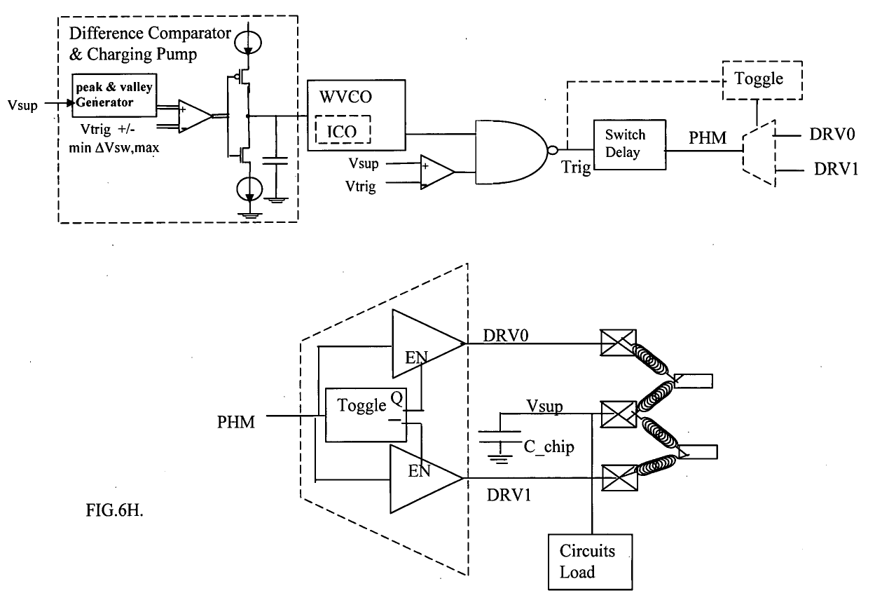

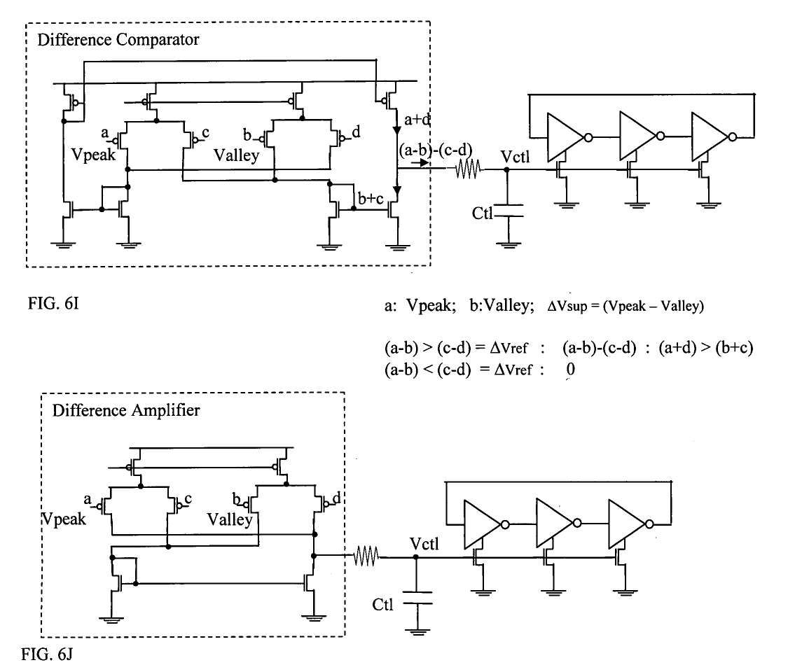

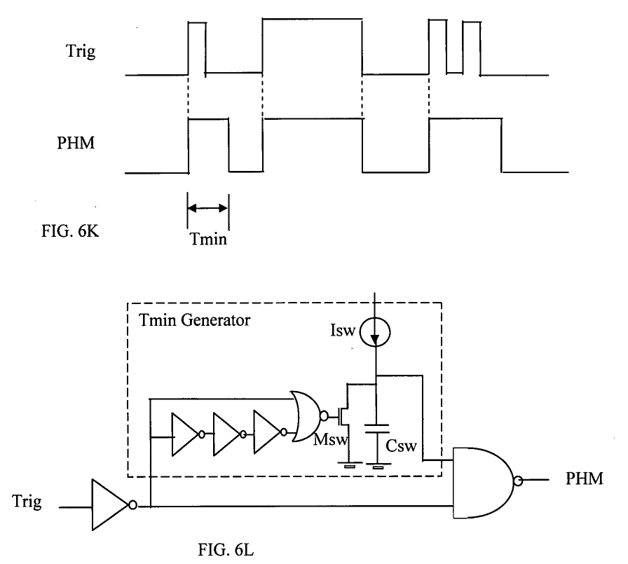

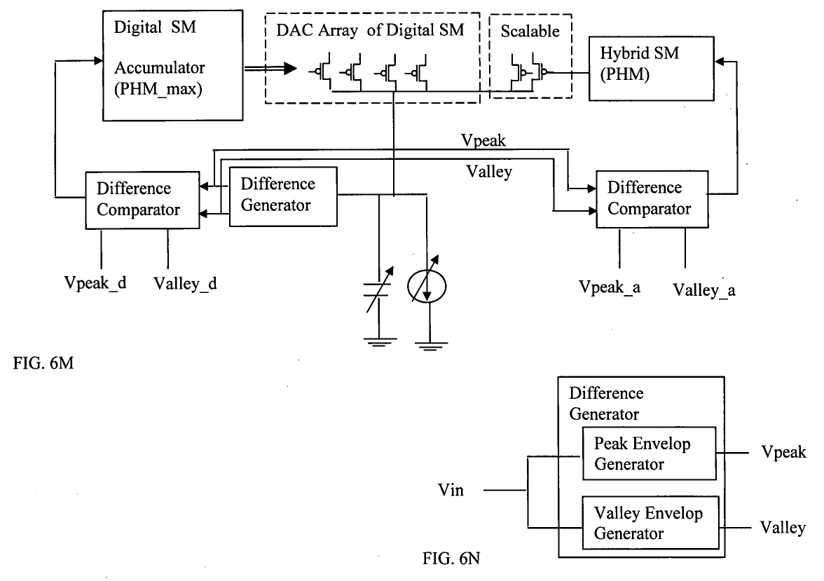

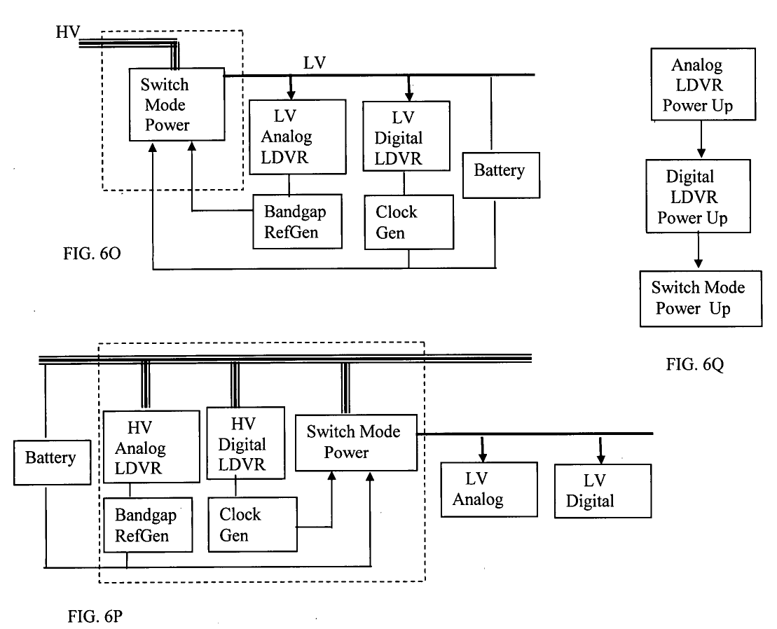

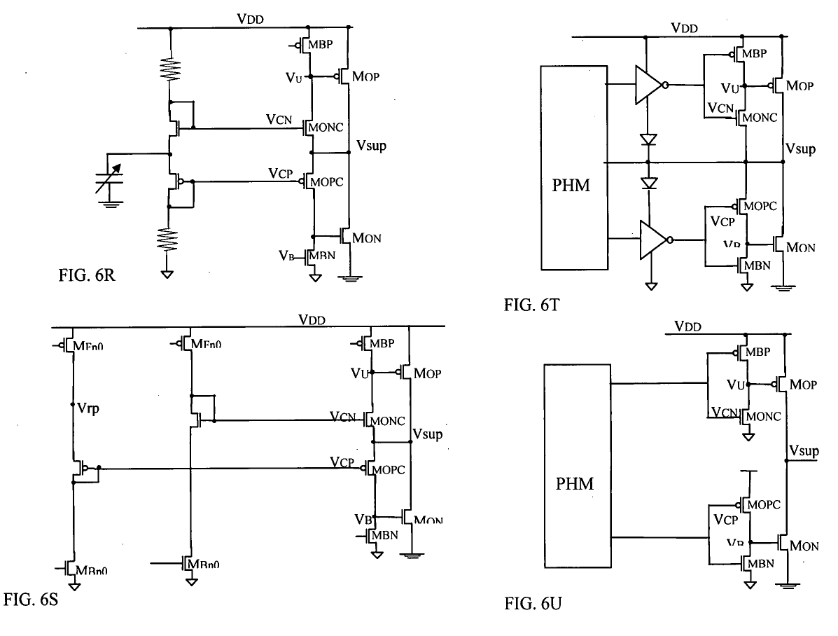

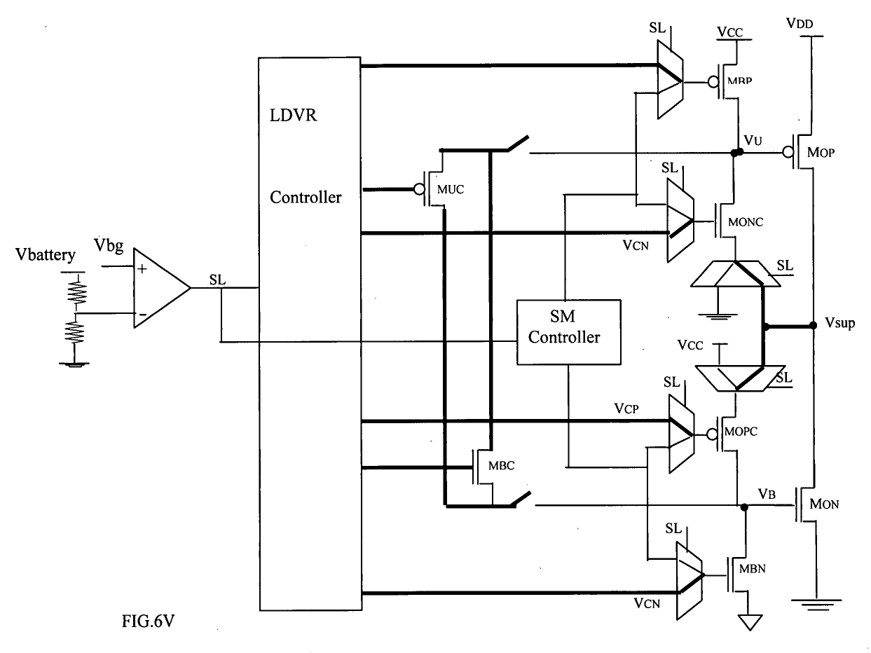

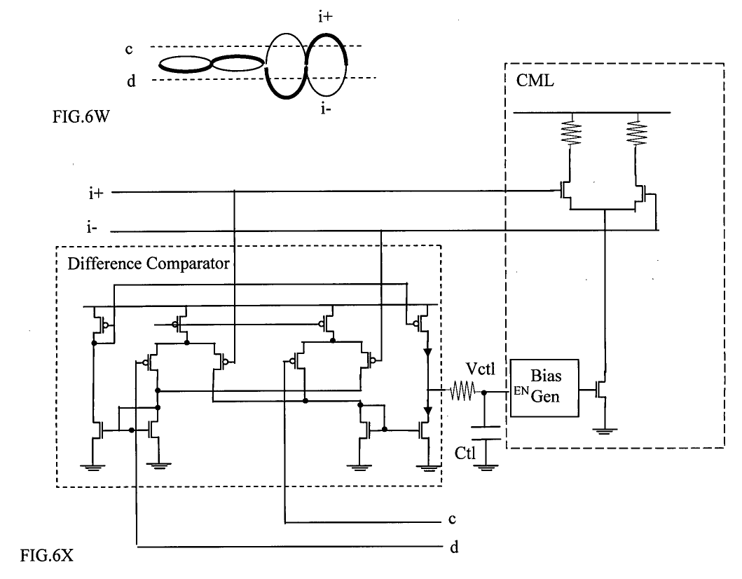

However, the LDVR's efficiency is E=Vsup/Vdd. As Vdd >>Vsup, the efficiency is pretty low. Now the digital circuit is 1.2V. The battery power is about 4V. The efficiency for battery PMU is 30% only. However, the portable device design is ask for the low power design to extend the battery life. How to increase the PMU efficiency becomes the first important issue. So the conventional on-board PMU architecture as shown in FIG. 6A is replaced with the battery PMU as shown in FIG. 6B. The digital circuit is operated at the voltage 1.2V with the large switch noise. The argument is the digital circuit itself has large switch noise so the switch noise of the Switch Mode (SM) power supply doesn't have impact on the performance digital circuit. So, the digital circuit can use the SM directly. However, today analog circuit design has drop to 1.8V. The anti-power noise analog circuit having very large PSRR has developed successfully. Can we connect the SM to then analog circuit? It implies that we have to consider both the efficiency and noise for the SM. As shown in FIG. 6C and FIG. 6D, we consider the both the noise and power efficiency in the PMU design. Actually, with the global system view, reduce the switch noise can increase the system power efficiency with the proper trade-off design. For SM, the load modulation on the Vsw,min causes the loss of power efficiency. As shown in FIG. 6C, the power loss due to the SM (switch mode) power noise of the output waveform

Vsup=Vsw,min−Vdrop

(Vsup+ΔVsw)*Isup is the power consumption; (ΔVsw*Isup/2) is the extra power loss to reduce the power efficiency.

Furthermore, there are 3M design methodology, Mixed Signal, Mixed Voltage, Mixed Power, for the TSOC design. The Mixed Signal is to mix the digital circuit and analog/RF/sensor circuit on the same chip. Mixed Voltage is to have the multiple voltage levels on the same chip, such as V=1.2, 3, 5, 10 and the POS (power-on-sequence), PDS (power-down-sequence) become design issues. Mixed Power is to mix the drive circuit and the control circuit on the same chip. The PMU is 3M design. However, for the cutting edge battery PMU has another tough challenge to extend the battery life ×3 times or more than the today's PMU. The design style of today's PMU is still the old-fashioned on-board system design. The cutting edge PMU design is 3M-3H design PMU. The 3H is the three-hybrids. The 3H is the Hybrid of PWM and PFM, the Hybrid of SM and LDVR and the Hybrid of digital PMU and analog PMU.

PWM (Pulse Width Modulation) is the switch mode with constant frequency and varying duty. PFM (Pulse Frequency Modulation) is the switch mode with varying frequency and constant duty period. PWM Design is specific load target and the target range is pretty narrow! PWM has the PFM effect at light load however it loses efficiency due to the constant frequency. PWM is not suitable for the wide dynamic load variation, such as the cellular phone!

To use all the battery power efficiently, the PMU is “dynamic load adaptive” to change its configurations and it is scalable in the configuration according to the load and battery condition. The hybrid of the digital and analog can reduce the switching loss, etc and keep the efficiency of PMU. As shown in FIG. 6C, the hybrid of the SM and LDVR is to extend the battery usage life. As the battery voltage drops and the switch loss makes the SM is no more gain over the LDVR in power efficiency, the hybrid SM-LDVR will change to the LDVR mode. The hybrid LN-SM is the hybrid Low Noise Switching Mode of the PWM (Pulse Width Modulation) and PFM (Pulse Frequency Mode) to be the PHM (Pulse Hybrid Mode).

Referring to FIG. 6C, FIG. 6D, FIG. 6E and FIG. 6F, the PWM_l is the pulse width modulation at light load; the PWM_h is the pulse width modulation at heavy load. The waveform of the switch mode power buck converter is operated with the PWM (Pulse Width Modulation) mode. The duty cycle is defined to be the switch-on time being divided by the clock period. As the load is heavy, the switching on time is longer and the duty cycle is larger. The power injection into Vsup is more. As the load is light, the switching on time is shorter and the duty cycle is smaller. The power injection into Vsup is less. However, to switch on and switch off, both switch energy losses are the same. So, the power efficiency for PWM is reduced as the load becomes small.

Referring to FIG. 6C, FIG. 6D, FIG. 6E and FIG. 6G, the PFM is designed for the light load. Several clock cycle, a constant finite impulse is the switch on signal to drive the drive circuit. The number of switching times is reduced that the switch loss is reduced at light load. However, for the heavy load, its switching loss is high and efficiency becomes low.

PWM and PFM is at two extreme modes. What is the optimum switching frequency and what is the optimum mode at that frequency? What is the way to adjust the frequency to adapt to the dynamic change of the load? Furthermore, either PWM or PFM, the design principle only considers the power efficiency and it doesn't consider the switching noise. From the global system viewpoint, the design principle is wrong. Referring to FIG. 6C, the user consider the voltage of the power supply is the minimum of the power supply. It forces the uses to have the target supply voltage set to be the high value. It even causes the global system to lose the power efficiency. Especially for the cutting edge Battery-PMU-X design, all the mixed signal analog circuit has the anti-power-noise design. As shown in FIG. 6T and FIG. 6U, the switch mode power supply can supply the analog circuit directly and the SM will be configured to be LDVR in the final battery-life stage to have the extended battery life. So, the cutting-edge Battery-PMU-X design needs to consider both the power efficiency and the switch noise at the same time to find out the optimum operating conditions for the global optimum solution. It is the PHM design.

As shown in FIG. 6E and FIG. 6H, the PHM (Pulse Hybrid Modulation) considers both the power efficiency and switching noise to have the global optimum system operation to adapt the dynamic change of the loading condition. As shown FIG. 6E, as the clock frequency increases, the switch amplitude decreases. However, the clock frequency increases doesn't increase the switching loss as the PWM does. We use the multi-phase driver shuffling techniques to keep the switching loss to be the same even we increasing the clock frequency to minimize the amplitude variation. In other words, the essential characteristics of the fantastic design of PHM modulation is to deliver the same power have the same switching loss which is independent of the amplitude of the switch noise.

As shown in FIG. 6E and FIG. 6H, the multi-phase clock has the scheme to be m=2, Clkxm=Clk×2 to illustrative the principle. The clock frequency is double to be ×2. However, we divide the drive to be two halves. In each clock, we switch on the one half driver. So, the switch loss is 2×(½)=1, i.e., the switch loss is the same as the switch loss with the minimum clock frequency having the maximum amplitude variation. However, the amplitude variation is reduced by half. The same principle can be extend to be the clock frequency is multiple xm. the switch loss is m×(1/m)=1, i.e., the switch loss is the same as the PWM type switch loss with the minimum clock frequency having the maximum amplitude variation. In other words, the power efficiency can be as high as 96% or more. But the switching noise is reduced to be l/m. The clock frequency is boosted up m times to have m phase. For the high frequency switch, we can adopt the bonding wire to be the inductor to be the indless SM.

As shown in FIG. 6H, it is an Indless SM having m=2. The inductance is the bonding wire. The damping capacitance C_chip is the on-chip capacitance or bonding capacitor. There is no external pin needed. The switch on signal PHM drives two driving buffers which are enabled by the toggling output signal Q alternatively. Each time, only one half the output driver of the Indless SM being activated. This architecture can be easily extended to be m=2**n architecture. For m=2**n, there is 2**(n−1) pairs of the drivers have the node Vsup connected together.

As shown in the FIG. 6H, FIG. 6I, FIG. 6J and FIG. 6L, it is the architecture and the circuit configuration of the PHM. FIG. 6H is to illustrate the concepts and principles of the PHM. FIG. 6I and FIG. 6J are the illustrative alternative design example of the PHM core circuit. The fundamental principle of PHM is (1) using the target voltage Vsup,min=Vsw=Vref to control charging or not; if Vsup,min=Vsw<Vref, then the PHM is triggered; (2) if the amplitude of Vsup, ΔVsup=(Vpeak−Valley), is large than the specified voltage difference ΔVref, increases the clock frequency until the amplitude of Vsup, ΔVsup=<ΔVref. As shown in FIG. 5K, the ΔVsup generator can be implemented with peak envelope generator and the valley envelope generator.

The clock frequency is generated from the Wide VCO (WVCO), the Wide frequency range Voltage Control Oscillator. The WVCO can be implemented with ICO, current controlled oscillator, to have the wide clock frequency range. As shown in FIG. 6I is the current mode difference amplifier type varying frequency clock generator. The Vpeak is the envelop of peak of the Vsup; the Valley is the valley of the Vsup. The difference comparator makes the comparison of ΔVsup and ΔVref. As ΔVsup>ΔVref, the current charges up the low pass filter to increase the clock frequency. As ΔVsup<ΔVref, the current discharge the low pass filter to decrease the clock frequency. As shown in FIG. 6J is the voltage mode difference amplifier type varying frequency clock generator.

To turn on the driver, there is a minimum switching on time Tmin. This minimum pulse time Tₘᵢₙ is equivalent to the finite pulse time in the PFM scheme. It is the minimum time needed to drive the output driver of the SM power supply. As shown in FIG. 6H, FIG. 6K and FIG. 6L, the switch delay block generates a impulse which has a minimum finite period pulse. If the switch on time of Trig is larger than the minimum finite Tmin, then the switch on time of the PHM is the same as the input trigger signal Trig. If the switch on time of Trig is less than the minimum finite Tmin, then the switch on time of the PHM is the switch on signal having the switch-on period to be Tmin. Referring to FIG. 6L, at the rising edge of Trig, the PHM will generate a rising edge. The Tmin generator will generate the pulse having the negative pulse width Tmin. The negative pulse width Tmin is the charging up time of Csw with Isw. At the rising of Trig, the discharging device Msw will discharge the capacitor Csw instantly. Then the charging current Isw starts to charge up the Csw to count for the minimum pulse time. With this switch delay module, we can make the dynamic load adaptive switch between the PWM and PFM modes.

As shown in FIG. 6M, to increase the power efficiency, the hybrid SM made of the digital SM and analog PHM can be applied to the SM power supply. The digital SM will use the Vpeak_d and Valley_d to decide the minimum number of the switches needed to drive the load. Then the analog PHM will use the Vpeak_a and Valley_a to find out the minimum scalable switches to supply the SM power supply. It is noted that the pure digital SM has the stability problem due to the longer delay of digital control loop. The analog PHM is unconditional stable. In this hybrid scheme, the digital SM becomes an open loop and the analog PHM takes over to handle the stability of the feedback control. So, the hybrid SM of digital SM and analog SM has the stability, power efficiency and minimum amplitude variation to be the best SM power supply. With this hybrid scheme, it will make the SM to work in the highest power efficiency with the minimum amplitude variance of power supply. Furthermore, as shown in FIG. 6T and FIG. 5E, it is noted that the Capless LDVR and PHM can share the same output driver stage to be unified power supply of SMLDVR switch mode low drop voltage regulator.

FIG. 6O shows the architecture of the Battery charging circuit for Battery PMU. FIG. 6P is the architecture of the power supply for Battery PMU. FIG. 6Q is the power-on sequence for the Battery PMU. For the portable cellular phone, etc, made of low voltage devices, the battery voltage is high voltage. We need to have the high voltage PMU design. The process has the high voltage device and low voltage device. For the high voltage PMU circuit, we use high voltage devices. As shown in FIG. 5C, FIG. 5D and FIG. 6R, FIG. 6R is the ramp up for the input voltage of the high voltage power supply for Vsup. As shown in FIG. 5C, and FIG. 6S, it is the clamping circuit of the high voltage PMU circuit. It is further noted the high voltage Capless and PHM can share the same output driver stage to be Buck regulator of LDVR. As shown in FIG. 5C, FIG. 6T and FIG. 6U, with the configurable circuit design, the PHM and LDVR can be unified to have the Battery-PMU-X design of FIG. 6C.

As shown in FIG. 6V, to extend the battery life for more than 6 times, we invent the SMLDVR Switch Mode & Low Drop Voltage Regulator. The battery voltage is monitored with the reference voltage Vbg. As the battery voltage is high, it uses the SM mode. As the battery voltage is low, SM is no more efficient. It switches to the LDVR mode. The SM and LDVR share the same driver stage to save the resources and operate more power efficiently. The multiplexers are to switch between the SM circuit configuration and the LDVR circuit configuration.

Today's PMU has such poor design is due to the former designer doesn't know the difference comparator that they cannot use the difference amplifier to control the amplitude variations of the power supply. As shown in FIG. 6J, FIG. 6W and FIG. 6X, the difference comparator has the application in many different designs. The high speed Fiber Optics uses the CML inputs. The CML consumes a lot of power. As there is no signal comes in, the input CML needs to disable to save power. The difference amplifier/comparator serves as the wake-up circuit for the CML input buffer of the Fiber Optics. As shown in FIG. 6W and FIG. 6X, as the differential pair of input signal i+ and i− is large than the specified difference level |c−d|, the bias generator circuit will be activated to wake up the CML input signal to work normally.

To create spread spectrum clock and get rid of the EMI problem of switch mode power, we need RNG random number generator. In communication theory, the white noise is a random noise. The true random noise generator (TRNG) is to generate a number having the spectrum of the white noise. The on-board design of TRNG hardware random noise generator adopts the avalanching diode high voltage breakdown process. It needs the high voltage and it cannot be integrated with the CMOS chip. Our invention is to generate the TRNG with the low voltage CMOS randomized chaos circuit. The randomized chaos circuit is to randomize the chaos with the hierarchical design of the randomized circuit over the chaos circuit.

As shown in FIG. 7A, the conventional PRNG (Pseudo Random Number Generator) is made of two segments of shift register SR and one XOR gate. The PRNG is a uniformly distributed mechanism to have the uniform distribution over a domain/space. Qualitatively, the PRNG has the memory to keep what it has the distribution and trying to generate new data which has not distributed yet. The XOR gate is to generate a data which is not existed in the already distributed domain. The two segments of SR keeps the memory of previous already distributed domain/space information.

However, the domain of the PRNG (Pseudo Random Number Generator) is limited to be 2**N where the N is the number of registers. The PRNG makes the randomized uniform distribution in the finite space in discrete time domain. Eventually, the finite domain will run out the resource that the PRNG has to repeat the old patterns again. That is the reason why the digital type random number generator to be pseudo random generator.

The PRNG has the randomized circuit of the fundamental Random Number Generator (RNG) mechanism over the finite space in discrete time. To be a true random number generator, we just need to make this fundamental Random Number Generator (RNG) in the infinite space domain and continuous time space. As shown in FIG. 7B, to make the RNG to be the TRNG, the Random Number Generator (RNG) mechanism has to operate as the analog signal processor in the infinite space and in the continuous time domain. The space is analog signal that it has the infinite space. For the N analog stage, the (infinite)**N states are infinite space. In FIG. 7B and FIG. 7C, the random number signal Ntrng feedbacks to the analog type shift register. FIG. 7D shows the analog style feedback of the random signal Ntrng. The analog signal are continuously varying in time domain. The time domain are continuous to be infinitely small to be infinite domain. As shown in FIG. 7C, the RNG mechanism can be implemented hierarchically and recursively. With the feedback of the chaos in the randomized circuit, the noise is generated by the randomized chaos circuit itself, too. With the infinite domain and time space, the randomized chaos doesn't have the limit of the pseudo-periodic behavior of the conventional chaos circuit.

As shown in the FIG. 7D, in the phase diagram, the solid line is the attractor of chaos circuit. The ring oscillator is considered to be the chaos circuit. The attractor of chaos is characterized by the repetitive traces of curves. In time domain, the chaos is characterized by the pseudo-periodic waveform. For the random noise generator, both the periodic and pseudo-periodic curve cannot be used as the random noise generator. It has to be the randomized chaos to be Randomized Chaos circuit. It has to be the combination of the chaos circuit and randomized circuit. As shown in FIG. 7B, the ring oscillator including the noises source is equivalent to the chaos circuit; the left-shift register circuit including the XOR gate and feedback is the randomized circuit. The randomized circuit drives the chaotic circuit to make the randomized chaos for the RNG (Randomized Number Generator).

As shown by the dotted line in FIG. 7D, the randomized signal is applied to the chaos circuit. As shown in FIG. 7E, the curve traces of the chaotic circuit rotates on the phase diagram as the random circuit applies the randomized signal on the chaotic circuit. As shown FIG. 7F, the trace of curves is the circuit without the feedback of the randomized Ntrng. The curve shows the attractor of chaos circuit. As shown in FIG. 7H, the spectrum is a narrow bandwidth of the pseudo-periodic oscillations. As shown in FIG. 7G, as the randomized signal Ntrng applying on the chaos circuit of ring oscillators, the trace of the curve seldom repeats itself. The phase diagram uniformly weaved on the phase diagram.

FIG. 7H is the noise has limited bandwidth. It cannot be the source of the randomized noise. As shown in FIG. 7I, the spectrum of the randomized chaos is a broad bandwidth of the TRNG randomized oscillations. As shown in the FIG. 7J, it is the spectrum of the S/H in FIG. 7A, FIG. 7B and FIG. 7C to have the discrete repetitive delta function in frequency domain. As shown in FIG. 7K, the white noise spectrum is the combinatory of the FIG. 7I and FIG. 7J. The sample and hold of the broad noise spectrum of the randomized chaos in FIG. 7I becomes the TRNG having the infinite noise spectrum of the white noise as shown in FIG. 7K. This is the fundamental principle of the randomized chaos generating the true random noise. In the real application, the hierarchically recursive randomized chaos can be adopted to have any different combinatory applications.

As shown in FIG. 7L, the random signal Ntrng is AC coupling on the biasing voltage generator to generate the Vctl controlling voltage for the analog type shift register. As shown in FIG. 7M, it is the implementation of the AC coupling of the Ntrng noise interface circuit. The other type noises of quantize noise Nquantize, ground noise Nground, thermal noise Nthermal, diode noise Ndiode, bipolar noise Nbiploar, MOS noise Nmos will add on the bias voltage, too.

There are many different kinds of the analog type shift registers. In FIG. 7B and FIG. 7C, the analog shift register is similar to the VCO type circuit being made of the inverters. However, as shown in FIG. 7N, the analog shift registers can be made of the AREG (analog register), VADC (voltage type ADC) or IADC (current type ADC). The noise generated by the ADC is the quantized noise in the analog to digital conversion processes.

As shown in FIG. 70, it is the voltage type AREG analog shift register. The Ntrng noise induces the variance of Vctl to inject the noise into the voltage type AREG analog shift register. As shown in FIG. 7P, it is the current type AREG analog shift register. The Ntrng noise induces the variance of Ictl to inject the noise into the current type AREG analog shift register.

FIG. 7Q is one example to illustrate the TRNG with the hierarchically randomized chaos circuit. It has the similar architecture as shown in FIG. 7B. There are two analog type shift registers having the infinite voltage states and in continuous time domain. One analog type shift registers is voltage type AREG shift register. Another analog type shift registers is current type AREG shift register. The output of current type shift register is fed into the voltage type analog shift register with the AC coupling. The output of current type analog shift register and the output of voltage type analog shift register XOR together to be the Ntrng signal and feedback to the current type analog shift register. The Ntrng is the randomized signal and send back to the analog type register to have the uniformly distributed in the infinite voltage state and continuous time domain to have the white noise type random number.

FIG. 7R is the TRNG applying to generate the spread spectrum clock. The clock samples the random noise generated by the TRNG core to be the random number. The clock has the output of the option to be regular clock or to be the spread spectrum clock. For the spread spectrum clock, the output RN of TRNG being filtered by LPF and modulates the oscillator of the clock generator to be the spread spectrum clock. Since the RN is TRN (True Random Number) not PRN (Pseudo Random Number), there is no spur phenomena in the spread spectrum clock as the PRN does.

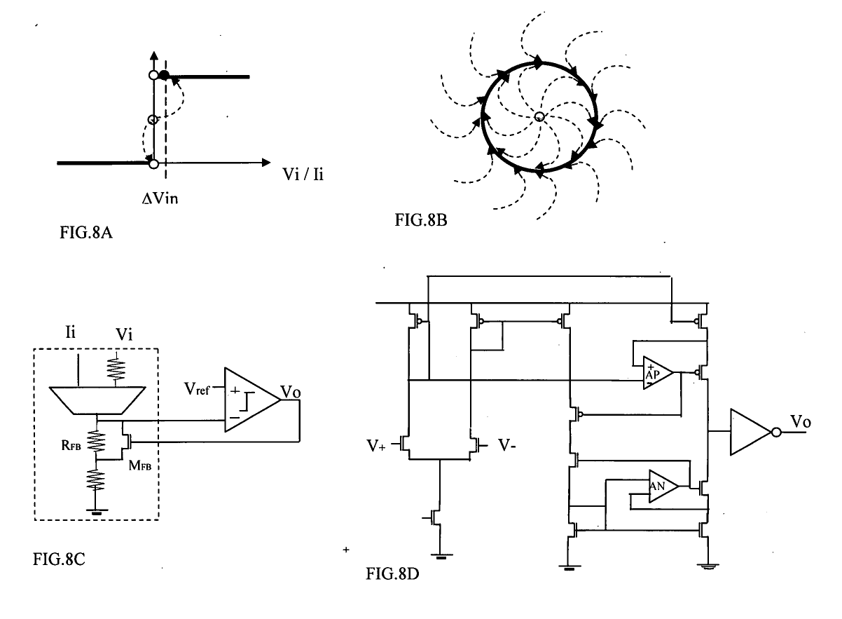

In the 4-Less TSOC design, we use a lot of comparators. However, so far, there is no true comparator. As shown in FIG. 8A, the true comparator has the jumping behavior. The equilibrium point at the origin is an unstable equilibrium. There is a jumping up and jumping down process at the equilibrium point. It is a jumping from the analog signal to digital signal interface process. If there is no such kind jumping process, it is not a true comparator. As shown in FIG. 8B, the comparator 1-D jumping process phase plot is similar to the 2-D phase diagram. Inside the limit cycle, it is the unstable equilibrium point and the trace spirals out and terminate at the limit cycle. So far, it uses the high gain OPAMP to emulate the comparator. However, the OPAMP is stable and continuous at the equivalent point and might be unstable at the extreme points. The comparator is discontinuous and unstable at the equilibrium point and is stable at the extreme points of 0 or 1 state. The properties of OPAMP are just reverse the properties of comparator. The comparator is unstable at the equilibrium point and stable at the extreme points of 0 or 1 state. So it is a fundamental mistake to use the high gain OPAMP to substitute for the comparator. Furthermore, the comparator operation must be continuous in time. It is a mistakes to use an OPAMP cascading with a latch which is discrete in time to emulate a comparator. For a time varying signal, the discrete time fails to catch the exact time when the warning signal is triggered.

FIG. 8C and FIG. 8D show the first TRUE comparator in all the world. The gain boost amplifiers AN and AP make the equilibrium point to be unstable to have the jumping process of the comparator. The feedback device MFB and resistor RFB make the comparator to be stable at the extreme points of state 0 and state 1. The general architecture of the comparator in FIG. 8C makes the comparator can be shared in many signals of the current type signals or voltage type signals. The share of the comparator is very important for the many sensors system to share the common resources.

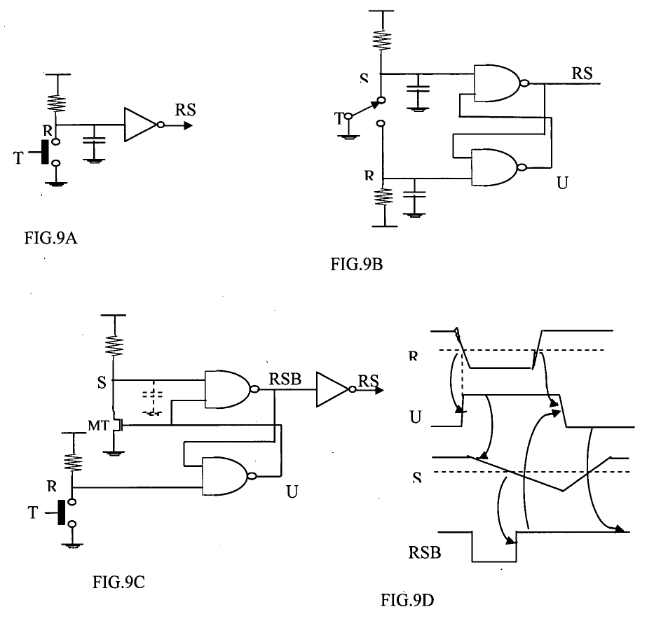

To reset the SOC, we need the perfect de-bouncing switch. FIG. 9C shows the first capless debounce switching circuit. As shown in FIG. 9A, the mechanical toggle switch T will generate spark flash. It has only one capacitor to damping out the spark. The capacitor must be large and it is the on-board capacitor. However, the inductance of the package of the capacitor will reduce the de-bouncing effect of the capacitor. FIG. 9B shows the double-throw switch de-bouncing circuit. The double-throw switch needs two on-board capacitors. However, the essential problem of the mechanical switch is still there. FIG. 9C shows the capless debouncing circuit. The mechanical toggle switch T triggers the electronic switch MT. The electronic switch MT has no disconnection that there is no spark. So the capless debouncing circuit converts the mechanical switch to be electronic switch to get rid of the spark. There is no spark that there is no need for the on-board capacitor. FIG. 9D shows the switch timing waveform of the capless debouncing toggling switch.

The USB switch is one of the most important PMU (Power Management Unit). The USB can supply the power. However, there are multiple USB devices. Each USB device might have its own supply power or it receive the power from outside. To arbitrate which power will be adopted, there is a need for smart USB switch to make the arbitration automatically.

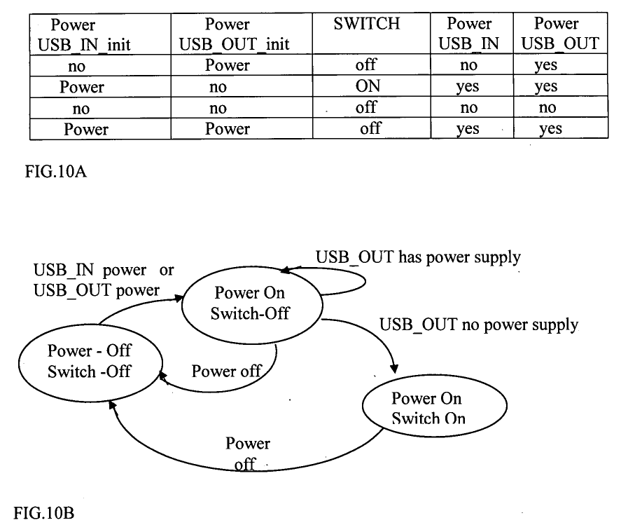

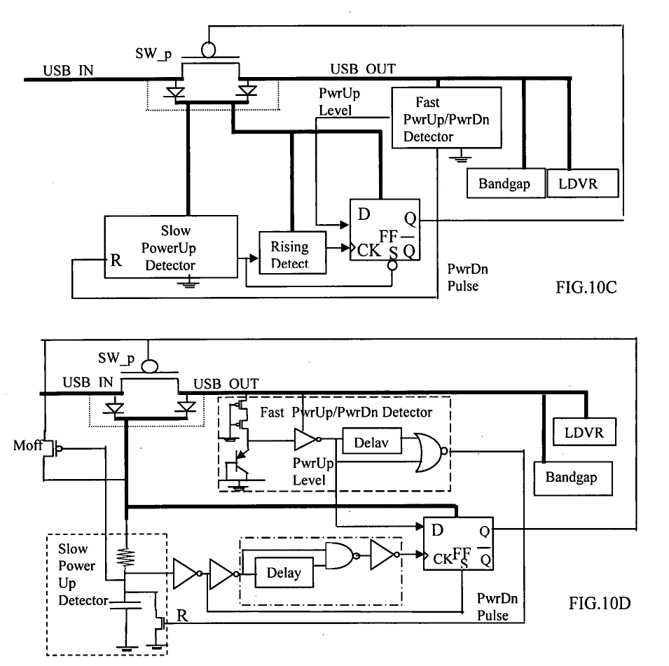

AS shown in FIG. 10A, it is the smart USB switch power table for the relation between the USB_IN_init power and USB_OUT_init. The smart USB switch principle is to save the external power if there is a local power on the USB_OUT side. However, the power on transient process is unpredictable and varies a lot. The ramp up slew rates of USB_IN and USB_OUT can be much different. The voltage levels of USB_IN and USB_OUT are much different in the transient process. Even there is the supply power on the USB_OUT side, however, the ramp up slew rate of USB_OUT is slow. It might make the wrong decision to open the switch SW_p. As the switch SW_p is turned on, both USB_IN and USB_OUT have power. It is impossible to make the decision of which side has power to be the power supply. All the decision has to make at the beginning of power on and the switch is still turned off at that time.

FIG. 10B is the power state diagram. It is different from the logic state diagram. The power state has the power off state. As the power is off, there is no logic state. No power, no logic state. However, the power state still has one power off state. So the power state cannot implemented with the logic state circuit. FIG. 10C is the architecture of the smart USB switch. The PMOS switch has the floating well. At beginning, the PMOS switch is off. Either USB_IN or USB_OUT has the power, the floating well of SW_p will be charged up. The Slow Power Up Detector, Rising Detect and FF will be powered up. If there is power on the USB_OUT, the fast PwrUp/PwrDn detector is 1, otherwise it is 0 state. The state will lock in the FF as the Slow Power Up Detector is powered up and generates a rising edge pulse. The lock state will decide whether the SW_p is on or off. FIG. 10D is the detailed circuit of the smart USB switch. As the power goes away, the Fast PwrUp/PwrDn Detector will issues a signal to discharge the Slow Power Up Detector and the FF will turn off the PMOS switch before the power has gone away. As the Slow Power Up Detector is discharged, the PMOS switch SW_p is switched off at the same time with the Moff being turned on to short the gate of SW_p to its substrate. It guarantees the initial state of the PMOS SW_p is shut-off.

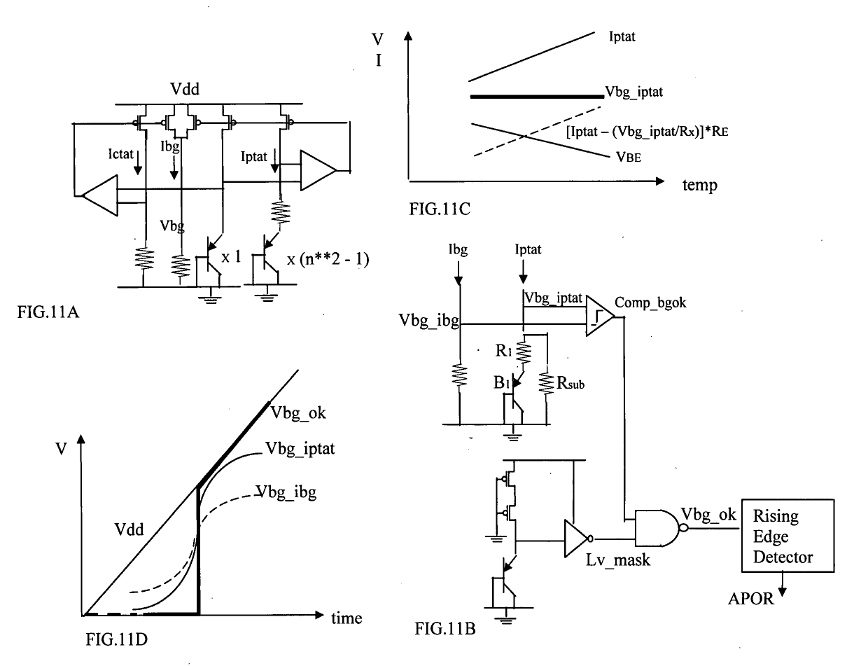

For SOC design, the digital circuit has the POR (Power On Reset) signal to reset all the FF (Flip-Flop) to the initial states condition. Similarly, for the analog/mixed signal circuit such as pipeline ADC and algorithmic ADC, etc, it has to set the initial phase clock, etc to avoid the short of the circuit, etc. The APOR is the analog power on reset signal to indicate the analog bandgap reference Vbg and Ibg are at the correct values and the APOR should be generated at the rising edge of Vbg_OK signal. As shown in FIG. 1 IA, the Iptat is generated by the conventional bandgap reference circuit. The Ictat is generated with (VBE/R). As shown in FIG. 11C and FIG. 11E, the sub-threshold bandgap reference voltage Vbg_iptat is generated with the Iptat injecting in the series connection of R₁ and B₁ in parallel with the sub-threshold resistor R_{sub}. The principle of the sub-threshold Vbg_iptat is as shown in FIG. C. Assuming the Vbg_iptat is constant over temperature, the current flowing through Rsub is (Vbg_iptat/Rsub) to be a DC constant. So the current Iptat is reduced by a constant DC value. It is the principle of the sub-threshold Vbg_iptat as follows.

[(Iptat−Iptat_{—}dc)*R+V_{BE}]=Vbg_{—}iptat<<Vbg=Iptat*R+VBE
where VBE is the bipolar base-emitter voltage.

As shown in FIG. 11E, both the Ibg and Iptat can generate the Vbg differently to be Vbg_ibg and Vbg_iptat. Vbg_ibg is derived from Ibg; Vbg_iptat is derived from Iptat. Both Vbg_ibg and Vbg_iptat can be sub-threshold bandgap voltage. However, as shown in FIG. 1 ID, Vbg_ibg and Vbg_iptat have the different slew rates. We use the different slew rates of Vbg_ibg and Vbg_iptat to generate the Vbg_ok with a comparator to generate the Comp_bgok signal. The Comp_bgok signal is masked with the Lv_mask signal for the Vdd still at the extreme low voltage to generate the ideal Vbg_ok signal for the whole Vdd, spanning from 0 volt to normal operation voltage. As shown in FIG. 11E, at the rising edge of Vdd_OK, the analog APOR is generated. Since Vbg_ibg and Vbg_iptat is PVT independent, APOR is independent of the PVT variation, too.

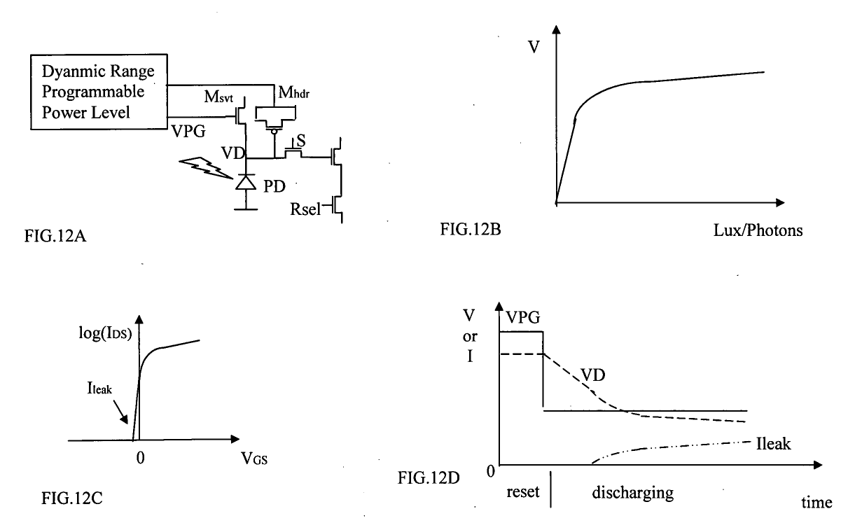

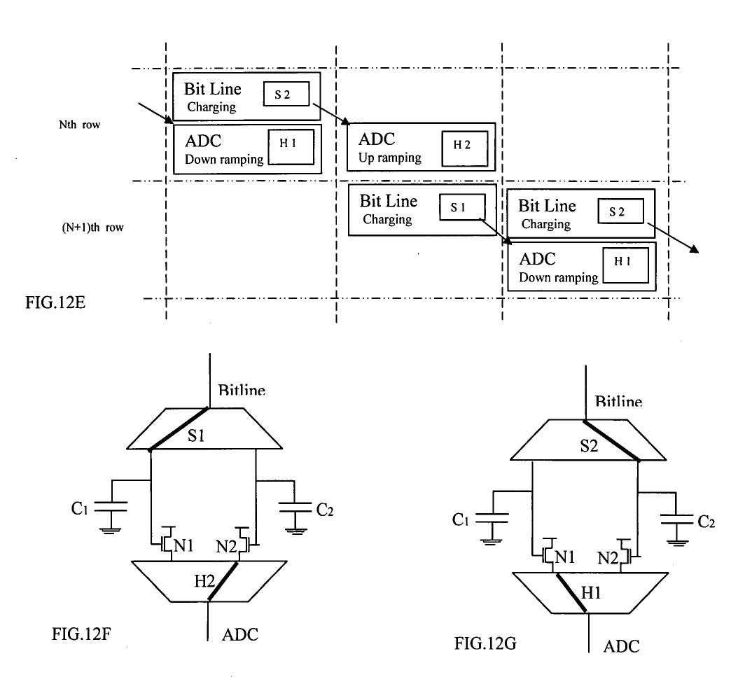

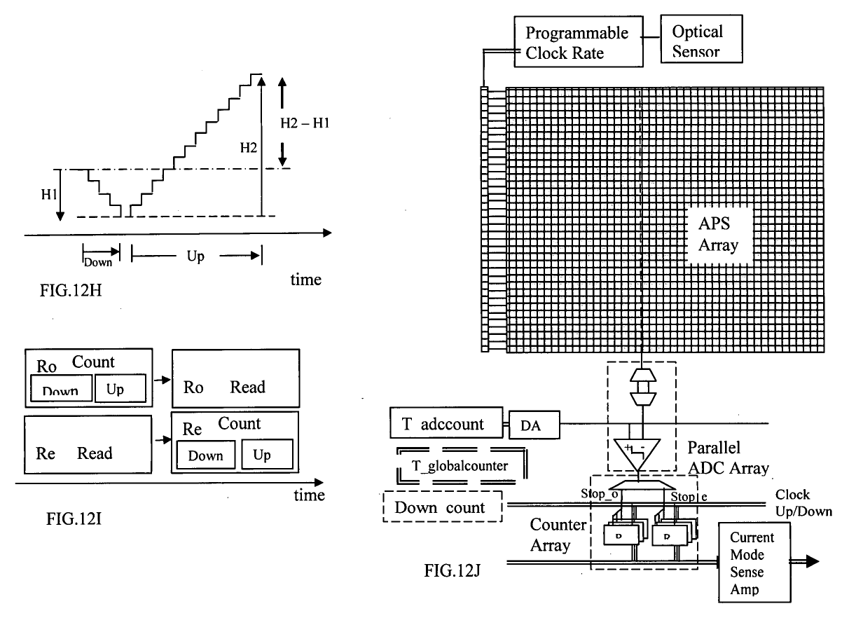

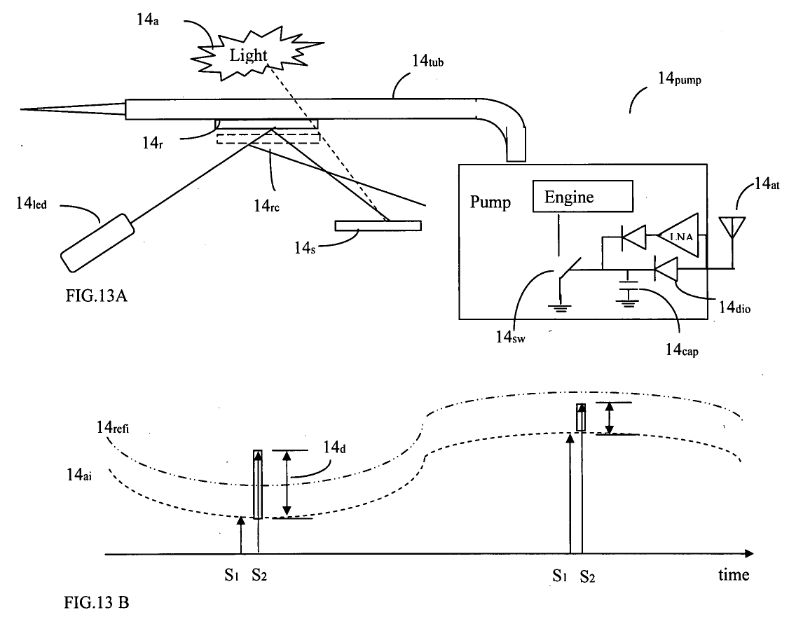

The SOC needs to detect the extreme environmental conditions. So the camera is Triple-Modes Camera. The triple modes are (1) surveillance camera mode, (2) video camera mode and (3) still camera mode. To have the surveillance camera mode, the APS (Active Pixel Sensor) needs to have the large dynamic range as shown in FIG. 12B.

To have the large dynamic range, as shown in FIG. 12A, the Msvt uses the low threshold voltage (Vth) device which has the leakage current as shown in FIG. 12C and the capacitor Mhdr is made of the PMOS. As shown in FIG. 12A, as the light shines on the photo diode PD, the voltage VD discharges. The PMOS device Mhdr turns on and the capacitance increases as the VD voltages drops. It increases the dynamic range. Furthermore, as shown in FIG. 12C and FIG. 12D, as VD voltages drops, the V_{GS} increases from the turn-off negative voltage to leaking voltage state. The VD voltage drops very slowly as the leakage occurs and the dynamic range is very large. It is noted that the reset voltage and the substrate voltage of PMOS might be programmed to be different voltage levels that the dynamic range can be programmed.

FIG. 12J is the architecture of the Triple-mode camera which has the APS array, parallel ADC array and the Counter Array. To speed up the operation of the Triple-Mode Camera, all the signal flows are pipelined design. As shown in FIG. 12E, FIG. 12F and FIG. 12G, the sampling operation is for the bit line charging the capacitor C1 and C2; the holding operation is for the parallel integrating ADC conversion.

As shown in FIG. 12G, FIG. 12H and FIG. 12J, the counter starts to count as the ADC operation begins. The counting number is converted to voltage with DAC. At the same time, the counter array also starts to count down as shown in FIG. 12H. As the ramp up DAC voltage is larger than the APS reset voltage, the comparator issues Stop_e or Stop_o command to stop the down count. At the same time, as shown in FIG. 12G, the bit line charges the capacitor C₂ with the integrated signal read out voltage.

Then as shown in FIG. 12F, FIG. 12H and FIG. 12J, the counter starts to count up as the ADC operation begins. The counting number is converted to voltage with DAC. At the same time, the counter array also starts to count up as shown in FIG. 12H. As the ramp up DAC voltage is larger than the APS integrated signal voltage, the comparator issues Stop_e or Stop_o command to stop the up count. At the same time, as shown in FIG. 12F, the bit line charges the capacitor C₁ with the reset voltage.

Furthermore, the camera can have the multiple sampling times option to increase the dynamic range. Using the T_globalcounter to count the total time, the count down only count once, later count up many times and the counting time uses the T_globalcounter times.

It is noted that to save the energy and reduce the chip noise, in the count down process, we can use a global Down_counter as shown by the dotted block in FIG. 12J. As the comparer triggers the stop or stopped signal, the register array Ro or Re of the counter array is loaded with the global count value into its register array.

As shown in FIG. 12I and FIG. 12J, the pipeline of counter array is divided to be odd bank Ro and even bank Re. The counting array and reading out array are swapping alternatively. Since the counter array has a lot switching noise, the reading out array adopts the current mode sense amplifier.

The count down and count up is one way to implement the CDS (Correlative Double Sampling). The CDS principle can be applied to many different applications. As shown in FIG. 13 is an injecting plastic tube in SOC system. Just like the passive RFID (Radio Frequency Identification) tag does, as shown in FIG. 13A, the antenna 14ₐₜ pumping up the voltage convert the RF energy to the electric energy, going through the diode 14_{dio} and store on the capacitor 14_{cap}. As the voltage is pumped up to be able to switch on the switch device 14_{sw}, the pump engine starts to pump. The injection tube 14_{tub} might be clogged that the plastic tube 14_{tub} will expand a little. To detect the minor expansion of the plastic tube 14_{tub}, the LED light 14_{led} shines on the mini-reflective mirror 14ᵣ. As the plastic tube 14_{tub} expands, the mirror 14ᵣ moves to the position 14_{rc}. The reflected light of the LED 14_{led} is no more shines on the sensor 14ₛ, the light intensity is reduced that the output voltage of the sensor 14ₛ is reduced, too. However, the system works in the open environment. The ambient light 14ₐ shines on the sensor 14ₛ, too. As shown in 13A, the ambient light intensity 14ₐᵢ varies a lot. It is impossible to use the conventional measurement. It must use the CDS (Correlated Double Sampling). As shown in FIG. 13B, the sensor 14ₛ samples the data twice successfully in a short period. At the second sampling time S2, the LED will light. The difference 14_{d} of these two sample is the LED light strength. Comparing the difference 14_{d} with the standard calibration table, we can decide whether the plastic tube 14_{tub} is clogged and how much the plastic tube 14_{tub} clog is. This SOC system has many other applications. For example, a patient has the blood pressure measurement wearing on the arm. The insulin pump 14ₚᵤₘₚ wears on the waist. The blood pressure can issue the RF signal to trigger on the pump 14ₚᵤₘₚ with the wireless trigger.

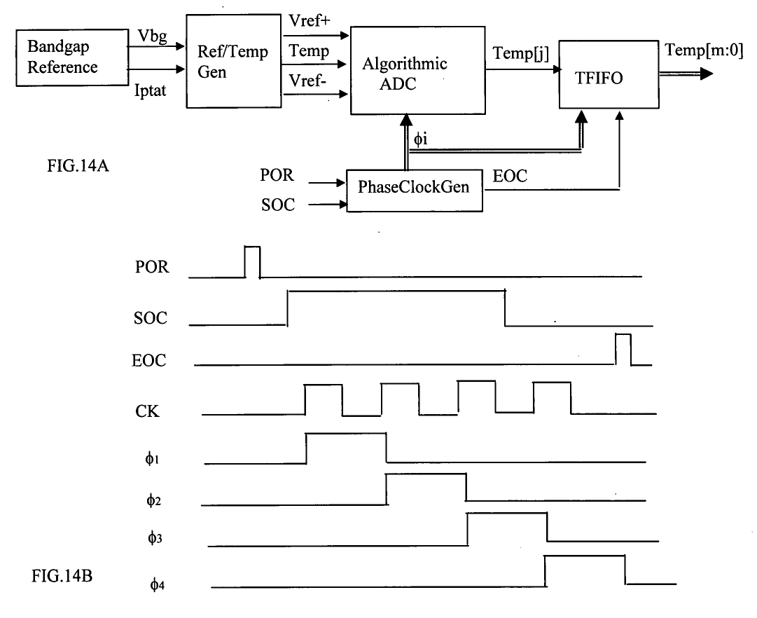

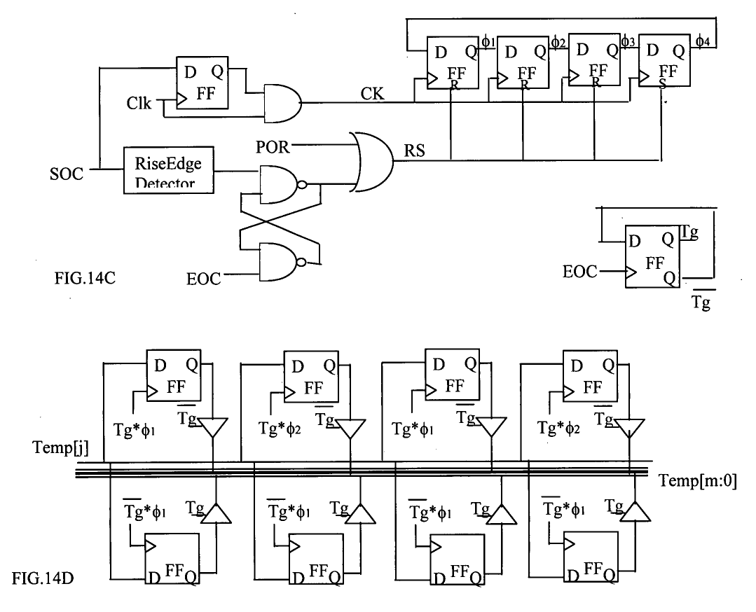

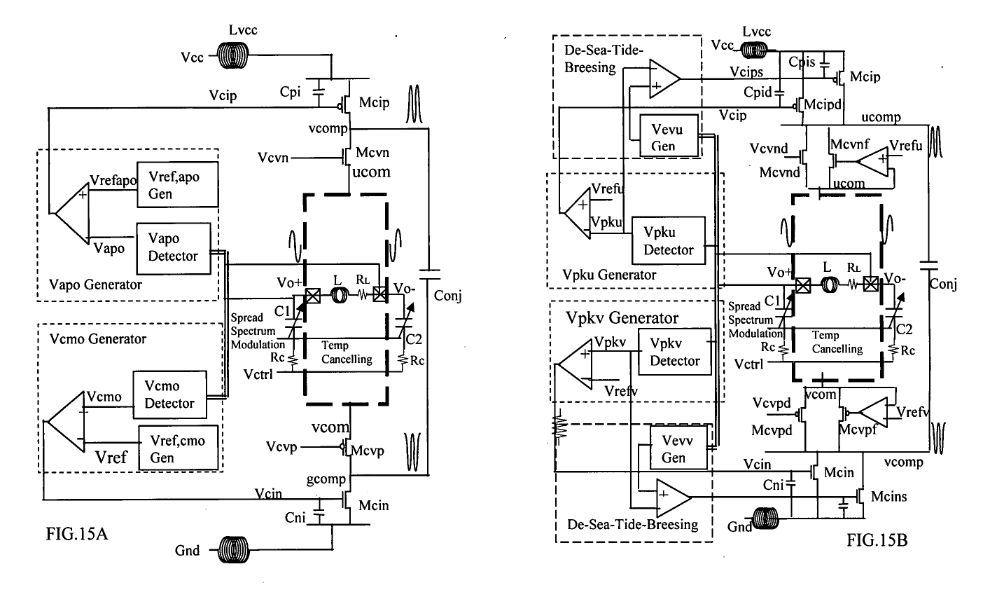

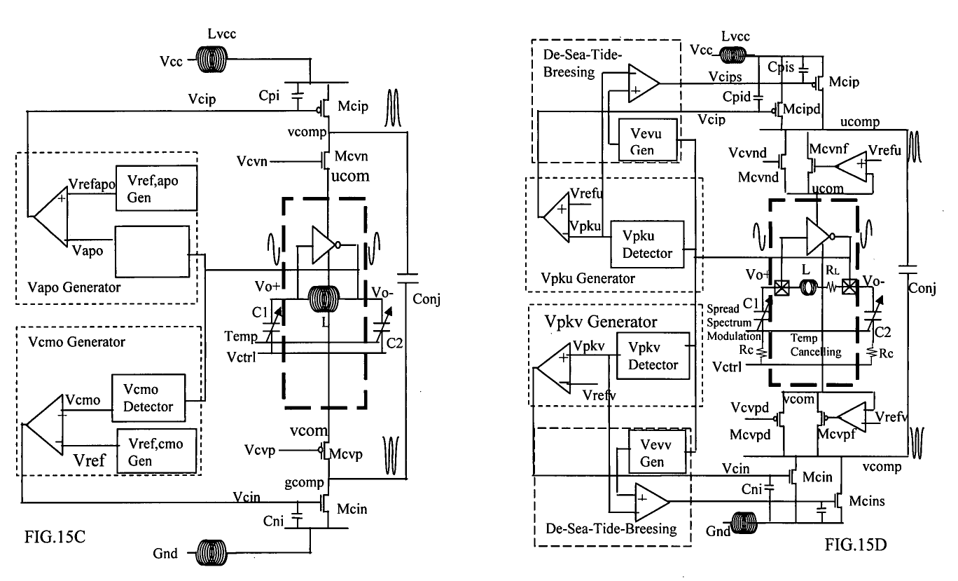

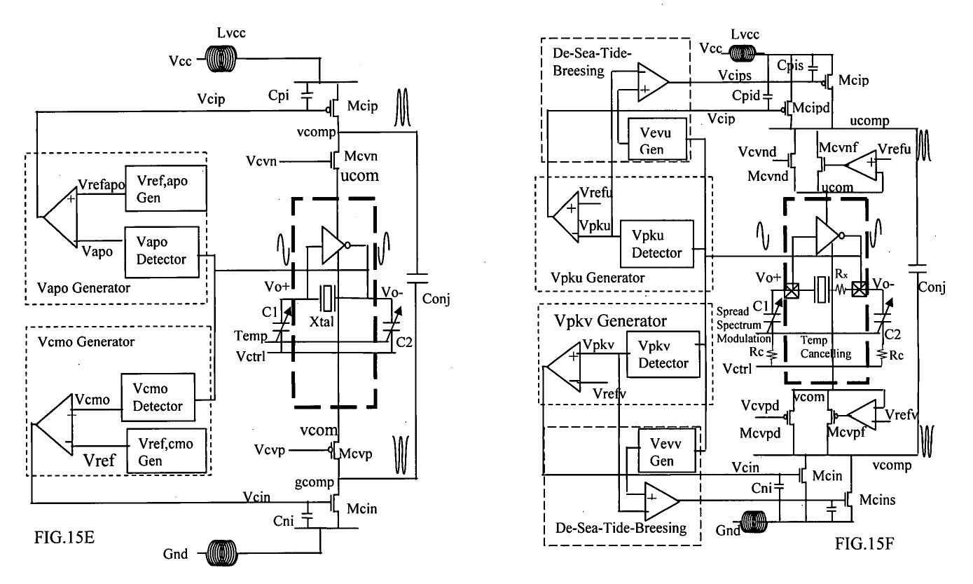

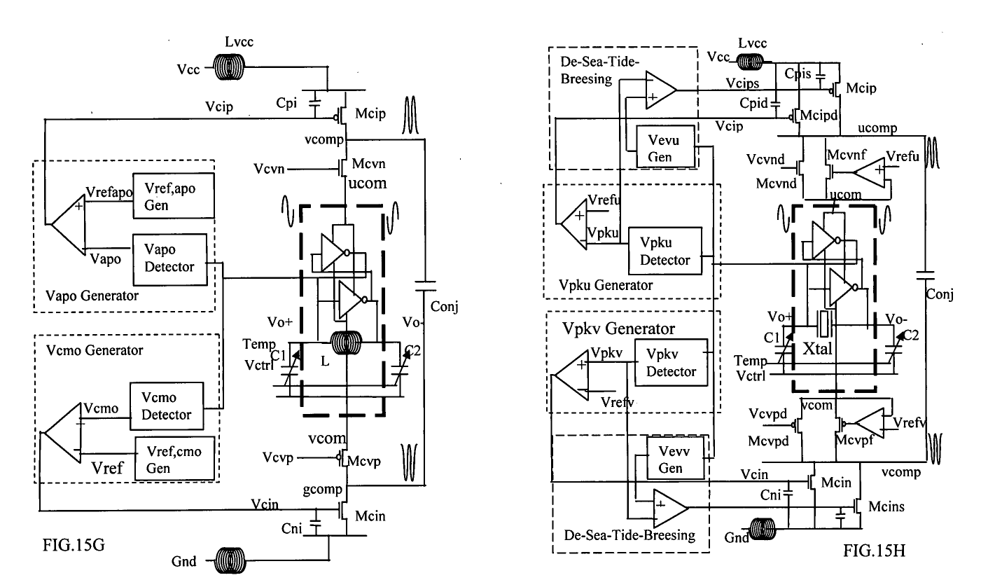

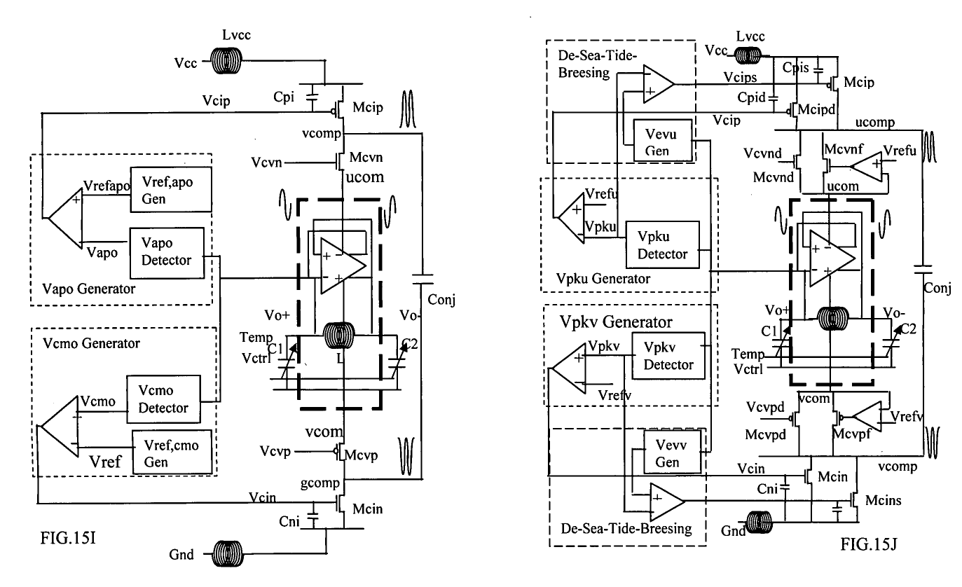

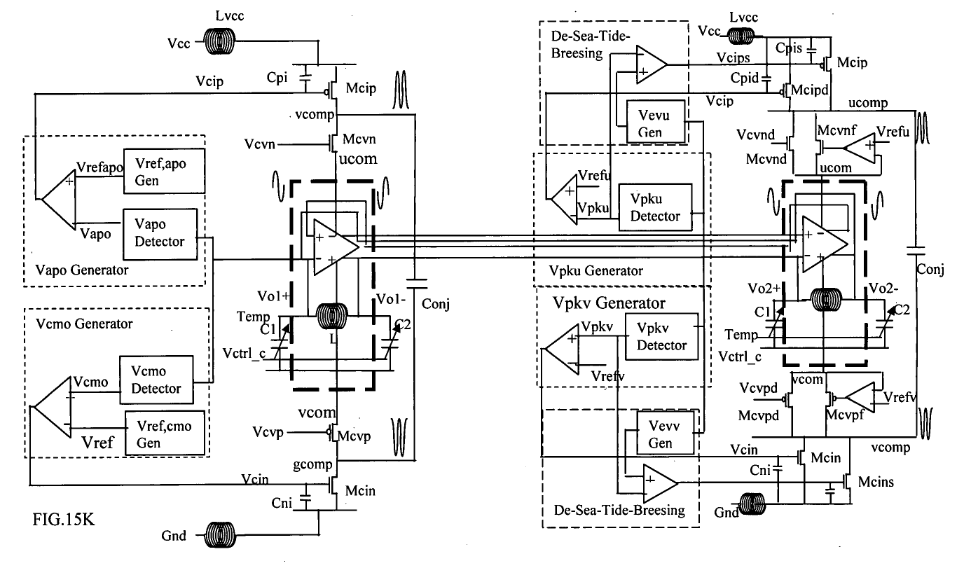

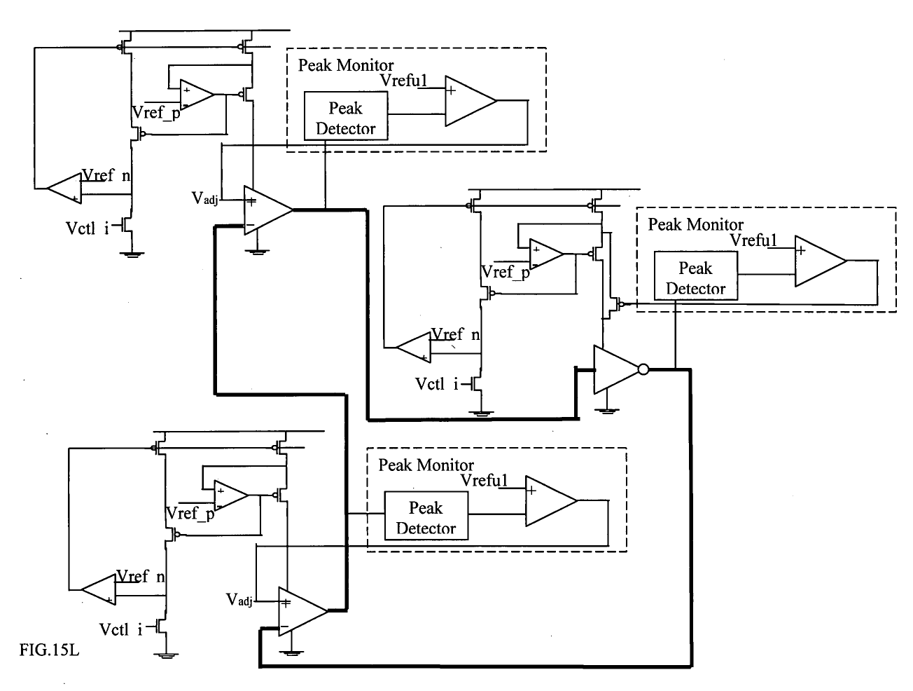

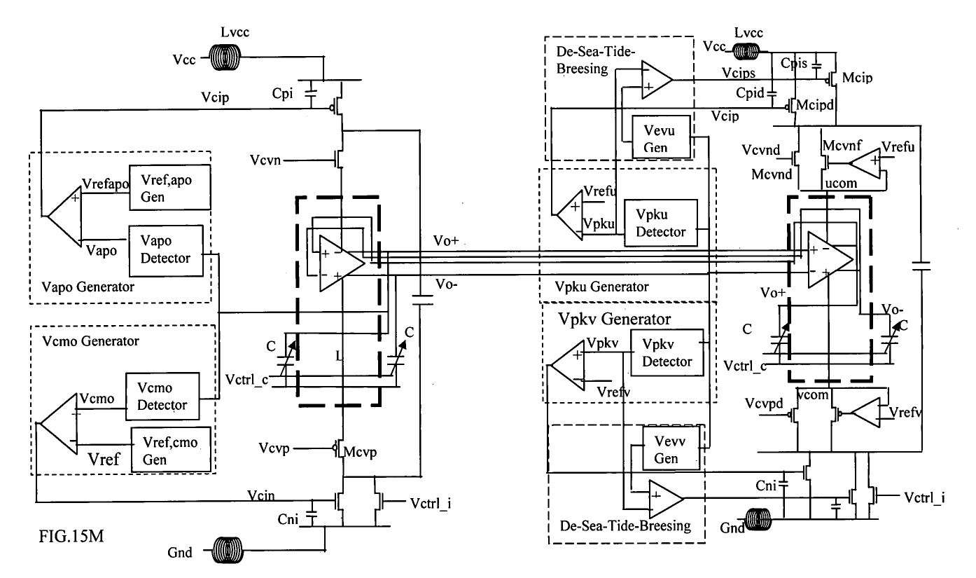

For the PVTANH design of TSOC, the temperature compensation is very important. For the nonlinear temperature compensation, we need to convert the analog voltage of the temperature measurement to the digital form. As shown in FIG. 14A, it is the on-chip temperature calibration. From the bandgap reference, we have the Vbg and Iptat. From the Vbg, we generate the vref+ and Vref− voltages. From Iptat, we generate the Temp which is the voltage representing the temperature. The Algorithmic ADC has the minimum chip area. As shown in FIG. 14A and FIG. 14D, to have the continuously update temperature and minimizing the switching noise, the serial data is converted to the parallel data with the TFIFO of toggling FIFO. As shown in FIG. 14A and FIG. 14C, the algorithmic ADC and toggling FIFO are driven with the phase clock generator PhaseClockGen. As shown in FIG. 14B is the timing waveform of the phase clock generator PhaseClockGen. The POR (Power On Reset) or SOC (Start Of Conversion) will reset the clock phases φ₁, φ₂, φ₃ and φ4. As long as a ADC conversion starts, this conversion will not stop until the currently executed ADC conversion finishes. As the ADC finishes, EOC (End Of Conversion) signal will be generated.

In toggling FIFO, the phase clock serves as the pointer to load the data directly into the register of its corresponding bit. One FIFO is engaged with the ADC and the other FIFO has the data been ready to read out any time. These two FIFOs toggling and swapping to changing the role of conversion and reading out. So, the most updated digital temperature is ready anytime.

FIG. 15 is the unified approach for the platform of the gain-boost-Q for all the different kinds of the oscillators as shown in FIG. 3J the gain-boost-Q for the LC resonator does. The oscillator has the generic L and C components. There are two ways for the eliminate the temperature variation. The first way is temperature compensation. The oscillation frequency variation is trimmed with the signal Temp to compensate for the variation of the temperature. The second way is temperature cancelling. The R_{C} is designed to be equal to R_{L} as FIG. 2H does. In FIG. 15, both ways are presented. The oscillation frequency variation is controlled with the signal Vctrl.

FIG. 15A is the platform for the constant-amplitude-control and fixed-common-mode-control. The constant-amplitude-control is to control the amplitude of the oscillation to be constant. The fixed-common-mode-control is to control the common voltage of the oscillation to be constant. In other words, for the sinusoidal oscillation, the middle voltage of the oscillation is a constant. For the symmetrical operation of the LCO case, the voltage oscillation at Vo+ is the same as the voltage oscillation at V−. The common mode control is to have Vo+ and V− to have the same voltage level. For the unsymmetrical of the XO crystal oscillator case, the common mode principle still applies. However, the amplitude at the Vo+ is different from the amplitude at the Vo−. So, the principle should apply smartly to have the minimum components to have the maximum control.

FIG. 15B is the platform for the constant-peak-control and constant-valley-control. The constant-peak-control is to control the peak of the oscillation to be constant. The constant-valley-control is to control the valley voltage of the oscillation to be constant. In other words, for the sinusoidal oscillation, the middle voltage of the oscillation is an automatically to be constant. For the symmetrical operation of the LCO case, the voltage oscillation at Vo+ is the same as the voltage oscillation at V−. The constant-peak-control is to have Vo+ and/or V− to have the same peak voltage. For the unsymmetrical of the XO crystal oscillator case, the common mode principle still applies. However, the amplitude at the Vo+ is different from the amplitude at the Vo−. So, the principle should apply smartly to have the minimum components to have the maximum control. The monitoring voltage is the output voltage of the inverter in the XO crystal oscillator.

For the unified approach, the oscillator can be single stage crystal oscillator, the two stages LC resonator and the multiage ring oscillator. The gain-boost-Q principle can be applied to all the different oscillator to enhance the performance of all the different oscillators. The temperature cancelling R_{C}=R_{L} also can be applied to all the different oscillator to enhance the performance of all the different oscillators. FIG. 15C is the constant amplitude and common-mode control platform having the single stage inverter to serve as the oscillator. With the gain-boost-Q circuit, the off-chip crystal can be replaced with the on-chip inductor. This is the on-chip crystal oscillator type LC oscillator with only one inverter. FIG. 15D is the constant-peak control and the constant-valley platform for the single stage inverter oscillator. To minimize the controller and maximize the performance, it is suggested to use the output node of the inverter to be the observation node.

FIG. 15E is the BQTCXO gain-boost-Q temperature compensation crystal oscillator and/or the BQVCXO gain-boost-Q voltage control crystal oscillator. The gain-boost-Q platform is not only for the on-chip LC oscillator but also for the crystal oscillator. As shown in FIG. 3K, the off-chip crystal oscillator has a lot of noises coming from the parametric inductors of the bonding wire and pin. The gain-boost-Q platform can compensate the chaotic noise of the crystal oscillator to enhance the performance a lot. Comparing FIG. 15E with FIG. 15C and FIG. 15F with FIG. 15D, the crystal is a high Q inductor L. For the on-chip inductor, the gain-boost-Q platform increases the performance a lot. For the crystal oscillator, with the gain-boost-Q platform, the low quality crystal has the same performance of the high quality crystal. FIG. 15F shows, instead of the temperature compensation, the temperature cancelling technique can apply to the crystal oscillator with R_{C}=Rx where Rx is the equivalent resistor of the crystal.

FIG. 15G and FIG. 15H are the gain-boost Q platform has the 2-stage dual-stage conjugate inverters to be the oscillator core. Comparing FIG. 15H with FIG. 3J, the 2 stage dual-stage conjugate inverters actually are a LC oscillator. Furthermore, crystal is a high Q inductor. In FIG. H, the inductor is replaced with a crystal. This new crystal oscillator is gain-boost-Q crystal oscillator. It has the much better performance than the conventional crystal oscillator. The gain-boost Q platform has proven on chip to enhance the LC oscillator crystal oscillator performance tremendously. FIG. 15I and FIG. J are the gain-boost Q platform has single stage differential conjugate oscillator. As shown in FIG. 15C and FIG. 15I, the single stage inverter or differential inverter is one stage ring oscillator. The single stage inverter or differential inverter is the basic component of the ring oscillator. If all the stages of the ring oscillator have the gain-boost platform, the ring oscillator will have the high performance and the jitter is minimized.

FIG. 15K is the gain-boost-Q has the conjugate Q and I oscillator having the phase difference among Vo1+, Vo1−, V2+ and V2− to be 90 degree. The gain-boost-Q IQ signals will enhance the wireless communication quality a lot. This enhancement in IQ performance might induce the innovations and revolution of the wireless architecture.

Comparing FIG. 4Q with FIG. 15L, FIG. 15L is the current mode type gain-boost-Q ring oscillator. For the ring oscillator, the Vctl controls the current to vary the frequency of the ring oscillation. The gain-boost-Q ring oscillator controls the constant amplitude of the oscillation to boost the Q of the ring oscillator. There are two ways to keep the amplitude of the oscillation to be constant. It might inject current into the oscillator or change the trigger point to keep the constant amplitude.

There are two ways to keep the amplitude of the oscillation to be constant. One is to change the capacitance with the control voltage Vctrl_c. The other is to change the current flowing through the ring oscillator with control voltage Vctrl_I as shown in FIG. 15L. FIG. 15M is the voltage mode type gain-boost-Q ring oscillator.

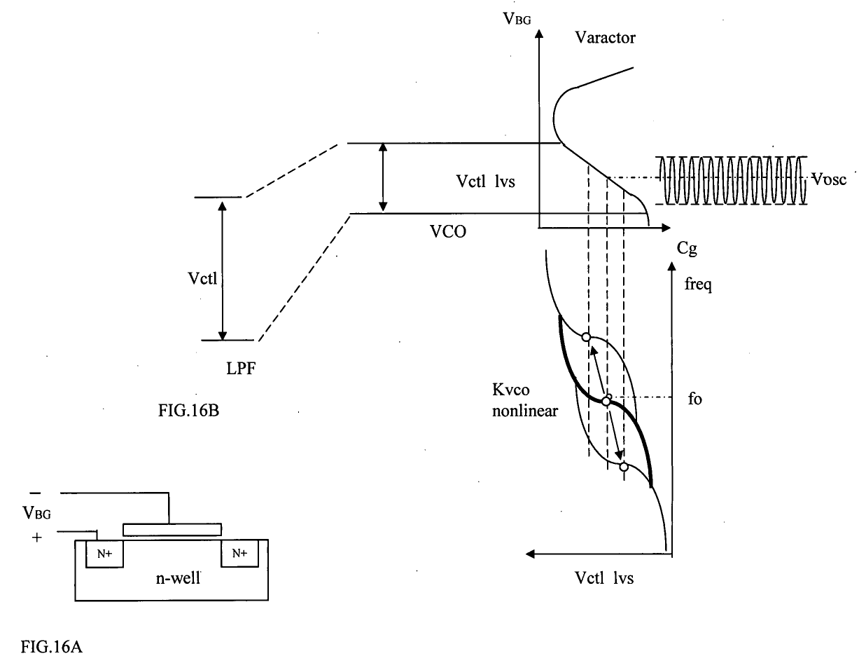

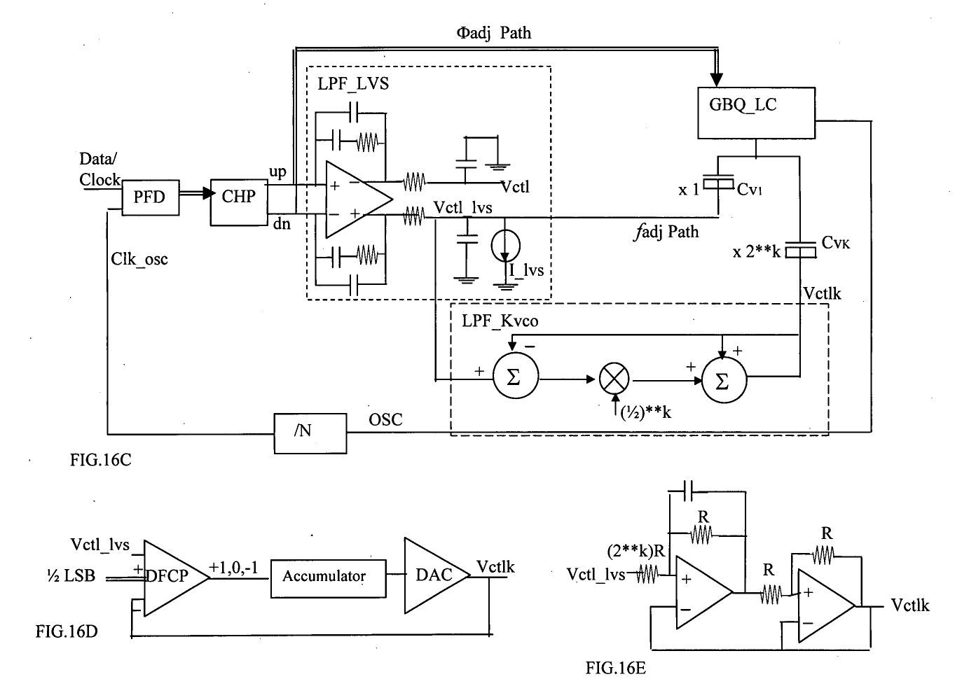

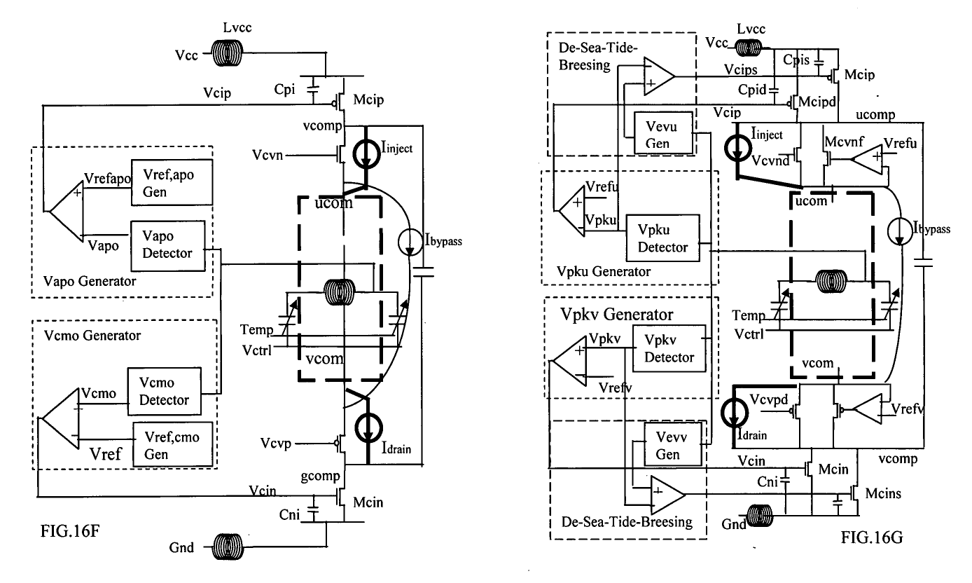

For the state-of-art high performance network having the requirement of clock jitter being less than 2 ps, only the LC oscillator can be adopted. FIG. 16 shows the application of Gain-Boost-Q LCO in FIG. 15G or FIG. 15H to the VCO of the frequency synthesizer to enhance the clock performance in the high frequency system such as the 10 GB Twist pair Ethernet network. To tune up the oscillation frequency of the LCO, the varactor is adopted. There are two kinds of varactor. The reversed-biased p-n junction diode type varactor has the leakage current problem as the large oscillation of the LCO makes varactor diode forward bias. So, to avoid the leakage problem, the LCO uses the MOSFET accumulation capacitance type varactor as shown in FIG. 16A. However, as shown in FIG. 16B, there are voltage level shift and scale problems in the system design of frequency synthesizer. First, the control voltage Vctl of LCO must be monotonous. However, the MOSFET varactor capacitance is not monotonous. We have to choose one monotonous region to work. Second, the LCO has the common voltage to be fixed. The VBG of the MOSFET varactor capacitance is relative to the common mode voltage of the oscillation of LCO. The monotonous range of the MOSFET varactor capacitance is narrow. Both the monotonous range and the voltage level don't match between the control voltage Vctl low pass filter LPF and the control voltage Vctl_lvs of the substrate voltage of the MOSFET varactor capacitance. So we need to make both the voltage level shift and voltage range scaling for the Vctl_lvs. The most important requirement for the 10 GHz high frequency PLL requirement is the performance requirement. The core engine of GBQLCO can meet the requirement of the jitter being less than 1 ps. However, the system control circuit of the PLL must make a lot innovation. The 1 ps jitter fine tune requirement make the Kvco is very small to be designed to have minimum value in small signal analysis. However, for the conventional linear Kvco design, the narrow tune-up range of Kvco makes the LCO failing to track the input data to perform the CDR function. To track the input data to recover the clock and data, we need to have wide Kvco range for LCO. So, we need the dynamic adaptive nonlinear Kvco as shown in FIG. 16B. The nonlinear Kvco curve can shift dynamically that the operating point of the oscillation frequency fo is always has the minimum Kvco in small signal analysis. Outside the oscillation frequency, the nonlinear Kvco makes the LCO having large frequency locking capability. As shown in FIG. 16C, the low pass filter and the level shift of the Vctl and Vctl_lvs is implemented in the dotted block LPF_LVS. The algorithmic and architecture of the dynamic adaptive nonlinear Kvco is implemented in the dotted block LPF_Kvco. FIG. 16D is the digital type LPF_Kvco; FIG. 16E is the analog type LPF_Kvco.

The conventional LPF is a passive RC circuit. To have the level shift and scaling function, the LPF becomes the active low pass filter as shown in FIG. 16C. The level shift is performed by the I_lvs. For the LPF_LVS, the scaling is optional. To add the scaling to the LPF_LVS, the scaling is just to add another OPAMP stage which is similar to the first stage of FIG. 16E and the scaling circuit is not shown in FIG. 16C.

The dynamic adaptive nonlinear LPF_Kvco circuit in FIG. 16B is to emulate the dynamic adaptive nonlinear behavior in FIG. 16B. There are two MOSFET varactors. The large MOSFET varactor Cᵥₖ is 2**k times of the small MOSFET varactor Cᵥₗ. The control voltage Vct_lvs is only tune up the least significant varactor Cᵥₗ. The substrate voltage of the most significant varactor Cᵥₖ is tune up with the control voltage Vctlk. To emulate the adaptive dynamic shift of the nonlinear Kvco curve, the voltage of Vctl_lvs will down scale with the factor 2**k to add on the Vctlk to be the new Vctlk. As shown in the dotted block, the least significant varactor control voltage Vctl_lvs subtracts the most significant varactor control voltage Vctlk, then the difference is down scale with the factor (½)**k. The scaled down difference is added on the Vctlk to be the new Vctlk. It is corresponding to the dynamic adaptive shift of the nonlinear Kvco curve.

FIG. 16D is the digital implementation of the LPF_Kvco. As the Vctl_lvs and Vctlk have the difference more than ½ LSB least significant bit, then the accumulator is triggered. If the Vctl_lvs is larger than Vctlk, then the accumulator is increased by one; if the Vctl_lvs is less than Vctlk, then the accumulator is decreased by one. The accumulator value is converted to be the voltage Vctlk through DAC. The analog LPF_Kvco is shown in FIG. 16E. The Vctl_lvs substrate Vctlk and down scale the difference with the factor ½**k. Then the downscaled difference is added to the Vctlk to be the new Vctlk. All the operation is performed continuously. Merging FIG. 16E with FIG. 16C, there are two level of hierarchical control. The first level of the hierarchy is the fast phase adjustment path Φ_adj Path and the slow f_adj Path. The second level of the hierarchy is the fast least significant varactor Cvl tuning up process and the slow most significant varactor Cvk tuning up process. This hierarchical structure of PLL satisfies the requirement of the small signal analysis that the bandwidth of the large and the Kvco is minimum. However, the nonlinear PLL still have the wide dynamic frequency locking range.

To have the fast settling time, as shown in FIG. 16C, the phase of the oscillation is adjusted with the feed forward path Φadj Path. The frequency of the oscillation is adjusted with the slow f adj Path. This is the separation of the phase adjustment path and the frequency adjustment path. As shown in FIG. 16C, FIG. 16F and FIG. 16G, the phase adjust of the oscillation might be implemented with the short impulse of the current which is corresponding to the phase difference between the input Data/Clock and the Clk_osc signal which is the signal derived from the oscillator. As the Data/Clock phase is earlier than the phase of the Clk_osc, the current flowing through the LCO oscillator increases momentarily: (1) the impulse current having the period being proportional to the up signal injecting into the oscillator; (2) the impulse current having the period being proportional to the up signal draining from the oscillator as shown by the thick line of the current source. The phase of the oscillation will be kicked to advance momentarily. As the Data/Clock phase is late than the phase of the Clk_osc, the current flowing through the LCO oscillator decreases momentarily. The impulse current has the period being proportional to the dn signal bypass the oscillator as shown by the thin line of the current source. The phase of the oscillation will be kicked to delay momentarily.

While the invention has been particularly shown and described with reference to the preferred embodiments thereof, it will be understood by those skilled in the art that various changes in form and details may be made therein without departing from the spirit and scope of the invention.

We claim:

1. A 4Less TSOC design being xtaless, capless, indless and dioless, of which 4Less TSOC design having superior circuit design such that
said xtaless clock chip design having no need for external crystal to have high clock performance, however, said as xtaless clock chip design having said external crystal having much better performance than original crystal oscillation.

2. A 4Less TSOC design according to claim 1 of which said xtaless clock chip design is constituting one inductor means, capacitor means, active devices means, amplitude control means and common mode control means;
said inductor means connecting with said capacitor means to form an oscillator means;
said active devices means driving said oscillator means to oscillate;
said amplitude control means monitoring an amplitude of oscillation to adjust current flowing into said oscillator means to keep said amplitude to be constant;
said common mode control means monitoring common voltage of said oscillator means to cooperate with said amplitude control means to set common mode voltage of said oscillator at a fixed voltage level.

3. A 4Less TSOC design according to claim 2 of which said active devices means being inverter means.

4. A 4Less TSOC design according to claim 3 of which said inductor means being a crystal means, said chip design being mentioned as BQXO, boosting Q crystal oscillator.

5. A 4Less TSOC design according to claim 4 of which said chip design further including a temperature variance effect compensating or cancelling means to keep said oscillation frequency being constant over temperature, of which said chip design being mentioned as BQTCXO, boosting Q temperature compensating crystal oscillator.

6. A 4Less TSOC design according to claim 4 of which said chip design further including a voltage controlling means to vary said oscillation frequency, of which said chip design being mentioned as BQVCXO, boosting Q voltage control crystal oscillator.

7. A 4Less TSOC design according to claim 2 of which capacitance being modulated with random noise to have spread spectrum clock.

8. A 4Less TSOC design according to claim 1 of which said xtaless clock chip design is constituting one inductor means, capacitor means, active devices means, peak control means and valley control means;
said inductor means connecting with said capacitor means to form an oscillator means;
said active devices means driving said oscillator means to oscillate;
said peak control means monitoring peak of oscillation to adjust current flowing into said oscillator means to keep said peak voltage of said oscillation to be constant voltage at a first fixed voltage level;
said valley control means monitoring valley voltage of said oscillator means to cooperate with said peak control means to set said valley voltage of said oscillator at a second fixed voltage level.

9. A 4Less TSOC design according to claim 8 of which said active devices means being inverter means.

10. A 4Less TSOC design according to claim 9 of which said inductor means being a crystal means, said chip design being mentioned as BQXO, boosting Q crystal oscillator.

11. A 4Less TSOC design according to claim 10 of which said chip design further including a temperature variance effect compensation or cancelling means to keep said oscillation frequency being constant over temperature, of which said chip design being mentioned as BQTCXO, boosting Q temperature compensating crystal oscillator.

12. A 4Less TSOC design according to claim 10 of which said chip design further including a voltage controlling means to vary said oscillation frequency, of which said chip design being mentioned as BQVCXO, boosting Q voltage control crystal oscillator.

13. A 4Less TSOC design according to claim 8 of which capacitance being modulated with random noise to have spread spectrum clock.

14. A 4Less TSOC design according to claim 1 of which said xtaless clock chip design further comprising a PLL,
said PLL comprising a PFD, LPF and VCO resonator means,
said VCO means having nonlinear coefficient of Kvco;
as oscillation frequency deviating from a designated oscillation frequency being small frequency range, said Kvco having very small value;
as oscillation frequency deviating from a designated oscillation frequency being large frequency range, said Kvco having very large value.

15. A 4Less TSOC design according to claim 14 of which said VOC having nonlinear coefficient of Kvco further being adaptive;
as said designated oscillation frequency being tuned up to vary, said nonlinear coefficient curve of Kvco will automatically shift to move said nonlinear coefficient curve of Kvco to center at new designated oscillation frequency;
as oscillation frequency deviating from said new designated oscillation frequency being small frequency range, said Kvco having very small value;
as oscillation frequency deviating from said new designated oscillation frequency being large frequency range, said Kvco having very large value.

16. A 4Less TSOC design according to claim 1 of which said xtaless clock chip design further comprising a PLL,
said PLL comprising a PFD, LPF and VCO resonator means,
said VCO means having nonlinear adaptive coefficient of Kvco;
as oscillation frequency deviating from a designated oscillation frequency being small frequency range, said Kvco having very small;
as oscillation frequency deviating from a designated oscillation frequency being large frequency range, said Kvco having very large.

17. A 4Less TSOC design according to claim 16 of which said VCO having varactor means,
said varactor means being constituted of a small capacitance means and a big capacitance means;
said small capacitance means being biased with a controlling voltage;
said big capacitance means being biased with a main controlling voltage;
a difference voltage of said main controlling voltage and said controlling voltage being downscaled according to a ratio of said small capacitance means and said big capacitance means and summing up with said difference voltage with said main controlling voltage to be a new said main controlling voltage.

18. A 4Less TSOC design according to claim 1 of which said xtaless clock chip design further comprising a PLL,
said PLL comprising a PFD, LPF and VCO resonator means,
said VCO having varactor means, said LPF filter having active level shift capability to shift control voltage to bias said varactor means at a monotonous region.

19. A 4Less TSOC design according to claim 1 of which said xtaless clock chip design further comprising a PLL,
said PLL comprising a phase frequency detector means PFD, CHP, LPF and VCO resonator means,
up and down output signal of said PFD means being fed into said VCO means,
as oscillation of said VCO having phase delay needing to catch up, said output of said PFD will injecting more current into said VCO momentarily for a up signal period;
as oscillation of said VCO having phase advance needing to delay, said output of said PFD will bypass more current out of said VCO momentarily for a down signal period.

20. A 4Less TSOC design being xtaless, capless, indless and dioless according to claim 1 of which 4Less TSOC design having a low drop voltage regulator LDVR and switch mode power supply SM being SMLDVR,
said LDVR having a driver and biasing voltage controller
said SM having said driver and switch mode control;
said SM and LDVR sharing same driver with multiplexes of said SM and LDVR driving signals.
